(19) United States
(12) Patent Application Publication
(10) Pub. No.: US 2026/0096410 A1
(43) Pub. Date: Apr. 2, 2026

(54) SEMICONDUCTOR DEVICE AND METHOD FOR MANUFACTURING SEMICONDUCTOR DEVICE

(71) Applicant: SONY SEMICONDUCTOR SOLUTIONS CORPORATION, Kanagawa (JP)

(72) Inventors: Takushi SHIGETOSHI, Kanagawa (JP); Masaki OKAMOTO, Kanagawa (JP); Tatsumasa HIRATSUKA, Kanagawa (JP); Takaaki HIRANO, Kanagawa (JP); Katsuhisa KUGIMIYA, Kanagawa (JP); Shun MATSUMOTO, Kanagawa (JP); Takahisa FURUHASHI, Kanagawa (JP)

(73) Assignee: SONY SEMICONDUCTOR SOLUTIONS CORPORATION, Kanagawa (JP)

(21) Appl. No.: 19/110,397

(22) PCT Filed: Sep. 22, 2023
(86) PCT No.: PCT/JP2023/034565

§ 371 Date: Mar. 10, 2025

(30) Foreign Application Priority Data
Sep. 22, 2022 (JP) 2022-150857
Dec. 2, 2022 (JP) 2022-193233
Mar. 22, 2023 (JP) 2023-045171

(51) Int. Cl. H10W 20/20; H10F 39/00; H10W 20/00

(52) U.S. Cl. CPC H10W 20/2134; H10F 39/811; H10W 20/0249

(57) ABSTRACT

Reliability is improved in a semiconductor device in which an annular trench is formed around a through hole. A semiconductor device includes a semiconductor substrate, a through wiring, a back surface insulating film, and an annular trench. A wiring layer is formed on a front surface of the semiconductor substrate. The through hole penetrates the semiconductor substrate. The through wiring is formed along a side surface of the through hole. The back surface insulating film covers a back surface of the semiconductor substrate with respect to the front surface. The annular trench surrounds the periphery of the through hole when viewed from a direction perpendicular to the back surface, and a cavity closed by the back surface insulating film when viewed from the direction parallel to the back surface is formed inside.

### TECHNICAL FIELD

The present technology relates to a semiconductor device. Specifically, the present invention relates to a semiconductor device in which a through electrode is formed, and a method for manufacturing a semiconductor device.

### BACKGROUND ART

In recent years, in various semiconductor devices, research and development of three-dimensional integration technology using through electrodes have been advanced for the purpose of further higher integration. In a case where the through electrode is formed on a semiconductor substrate such as silicon, a parasitic capacitance is formed between the through electrode and the semiconductor substrate, and signal transmission performance may be deteriorated. Therefore, semiconductor devices have been proposed in which an annular trench is formed around a through hole in a through electrode to separate a conductor in the through hole from the periphery (see, for example, Patent Document 1).

### CITATION LIST

### Patent Document

Patent Document 1: Japanese Patent Application Laid-Open No. 2013-251539

### SUMMARY OF THE INVENTION

### Problems to be Solved by the Invention

In the above-described conventional technique, the conductor in the through hole is separated by the annular trench, thereby reducing the parasitic capacitance and improving the reliability of the through electrode. However, in the above-described semiconductor device, it is difficult to further improve reliability represented by yield or the like.

The present technology has been made in view of such a situation, and an object thereof is to improve reliability in a semiconductor device in which an annular trench is formed around a through hole.

### Solutions to Problems

The present technology has been made to solve the above-described problems, and a first aspect thereof is a semiconductor device including: a semiconductor substrate having a wiring layer formed on a front surface of the semiconductor substrate; a through hole penetrating the semiconductor substrate; a through wiring formed along a side surface of the through hole; and an annular trench surrounding a periphery of the through hole when viewed from a direction perpendicular to a back surface of the semiconductor substrate with respect to the front surface, and a method for manufacturing the same. This brings about an effect of improving reliability.

In addition, in the first aspect, a cavity may be formed inside the annular trench when viewed from a direction parallel to the back surface. This brings about an effect of reducing the parasitic capacitance.

In addition, the first aspect may further include a back surface insulating film that covers the back surface of the semiconductor substrate with respect to the front surface, in which the back surface insulating film may include first and second back surface insulating films laminated, and the second back surface insulating film may cover the back surface and a side wall of at least one of the through hole or the annular trench. This brings about an effect of improving insulation properties and resistance to mechanical stress.

Furthermore, the first aspect may further include a first element isolation region formed around a bottom portion of the through hole. This brings about an effect of suppressing formation of a notch or a trailing shape.

Furthermore, in the first aspect, the second back surface insulating film may include a fixed charge film. This brings about an effect of reducing the influence of defects on the interface and the front surface.

Further, in the first aspect, the through hole may include a first through hole and a second through hole, the annular trench may be formed around the first through hole, and the annular trench may not be formed around the second through hole. This brings about an effect that both signal transmission performance and integration are realized.

Further, in the first aspect, the through holes may include first and second through holes arranged adjacent to each other in the direction parallel to the back surface, the annular trench may include a first annular trench formed around the first through hole and a second annular trench formed around the second through hole, and the first annular trench may share a part with the second annular trench. This brings about an effect that the pitch of the through electrodes is reduced.

In addition, in the first aspect, a width of a portion shared by the first and second annular trenches may be substantially same as a width of a portion not shared. This brings about an effect of reducing variations in the entry amount of the back surface insulating film into the annular trench.

In addition, the first aspect may further include a back surface insulating film that covers the back surface of the semiconductor substrate with respect to the front surface; and a back surface rewiring formed along the periphery of the through hole and the back surface insulating film in the back surface. This brings about an effect that the through electrodes are electrically connected via the back surface rewiring.

In addition, in the first aspect, an outer periphery of the back surface rewiring formed around the through hole may be larger than an outer periphery of the annular trench. This brings about an effect of improving wiring reliability.

In addition, in the first aspect, a width of a portion traversing the annular trench in the back surface rewiring may be thicker than other portions. This brings about an effect of improving wiring reliability.

In addition, in the first aspect, an opening having an outer periphery larger than an outer periphery of the through hole may be formed in the back surface insulating film, and the back surface rewiring around the through hole may cover the back surface inside the opening. This brings about an effect that stress is reduced and a yield is increased.

Furthermore, the first aspect may further include: an on-chip lens; a photoelectric conversion section; and an external terminal. This brings about an effect that the semiconductor device functions as a solid-state imaging device.

Furthermore, the first aspect may further include a back surface insulating film that covers the back surface of the semiconductor substrate with respect to the front surface, in which an end portion of the back surface insulating film may include a tapered shape. This brings about an effect of improving reliability.

In addition, in the first aspect, a diameter of the through hole may be 1.5 to 4.0 times a width of the annular trench. This brings about an effect of reducing the manufacturing cost.

In addition, in the first aspect, the diameter of the through hole may be 2.0 to 3.0 times the width of the annular trench. This brings about an effect of reducing the manufacturing cost.

In addition, the first aspect may further include a solder mask that covers the insulating film and the through hole, in which a cavity closed by the solder mask may be formed inside the through hole when viewed from the direction parallel to the back surface. This brings about an effect of improving reliability.

Furthermore, the first aspect may further include a low-k material formed between the through hole and the annular trench and having a dielectric constant lower than that of the semiconductor substrate. This brings about an effect of facilitating high integration.

Furthermore, the first aspect may further include a back surface insulating film that covers the back surface of the semiconductor substrate with respect to the front surface and the annular trench, in which the solder mask may further cover the back surface insulating film.

This brings about an effect of facilitating high integration.

In addition, in the first aspect, the low-k material may cover the back surface of the semiconductor substrate with respect to the front surface, and the solder mask may further cover the low-k material and the annular trench. This brings about an effect that the back surface insulating film becomes unnecessary.

Furthermore, the first aspect may further include an element isolation region formed between the wiring layer and the annular trench. This brings about an effect that the degree of freedom in the layout of the wiring layer is improved and the degree of integration of the semiconductor elements is improved.

Furthermore, in the first aspect, the wiring layer may include a dummy gate formed between the through hole and the annular trench. This brings about an effect that the forbidden region of the gate electrode is reduced.

Furthermore, the first aspect may further include: a back surface insulating film that covers the back surface of the semiconductor substrate with respect to the front surface; and an insulating reinforcing film adjacent to the wiring layer and covering the periphery of the through hole. This brings about an effect of suppressing peeling of the semiconductor substrate.

In addition, in the first aspect, the through hole may have a step at a predetermined depth position when viewed from the direction parallel to the back surface, the back surface insulating film may cover the periphery of the through hole in a range from the back surface to the depth position, and the reinforcing film may cover the periphery of the through hole in a range from the depth position to the wiring layer, and be formed between a base material of the semiconductor substrate and the through hole when viewed from the direction perpendicular. This brings about an effect of suppressing peeling of the semiconductor substrate.

In addition, in the first aspect, a cross-sectional shape of each of the through hole and the reinforcing film as viewed from the direction parallel may have a curved taper. This brings about an effect of facilitating adjustment of the cross-sectional shape at the time of etch-back.

In addition, in the first aspect, the through hole may have a step at a predetermined depth position when viewed from the direction parallel to the back surface, the reinforcing film may cover the periphery of the through hole in a range from the depth position to the wiring layer, and the back surface insulating film may cover the through hole and a periphery of the reinforcing film. This brings about an effect of suppressing peeling of the semiconductor substrate.

Furthermore, in the first aspect, a shape of the through hole may include a circle or a polygon when viewed from the direction perpendicular. This brings about an effect of suppressing peeling of the semiconductor substrate.

In addition, in the first aspect, the through hole may cover an entire circumference of the through hole when viewed from the direction perpendicular. This brings about an effect of suppressing peeling of the semiconductor substrate.

In addition, in the first aspect, the reinforcing film may cover a part of the periphery of the through hole when viewed from the direction perpendicular. This brings about an effect of suppressing the parasitic capacitance.

Furthermore, in the first aspect, a base material of the semiconductor substrate may have a step at a predetermined depth position when viewed from the direction parallel to the back surface, the back surface insulating film may cover the periphery of the through hole in a range from the back surface to the depth position, and the reinforcing film may cover the periphery of the through hole in a range from the depth position to the wiring layer. This brings about an effect that it is not necessary to provide a step in the through hole.

In addition, the first aspect may further include a first protection member disposed adjacent to the wiring layer in the annular trench. This brings about an effect of suppressing peeling of the semiconductor substrate.

Furthermore, in the first aspect, the first protection member may include an insulating resin or an inorganic film. This brings about an effect of suppressing peeling of the semiconductor substrate.

Furthermore, in the first aspect, a shape of the first protection member may be recessed toward a side of the wiring layer when viewed from the direction parallel to the back surface. This brings about an effect of being advantageous for high-speed transmission.

In addition, in the first aspect, the first protection member may cover both corners on an inner peripheral side and an outer peripheral side of the annular trench. This brings about an effect of suppressing peeling of the semiconductor substrate.

In addition, in the first aspect, the first protection member may cover only a corner on an inner peripheral side of the annular trench. This brings about an effect of being advantageous for high-speed transmission.

Furthermore, the first aspect may further include a second protection member disposed adjacent to the wiring layer in the through hole. This brings about an effect of suppressing peeling of the semiconductor substrate.

In addition, the first aspect may further include a back surface insulating film that covers the back surface of the semiconductor substrate with respect to the front surface, in which a width of the annular trench on a side of the wiring layer may be narrower than a width of the annular trench on a side of the back surface insulating film. This brings about an effect that the protection member becomes unnecessary.

In addition, in the first aspect, a cross-sectional shape of the annular trench may have a taper when viewed from the direction parallel to the back surface. This brings about an effect that the protection member becomes unnecessary.

In addition, in the first aspect, a corner of the annular trench may be rounded when viewed from the direction parallel to the back surface. This brings about an effect that the protection member becomes unnecessary.

In addition, in the first aspect, the corner may be located in the wiring layer. This brings about an effect of suppressing peeling of the semiconductor substrate.

Furthermore, in the first aspect, the corner may straddle a boundary between the semiconductor substrate and the wiring layer. This brings about an effect of suppressing peeling of the semiconductor substrate.

Further, in the first aspect, only the corner on an inner peripheral side of an inner periphery and an outer periphery of the annular trench may be rounded. This brings about an effect of suppressing peeling of the semiconductor substrate.

In addition, the first aspect may further include: an insulating film formed between the annular trench and the through hole; and an annular depletion layer formed in the insulating film. This brings about an effect of improving reliability of the device.

Furthermore, in the first aspect, the insulating film may have a predetermined number of openings formed at an end portion of the depletion layer. This brings about an effect that ring-shaped silicon is removed.

Further, in the first aspect, holes may be formed as the openings at the end portion. This brings about an effect that ring-shaped silicon is removed.

Further, in the first aspect, slits may be formed as the openings at the end portion. This brings about an effect that ring-shaped silicon is removed.

In addition, the first aspect may further include a conductive metal embedded in the annular trench. This brings about an effect of improving the strength of the semiconductor substrate.

In addition, in the first aspect, a potential of the through wiring may be different from a potential of the conductive metal. This brings about an effect of blocking an electromagnetic wave from the outside.

In addition, the first aspect may further include a first insulating film that covers a side surface of the annular trench. This brings about an effect that the conductive metal is insulated.

In addition, the first aspect may further include a second insulating film that covers the side surface of the through hole. This brings about an effect that the through wiring is insulated.

In addition, the first aspect may further include: a first barrier metal that covers a side surface of the annular trench; and a second barrier metal that covers the side surface of the through hole, in which each of the first and second barrier metals may include any one of titanium, titanium nitride, tantalum, tantalum nitride, and ruthenium. This brings about an effect of improving reliability.

In addition, in the first aspect, the conductive metal may include any of copper, aluminum, tungsten, cobalt, silver, gold, iron, and lead. This brings about an effect of blocking an electromagnetic wave from the outside.

Further, in the first aspect, the annular trench may include a first annular trench and a second annular trench formed between the first annular trench and the through hole. This brings about an effect of reducing the parasitic capacitance.

In addition, in the first aspect, the conductive metal may include a first conductive metal embedded in the first annular trench and a second conductive metal embedded in the second annular trench, and the second conductive metal may be different in type from the first conductive metal. This brings about an effect of blocking a plurality of types of electromagnetic waves.

### BRIEF DESCRIPTION OF DRAWINGS

FIG. 1 is a cross-sectional view illustrating a configuration example of a semiconductor device according to a first embodiment of the present technology.

FIG. 2 is an example of a cross-sectional view and a top view of the semiconductor device according to the first embodiment of the present technology.

FIG. 3 is a diagram for explaining a manufacturing method until etching is completed according to the first embodiment of the present technology.

FIG. 4 is a diagram for explaining the manufacturing method up to the formation of the solder mask according to the first embodiment of the present technology.

FIG. 5 is a flowchart illustrating a method for manufacturing the semiconductor device according to the first embodiment of the present technology.

FIG. 6 is an example of a cross-sectional view of a semiconductor device in which a taper is formed at an end portion of a back surface insulating film according to the first embodiment of the present technology.

FIG. 7 is an example of a cross-sectional view of a semiconductor device in which an annular trench is filled with a back surface insulating film according to the first embodiment of the present technology.

FIG. 8 is a cross-sectional view illustrating a configuration example of a semiconductor device according to a second embodiment of the present technology.

FIG. 9 is a cross-sectional view illustrating a configuration example of a semiconductor device according to a third embodiment of the present technology.

FIG. 10 is a diagram for explaining the manufacturing method according to the third embodiment of the present technology.

FIG. 11 is an example of a cross-sectional view of a semiconductor device 100 according to a fourth embodiment of the present technology.

FIG. 12 is a cross-sectional view illustrating a configuration example of a semiconductor device according to a fifth embodiment of the present technology.

FIG. 13 is an example of a top view of the semiconductor device according to the fifth embodiment of the present technology.

FIG. 14 is an example of a top view of a semiconductor device according to a sixth embodiment of the present technology.

FIG. 15 is a cross-sectional view illustrating a configuration example of a semiconductor device according to a seventh embodiment of the present technology.

FIG. 16 is an example of a top view of the semiconductor device according to the seventh embodiment of the present technology.

FIG. 17 is a cross-sectional view illustrating a configuration example of a semiconductor device according to an eighth embodiment of the present technology.

FIG. 18 is a cross-sectional view illustrating a configuration example of a semiconductor device according to a ninth embodiment of the present technology.

FIG. 19 is a cross-sectional view of the semiconductor device according to the ninth embodiment of the present technology as viewed from another direction.

FIG. 20 is a diagram for explaining the method for manufacturing up to the opening of the semiconductor substrate according to the ninth embodiment of the present technology.

FIG. 21 is a diagram for explaining the manufacturing method up to etch back according to the ninth embodiment of the present technology.

FIG. 22 is a diagram for explaining the method for manufacturing up to the opening of the back surface insulating film according to the ninth embodiment of the present technology.

FIG. 23 is a diagram for explaining the manufacturing method up to the formation of the solder mask according to the ninth embodiment of the present technology.

FIG. 24 is a diagram for explaining the manufacturing method up to the formation of the trench according to the ninth embodiment of the present technology.

FIG. 25 is a diagram for explaining the manufacturing method up to the formation of the wiring layer according to the ninth embodiment of the present technology.

FIG. 26 is a diagram for explaining the manufacturing method up to the formation of the back surface insulating film according to the ninth embodiment of the present technology.

FIG. 27 is a diagram for explaining the method for manufacturing up to rewiring according to the ninth embodiment of the present technology.

FIG. 28 is a cross-sectional view of the semiconductor device in a case where annular trenches are disposed according to the ninth embodiment of the present technology.

FIG. 29 is a cross-sectional view illustrating a configuration example of a semiconductor device in a first modification of the ninth embodiment of the present technology.

FIG. 30 is a cross-sectional view illustrating a configuration example of a semiconductor device in a second modification of the ninth embodiment of the present technology.

FIG. 31 is a cross-sectional view illustrating a configuration example of a semiconductor device in a third modification of the ninth embodiment of the present technology.

FIG. 32 is a diagram for explaining the method for manufacturing up to the opening of the semiconductor substrate in the third modification of the ninth embodiment of the present technology.

FIG. 33 is a diagram for explaining the manufacturing method up to the film formation of the reinforcing film in the third modification of the ninth embodiment of the present technology.

FIG. 34 is a diagram for explaining the method for manufacturing up to the opening of the back surface insulating film in the third modification of the ninth embodiment of the present technology.

FIG. 35 is a diagram for explaining the manufacturing method up to the formation of the solder mask in the third modification of the ninth embodiment of the present technology.

FIG. 36 is a cross-sectional view illustrating a configuration example of a semiconductor device in a fourth modification of the ninth embodiment of the present technology.

FIG. 37 is a cross-sectional view illustrating a configuration example of a semiconductor device in a fifth modification of the ninth embodiment of the present technology.

FIG. 38 is a cross-sectional view illustrating a configuration example of a semiconductor device according to a 10th embodiment of the present technology.

FIG. 39 is a diagram for explaining the effect of the semiconductor device according to the 10th embodiment of the present technology.

FIG. 40 is a diagram for explaining the manufacturing method until etching is completed according to the 10th embodiment of the present technology.

FIG. 41 is a diagram for explaining the manufacturing method up to the formation of the resin according to the 10th embodiment of the present technology.

FIG. 42 is a diagram for explaining the method for manufacturing up to rewiring according to the 10th embodiment of the present technology.

FIG. 43 is a cross-sectional view illustrating an arrangement example of resin according to the 10th embodiment of the present technology.

FIG. 44 is an example of a cross-sectional view of the semiconductor device in which an inorganic film is disposed according to the 10th embodiment of the present technology.

FIG. 45 is a cross-sectional view illustrating a configuration example of a semiconductor device in a first modification of the 10th embodiment of the present technology.

FIG. 46 is an example of an enlarged view of the semiconductor device in the first modification of the 10th embodiment of the present technology.

FIG. 47 is a cross-sectional view illustrating a configuration example of a semiconductor device in a second modification of the 10th embodiment of the present technology.

FIG. 48 is an example of an enlarged view of the semiconductor device in the second modification of the 10th embodiment of the present technology.

FIG. 49 is an example of an enlarged view of a semiconductor device in a comparative example.

FIG. 50 is another example of an enlarged view of the semiconductor device in the second modification of the 10th embodiment of the present technology.

FIG. 51 is a cross-sectional view illustrating a configuration example of a semiconductor device according to a 11th embodiment of the present technology.

FIG. 52 is an example of a cross-sectional view of the semiconductor device according to the 11th embodiment of the present technology when viewed from another direction.

FIG. 53 is a diagram for explaining the method for manufacturing up to the opening of the semiconductor substrate according to the 11th embodiment of the present technology.

FIG. 54 is a diagram for explaining the method for manufacturing up to the opening of the insulating film according to the 11th embodiment of the present technology.

FIG. 55 is a diagram for explaining the manufacturing method up to coating and exposure of the back surface insulating film according to the 11th embodiment of the present technology.

FIG. 56 is a diagram for explaining the method for manufacturing up to rewiring according to the 11th embodiment of the present technology.

FIG. 57 is an example of a cross-sectional view of a semiconductor device in a first modification of the 11th embodiment of the present technology.

FIG. 58 is an example of a cross-sectional view of a semiconductor device in a second modification of the 11th embodiment of the present technology.

FIG. 59 is a diagram illustrating an example in which an ideal through hole is formed according to the second embodiment of the present technology.

FIG. 60 is a diagram illustrating an example in which a notch is generated according to the second embodiment of the present technology.

FIG. 61 is a diagram illustrating an example in which silicon has a trailing shape according to the second embodiment of the present technology.

FIG. 62 is an example of a cross-sectional view of a semiconductor device before formation of a through hole according to a 12th embodiment of the present technology.

FIG. 63 is a diagram for explaining the method for manufacturing the semiconductor device up to etch-back according to the 12th embodiment of the present technology.

FIG. 64 is an enlarged view of the vicinity of an element isolation region according to the 12th embodiment of the present technology.

FIG. 65 is an example of a cross-sectional view of a semiconductor device in a first modification of the 12th embodiment of the present technology.

FIG. 66 is an example of a cross-sectional view of a semiconductor device in a second modification of the 12th embodiment of the present technology.

FIG. 67 is a cross-sectional view illustrating a configuration example of a semiconductor device according to a 13th embodiment of the present technology.

FIG. 68 is a diagram for explaining the manufacturing method up to exposure according to the 13th embodiment of the present technology.

FIG. 69 is a diagram for explaining the manufacturing method up to ion implantation according to the 13th embodiment of the present technology.

FIG. 70 is a diagram for explaining the manufacturing method up to the formation of the solder mask according to the 13th embodiment of the present technology.

FIG. 71 is a cross-sectional view illustrating a configuration example of a semiconductor device in a modification of the 13th embodiment of the present technology.

FIG. 72 is a diagram for explaining the manufacturing method up to the application of the low-k material in the modification of the 13th embodiment of the present technology.

FIG. 73 is a diagram for explaining the manufacturing method up to the opening of the pad in the modification of the 13th embodiment of the present technology.

FIG. 74 is a diagram for explaining the manufacturing method up to the formation of the solder mask in the modification of the 13th embodiment of the present technology.

FIG. 75 is a cross-sectional view illustrating a configuration example of a semiconductor device according to a 14th embodiment of the present technology.

FIG. 76 is an example of a cross-sectional view of the semiconductor device taken along line segments A1-A2 and B1-B2 according to the 14th embodiment of the present technology.

FIG. 77 is an example of a cross-sectional view of the semiconductor device taken along a line segment C1-C2 according to the 14th embodiment of the present technology.

FIG. 78 is a diagram for explaining the method for manufacturing the semiconductor device up to the first application of the insulating film according to the 14th embodiment of the present technology.

FIG. 79 is a diagram for explaining the method for manufacturing the semiconductor device up to the second application of the insulating film according to the 14th embodiment of the present technology.

FIG. 80 is a diagram for explaining the method for manufacturing the semiconductor device up to the formation of the solder mask according to the 14th embodiment of the present technology.

FIG. 81 is a cross-sectional view illustrating a configuration example of a semiconductor device in a first modification of the 14th embodiment of the present technology.

FIG. 82 is an example of a cross-sectional view of the semiconductor device taken along line segments A1-A2 and B1-B2 in the first modification of the 14th embodiment of the present technology.

FIG. 83 is an example of a cross-sectional view of the semiconductor device taken along a line segment C1-C2 in the first modification of the 14th embodiment of the present technology.

FIG. 84 is a cross-sectional view illustrating a configuration example of a semiconductor device in a second modification of the 14th embodiment of the present technology.

FIG. 85 is an example of a cross-sectional view of the semiconductor device taken along line segments A1-A2 and B1-B2 in the second modification of the 14th embodiment of the present technology.

FIG. 86 is an example of a cross-sectional view of the semiconductor device taken along a line segment C1-C2 in the second modification of the 14th embodiment of the present technology.

FIG. 87 is a block diagram depicting a schematic configuration example of a vehicle control system.

FIG. 88 is a diagram of assistance in explaining an example of an installation position of an imaging section.

### MODE FOR CARRYING OUT THE INVENTION

Modes for carrying out the present technology (hereinafter, referred to as embodiments) will be described below. The description will be given in the following order.
1. First Embodiment (Example in which cavity is provided in annular trench)
2. Second Embodiment (Example in which cavity is provided in annular trench and back surface insulating film is formed into two layers)
3. Third Embodiment (Example in which through electrode provided with cavity in annular trench and through electrode without annular trench are disposed)
4. Fourth Embodiment (Example in which cavity is provided in annular trench and adjacent through electrodes share part)
5. Fifth Embodiment (Example in which cavity is provided in annular trench and annular trench is covered with back surface rewiring)
6. Sixth Embodiment (Example in which cavity is provided in annular trench and part of back surface rewiring is thickened)
7. Seventh Embodiment (Example in which cavity is provided in annular trench and back surface rewiring covers inner side of back surface insulating film)
8. Eighth Embodiment (Example in which structure in which cavity is provided in annular trench is applied to solid-state imaging device)
9. Ninth Embodiment (Example in which cavity is provided in annular trench and through hole is covered with reinforcing film)
10. 10th Embodiment (Example in which cavity is provided in annular trench and resin is disposed in annular trench)
11. 11th Embodiment (Example in which cavity is provided in annular trench and depletion layer is formed in insulating film)
12. 12th Embodiment (Example in which cavity is provided in annular trench and ring-shaped element isolation region is disposed)
13. 13th Embodiment (Example in which cavity is provided in annular trench and ring-shaped low-k material is disposed)
14. 14th Embodiment (Example in which conductive metal is embedded in annular trench)
15. Application Example to Mobile Body

### 1. First Embodiment

### Configuration Example of Semiconductor Device

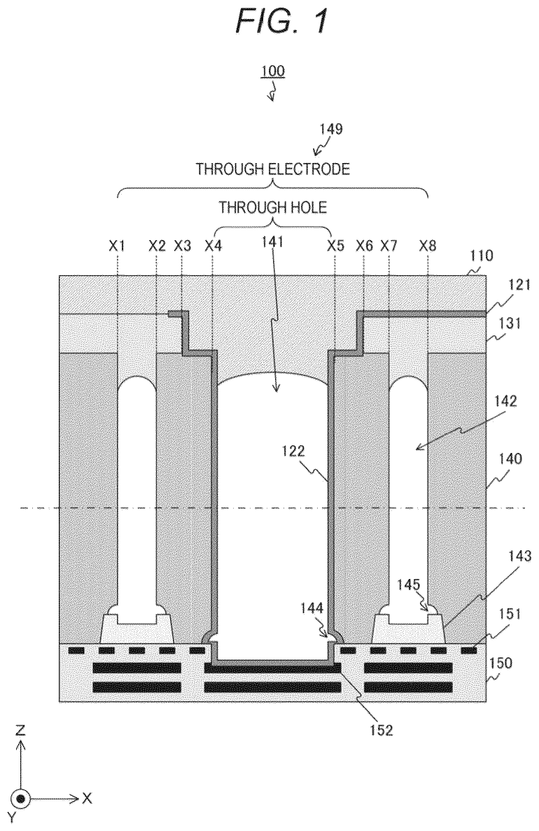

FIG. 1 is a cross-sectional view illustrating a configuration example of a semiconductor device 100 according to an embodiment of the present technology. This cross-sectional view is an enlarged view of the vicinity of a through electrode 149 in the semiconductor device 100. The semiconductor device 100 includes a semiconductor substrate 140. A semiconductor element (not illustrated) and a wiring layer 150 are formed on one of both surfaces of the semiconductor substrate 140. Of both surfaces of the semiconductor substrate 140, a surface on which the wiring layer 150 is formed is hereinafter referred to as a “front surface”, and the other surface is hereinafter referred to as a “back surface”. A direction from the front surface to the back surface is defined as an “up” direction. Furthermore, the semiconductor device 100 functions as a signal processing circuit, a memory, an image sensor, and the like, and the type thereof is not limited.

Hereinafter, an axis perpendicular to a substrate plane (front surface or back surface) of the semiconductor substrate 140 is referred to as a “Z axis”, and a predetermined axis parallel to the surface is referred to as an “X axis”. An axis perpendicular to the X axis and the Z axis is referred to as a “Y axis”. The figure is a cross-sectional view as viewed from the Y-axis direction.

In addition, the through electrode 149 is formed on the semiconductor substrate 140.

The through electrode 149 includes a through hole 141 penetrating the semiconductor substrate 140, a through wiring 122 formed along a side surface of the through hole 141, and an annular trench 142 surrounding the periphery of the through hole when viewed from the Z-axis direction. In the X-axis direction, coordinates X1 to X8 correspond to the outer diameter of the annular trench 142, that is, the diameter of the through electrode 149. Further, coordinates X2 to X7 correspond to the inner diameter of the annular trench 142. The coordinates X4 to X5 correspond to the diameter of the through hole 141.

In addition, the through wiring 122 is connected to a pad 152 formed in the wiring layer 150 on the front surface side and the back surface rewiring 121 wired on the back surface. As a material of the through wiring 122, copper (Cu), titanium (Ti), tantalum (Ta), aluminum (Al), tungsten (W), nickel (Ni), ruthenium (Ru), cobalt (Co), titanium nitride (TiN), tantalum nitride (TaN), tungsten nitride (WN), or the like is used. Note that the through wiring 122 may have a structure in which a plurality of materials is laminated.

The annular trench 142 preferably has an aspect ratio between a depth and a width of about 3 to 20 when viewed from the X-axis direction or the Y-axis direction from the viewpoint of reliability and ease of manufacturing. In addition, the diameter of the through hole 141 is preferably 1.5 times to 4.0 times, and most preferably 2.0 times to 3.0 times the width of the annular trench 142. As a result, since the through hole 141 and the annular trench 142 can be processed at substantially the same speed during dry etching, they can be formed in the same process.

Further, the annular trench 142 and the through hole 141 may not have the same size in the semiconductor device 100. The width of the annular trench 142 can be increased in the signal wiring in which the parasitic capacitance is desired to be as small as possible, and the width of the annular trench 142 can be decreased in a portion in which the degree of integration of the through electrodes 149 is desired to be increased. This makes it possible to achieve both the performance and the degree of integration of the through electrode 149.

In addition, a notch 144 is formed at the bottom portion of the through hole 141 and a notch 145 is formed at the bottom portion of the annular trench 142 with end portions on the front surface side of the through hole 141 and the annular trench 142 as the bottom portions.

Processing shapes of the through hole 141 and the annular trench 142, for example, a processing angle and a size of notching of the bottom portion may be different. In a case where the through hole 141 has a smaller forward taper or notching, it is advantageous for forming the through wiring 122. On the other hand, reducing the forward taper or notching of the annular trench 142 is advantageous for the mechanical stress applied to the annular trench 142. In addition, the processing angle may change from the middle of the annular trench 142 or the through hole 141.

The back surface insulating film 131 is formed so as to cover the entire back surface of the semiconductor substrate 140 and a part of the through electrode 149. When viewed from the Y-axis direction, a cavity closed by the back surface insulating film 131 is formed inside the annular trench 142.

As the back surface insulating film 131, a photosensitive insulating film constituted by an organic material having a skeleton of polyimide, acrylic, silicone, or an epoxy group can be formed by a lithography method. This makes it possible to simplify the manufacturing process as will be described later. The back surface insulating film 131 may be constituted by a single material, or a plurality of materials may be laminated as described later. In addition, it may have a laminated structure with inorganic films. The area of the back surface insulating film 131 covering the through electrode 149 is preferably about 20 to 80% (%) of the through electrode, and desirably 30 to 65% (%) when viewed from the Z-axis direction.

In order to adjust the area where the back surface insulating film 131 covers the through electrode 149, an opening slightly larger than the diameter of the through hole 141 is formed in the back surface insulating film 131 at a portion of the through hole 141 when viewed from the Z-axis direction. With this structure, a step is generated in the back surface insulating film 131 when viewed from the Y-axis direction. In the figure, a step is generated between the coordinate X3 and the coordinate X6.

In addition, a part of the back surface insulating film 131 may enter the inside of the annular trench 142. In addition, the entering back surface insulating film 131 may have a dome shape when viewed from the X-axis direction or the Y-axis direction. As an example, an entry depth of about 5 to 40% (%) of the trench is preferable from the viewpoint of yield, reliability, and parasitic capacitance.

The back surface rewiring 121 is formed along the periphery of the through hole 141 and the side surface and the upper surface of the back surface insulating film 131. Since there is a step on the back surface insulating film 131, a step is also generated on the back surface rewiring 121. The through wiring 122 and the back surface rewiring 121 may be formed by the same process. In the case of being formed by the same process, there is no bonding surface with the through wiring 122, which is advantageous from the viewpoint of resistance and reliability. As a material of the back surface rewiring 121, copper (Cu), titanium (Ti), tantalum (Ta), aluminum (Al), tungsten (W), nickel (Ni), ruthenium (Ru), cobalt (Co), titanium nitride (TiN), tantalum nitride (TaN), tungsten nitride (WN), or the like is used. Note that the back surface rewiring 121 may have a structure in which a plurality of materials is laminated.

In addition, a solder mask 110 is formed as a protective film on the back surface rewiring 121 and the upper surface of the back surface insulating film 131. A part of the solder mask 110 enters the through hole 141, and a cavity closed by the solder mask 110 is formed inside the through hole 141. As illustrated in the figure, the entry depth of a part of the through hole 141, preferably about 5 to 40% (%) is preferable from the viewpoint of yield and reliability.

Furthermore, on the front surface side of the semiconductor substrate 140, an element isolation region 143 (shallow trench isolation (STI)) is formed between the annular trench 142 and the wiring layer 150 as necessary. Note that the element isolation region 143 is an example of a second element isolation region described in the claims. In the figure, the STI is disposed only immediately below the annular trench 142, but the present invention is not limited to this configuration. For example, the STI may be further disposed between the annular trench 142 and the through hole 141 (coordinates X2 to X4 and coordinates X5 to X7). Thus, the through hole 141 can be formed by self-alignment. The STI can also be formed between the annular trench 142 and the through hole 141. Furthermore, in the wiring layer 150, a dummy gate 151 is formed in the vicinity of the annular trench 142 as necessary. For example, the dummy gate 151 is formed at the lower portion of the annular trench 142 and between the through hole 141 and the annular trench 142. When the STI is disposed at the bottom portion of the annular trench 142, the STI serves as an etching stopper, so that the degree of freedom in layout of the wiring layer 150 is improved, and the degree of integration of semiconductor elements is improved.

In addition, the pad 152 in the wiring layer 150 may be formed only inside the annular trench 142. As a result, the parasitic capacitance between the pad 152 and the semiconductor substrate 140 can be reduced.

In addition, disposing the dummy gate 151 between the through hole 141 and the annular trench 142 makes it possible to reduce the forbidden region of the gate electrode. This improves the flatness when the wiring layer 150 is formed on the front surface, and in particular, in the entire process, the fine wiring can be disposed in the vicinity of the through electrode 149. The dummy gate 151 may be constituted by polycrystalline silicon, amorphous silicon, or other materials.

In summary, the through hole 141 penetrates the semiconductor substrate 140 having the wiring layer 150 formed on the front surface, and the through wiring 122 is formed along the side surface of the through hole 141. The annular trench 142 is formed so as to surround the periphery of the through hole 141 when viewed from the Z-axis direction perpendicular to the back surface. The back surface insulating film 131 covers the back surface of the semiconductor substrate 140, and a cavity closed by the back surface insulating film 131 when viewed from the X-axis direction and the Y-axis direction parallel to the back surface is formed inside the annular trench 142.

Here, a structure in which the through hole 141 and the annular trench 142 are filled with the solder mask 110 and the back surface insulating film 131 to eliminate the cavity is assumed as a comparative example. In the comparative example, since the parasitic capacitance increases and the solder mask 110 and the back surface insulating film 131 flow into the through hole 141 and the annular trench 142, the flatness of the upper surface may be deteriorated. In addition, the back surface insulating film 131 once enters the through hole 141 at the time of manufacturing, and it is necessary to remove the back surface insulating film 131 by lithography, but it is difficult to completely remove the back surface insulating film 131. Due to these factors, the yield may be lowered. In addition, keep out zone (KOZ), which is a design exclusion region around the through electrode for device characteristic guarantee, becomes large, which may increase stress and manufacturing cost.

On the other hand, in the figure, since a cavity is left inside the through hole 141 or the annular trench 142, it is possible to increase the yield and improve the reliability as compared with the comparative example. Furthermore, the KOZ can be reduced to reduce stress and manufacturing cost.

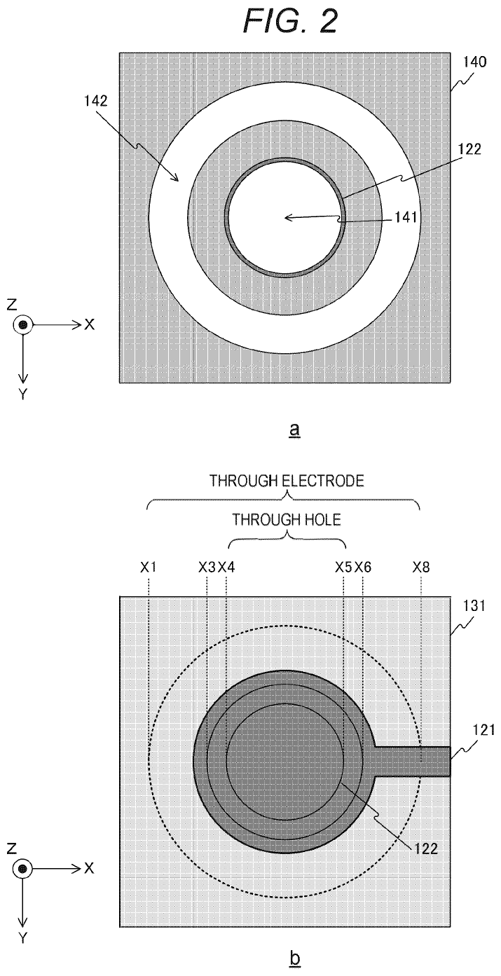

FIG. 2 is an example of a cross-sectional view and a top view of the semiconductor device 100 according to the first embodiment of the present technology. a in the figure is a cross-sectional view of the semiconductor device 100 taken along an alternate long and short dash line in FIG. 1 when viewed from the Z-axis direction. b of FIG. 2 illustrates a top view of the semiconductor device 100 in a state before being covered with the solder mask 110.

As exemplified in a of FIG. 2, the cross-sectional shape of the through hole 141 is circular, and the annular trench 142 around the through hole 141 has a ring shape.

A circular dotted line in b of FIG. 2 indicates the outer periphery of the through electrode 149, that is, the outer periphery of the annular trench 142. As exemplified in b of the figure, the back surface insulating film 131 covers the periphery of a circular opening having an outer diameter larger than that of the through hole 141. In addition, the through wiring 122 is formed in the through hole 141, and the back surface rewiring 121 is formed along the periphery of the through hole 141 and the upper surface of the back surface insulating film 131. In addition, the back surface rewiring 121 on the upper surface of the back surface insulating film 131 is formed along a linear path.

The inside of a circle having a diameter from the coordinates X4 to the coordinates X5 indicates a region of the through wiring 122, and a circle having a diameter from the coordinates X3 to X6 indicates a step of the back surface rewiring 121 due to a step of the back surface insulating film 131.

### Method for Manufacturing Semiconductor Device

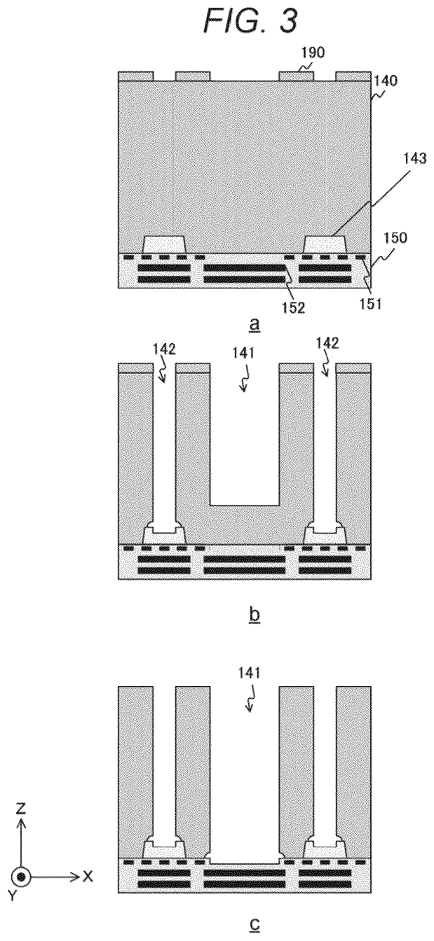

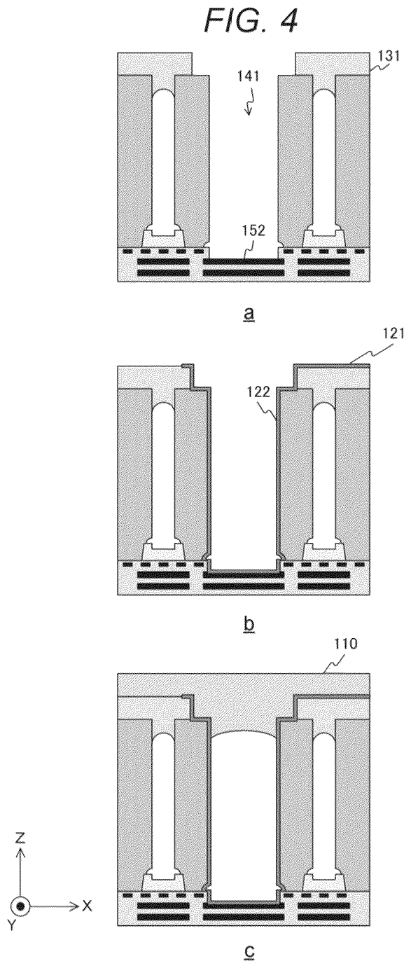

FIGS. 3 and 4 illustrate a method for manufacturing the semiconductor device 100 according to the first embodiment of the present technology.

First, as exemplified in a of FIG. 3, on the front surface side of the semiconductor substrate 140, the pad 152 is formed at the position of the subsequent through wiring 122, and the element isolation region 143 is formed at the position of the annular trench 142. In addition, the dummy gate 151 is formed up to the position of the annular trench 142. Furthermore, the semiconductor substrate 140 is thinned from the back surface side, and a resist mask 190 is formed at a position other than the positions where the through hole 141 and the annular trench 142 are processed by lithography.

Next, as exemplified in b of the figure, the through hole 141 and the annular trench 142 are formed by dry etching. b in the figure illustrates a state in the middle of processing, and is an example of a case where the processing speed on the trench side is higher than the etching speed of the through hole 141. The etching speed of the through hole 141 and the annular trench 142 depends on the aspect ratio and the processing conditions.

Next, as exemplified in c of the figure, dry etching proceeds until the through hole 141 penetrates the semiconductor substrate 140. Thereafter, the resist mask 190 is removed by ashing or the like. When the through hole 141 penetrates the semiconductor substrate 140, it is possible to perform the end point detection of etching by a change in plasma emission state or the like. For example, the end point detection is performed at the timing when the through hole 141 penetrates, and the plasma etching condition can be changed to a condition in which the notching is less likely to occur or a condition in which the processing is performed in a forward taper. Specifically, as a manufacturing method for reducing the notching, there are a method of increasing the side wall protective component, a method of reducing the processing amount per cycle in the case of processing by the Bosch process, and the like. As a result, the processing shape of the bottom portion of the through hole 141 can be more stably and precisely controlled, so that the through wiring 122 can be easily formed in the subsequent process. In addition, it is also possible to optimize the shapes of the annular trench 142 and the through hole 141.

Next, as exemplified in a of FIG. 4, after the photosensitive insulating resin is formed on the entire surface as the back surface insulating film 131, the photosensitive resin between a part of the through electrode 149 on the side of the through hole 141 and the through hole 141 is removed by a lithography method, and is made into a permanent resin by annealing. Further, the entire surface is etched back, and the through hole 141 is connected to the pad 152 on the front surface side. As a method for forming the back surface insulating film 131, a lamination method or a coating method can be used. For example, in the case of the coating method, the entry depth into the annular trench 142 can be controlled by optimizing the viscosity of the resin.

Next, as exemplified in b of the figure, the back surface rewiring 121 and the through wiring 122 are simultaneously formed by a semi-additive method. As an example of the semi-additive method, a method is used in which a barrier metal film and a seed metal film are formed, a resist mask is then formed by a lithography method, and wiring is formed by electroplating at a portion where the resist mask is not disposed. Thereafter, the resist mask is removed, and the barrier metal film and the seed metal film are removed by full-surface etch-back, thereby forming the back surface rewiring 121.

Next, as exemplified in c of the figure, the solder mask 110 is formed. Although not illustrated, a part of the solder mask 110 may be removed so that the back surface rewiring 121 is exposed, and an external connection terminal may be connected to the back surface rewiring 121.

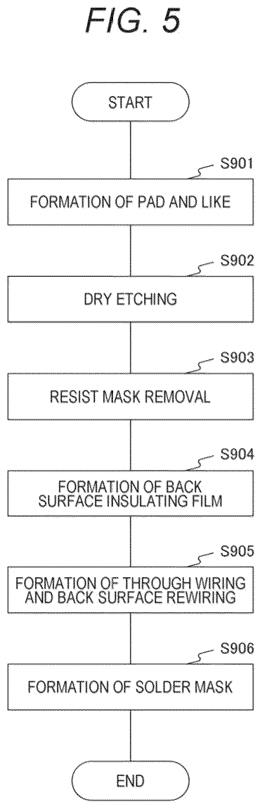

FIG. 5 is a flowchart illustrating a method for manufacturing the semiconductor device 100 according to the first embodiment of the present technology. The manufacturing system of the semiconductor device 100 forms the pad 152 and the like (step S901), and forms the annular trench 142 together with the through hole 141 by dry etching (step S902). At the end of the dry etching, the manufacturing system removes the resist mask (step S903) and forms the back surface insulating film 131 (step S904). Then, the manufacturing system forms the back surface rewiring 121 together with the through wiring 122 (step S905), and forms the solder mask 110 (step S906). After step S906, the manufacturing system performs other necessary steps, and ends the manufacturing process.

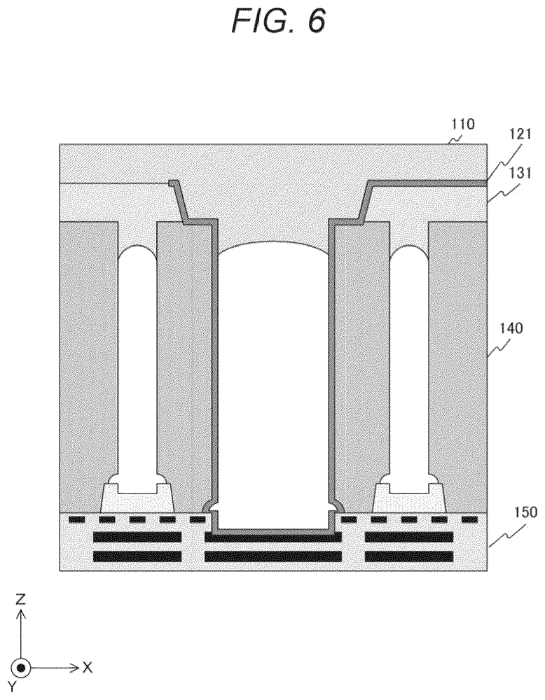

Note that, as exemplified in FIG. 6, the end portion of the back surface insulating film 131 may have a forward tapered shape. At this time, it is preferable that the upper end (solder mask 110 side) and the lower end (semiconductor substrate 140 side) of the back surface insulating film 131 fall within the width of the annular trench 142 from the viewpoint of yield and reliability.

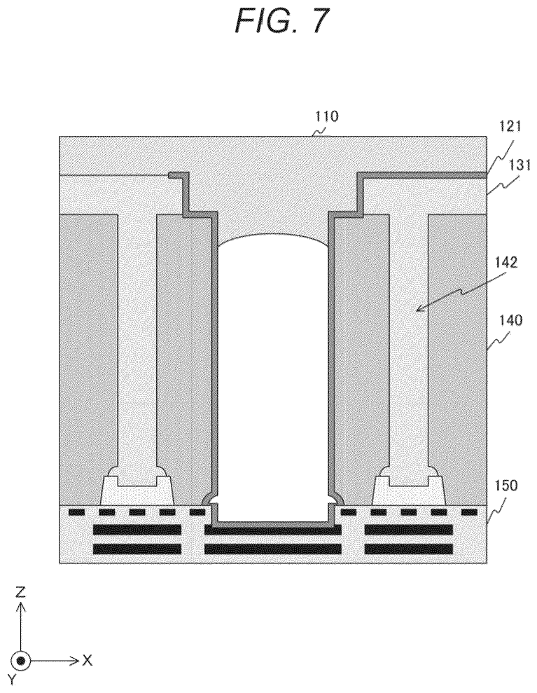

In addition, as exemplified in FIG. 7, the annular trench 142 can also be filled with the back surface insulating film 131. As a result, depending on the size, the manufacturing becomes easy, and the insulation property is also improved. In addition, there is also a case where resistance to mechanical stress is increased.

As described above, according to the first embodiment of the present technology, since the cavity remains inside the annular trench 142, the yield can be improved. In addition, stress and manufacturing cost can be reduced.

### 2. Second Embodiment

In the first embodiment described above, the back surface insulating film is a single layer, but with this configuration, it is difficult to further improve the insulation property of the annular trench 142 and the resistance to mechanical stress. A semiconductor device 100 according to a second embodiment is different from that of the first embodiment in that the back surface insulating film has two layers.

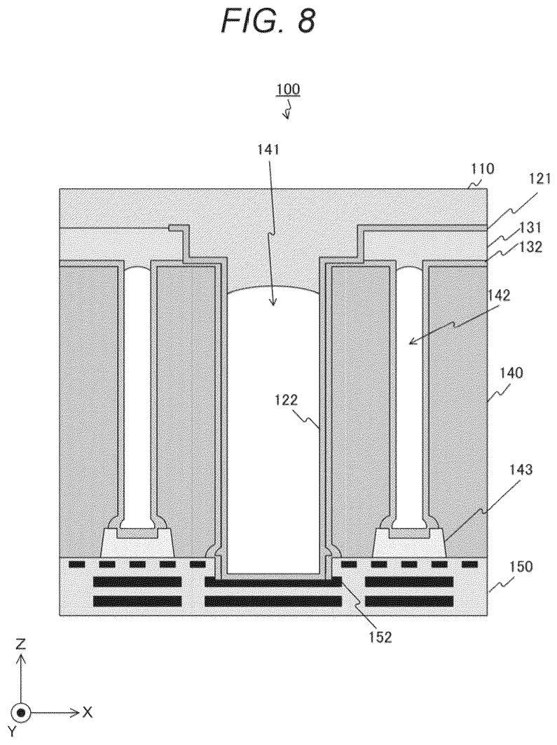

FIG. 8 is a cross-sectional view illustrating a configuration example of the semiconductor device 100 according to the second embodiment of the present technology. A feature of the second embodiment is that a plurality of back surface insulating films is laminated. For example, the back surface insulating film 132 is laminated on the back surface insulating film 131.

Preferably, the back surface insulating film 132 is formed up to the inside of the back surface of the semiconductor substrate 140, the annular trench 142 or the through hole 141, or both of them. The back surface insulating film 131 is formed in a region similar to that of the first embodiment. Each of the back surface insulating films 131 and 132 may be formed by laminating a plurality of materials. Note that the back surface insulating film 131 is an example of a first back surface insulating film described in the claims, and the back surface insulating film 132 is an example of a second back surface insulating film described in the claims.

As the back surface insulating film 132, silicon dioxide (SiO₂), silicon nitride (SiN), silicon oxynitride (SiON), or a fixed charge film is used. As a fixed charge film, HfO₂ (hafnium oxide), Al₂O₃ (aluminum oxide), ZrO (zirconium oxide), Ta₂O₅ (tantalum oxide), titanium oxide (TiO₂ (titanium oxide), LaO₃ (lanthanum oxide), Pr₆O₁₁ (praseodymium oxide), CeO₂ (cerium oxide), Nd₂O₃ (neodymium oxide), Pm₂O₃ (promethium oxide), Sm₂O₃ (samarium oxide), Eu₂O₃ (europium oxide), GdO₃ (gadolinium oxide), Tb₂O₃ (terbium oxide), Dy₂O₃ (dysprosium oxide), Ho₂O₃ (holmium oxide), Tm₂O₃ (thulium oxide), Yb₂O₃ (ytterbium oxide), Lu₂O₃ (lutetium oxide), Y₂O₃ (yttrium oxide), AlN (aluminum nitride), HfON (hafnium oxynitride), AlON (aluminum oxynitride), and the like can be used. Similarly to the first embodiment, the upper portion of the annular trench 142 may be closed by the back surface insulating film 131. As the back surface insulating film 131, a photosensitive insulating film constituted by an organic material having a skeleton of polyimide, acrylic, silicone, or an epoxy group can be used similarly to the first embodiment.

In the structure of the second embodiment, the insulation property of the annular trench 142 can be enhanced by the back surface insulating film 132. In addition, resistance to mechanical stress can be enhanced. In particular, a high effect can be obtained by closing the notching with a film having good coverage. In addition, by introducing the fixed charge film, it is possible to reduce the influence of defects on the interface and the front surface being noise and a leak source. In addition, it is also possible to control the balance of mechanical stress by disposing the back surface insulating film 132 having different films or different film thicknesses in the through hole 141 and the annular trench 142.

As described above, according to the second embodiment of the present technology, since the two layers of the back surface insulating films 131 and 132 are laminated on the back surface, it is possible to improve the insulation property of the annular trench 142 and the resistance to mechanical stress.

### 3. Third Embodiment

In the second embodiment described above, the annular trench 142 is formed around the through hole 141 in the through electrode 149, but if the annular trench 142 is provided in all the through electrodes, it may be difficult to achieve high integration. A semiconductor device 100 according to a third embodiment is different from that of the second embodiment in that through electrodes in which annular trenches 142 are formed and through electrodes without annular trenches are mixed.

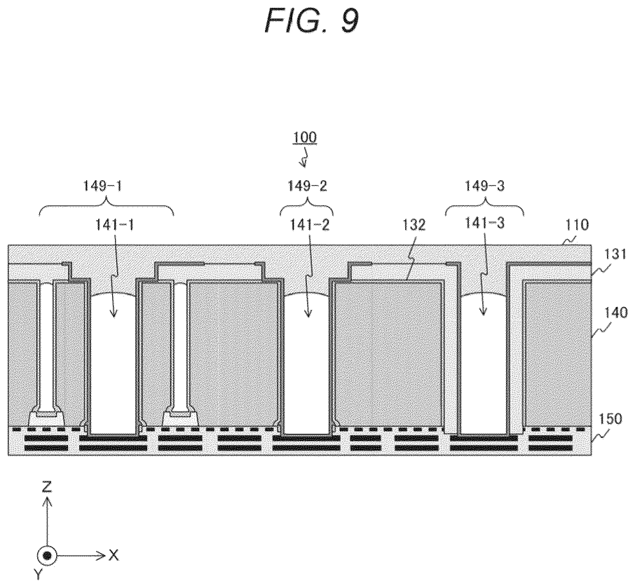

FIG. 9 is a cross-sectional view illustrating a configuration example of the semiconductor device 100 according to the third embodiment of the present technology. A feature of the third embodiment is that the third embodiment has a structure of a plurality of through electrodes. In the semiconductor device 100 of the third embodiment, through electrodes 149-1, 149-2, 149-3, and the like are formed.

The through electrode 149-1 has a structure similar to that of the second embodiment, an annular trench for separating the semiconductor substrate 140 is formed, and a through wiring is disposed inside the through hole 141-1.

In the through electrode 149-2, there is no annular trench around the through hole 141-2, and insulation between the through wiring and the semiconductor substrate is performed by the back surface insulating film 132. In addition, the through electrode 149-3 has a structure in which the back surface insulating film 132 and the back surface insulating film 131 are laminated between the side wall of the through hole 141-3 and the semiconductor substrate 140. The structure in the figure is merely an example, and other combinations can be adopted.

In the structure of the third embodiment, an optimum shape can be taken according to the purpose of the through electrode in one die. For example, in a case where wiring delay is regarded as important, the through electrode 149-1 provided with an annular trench is used, and in a case where high integration is regarded as important, the through electrode 149-2 or 149-3 without an annular trench is used, so that a structure having both signal transmission performance and integration can be obtained.

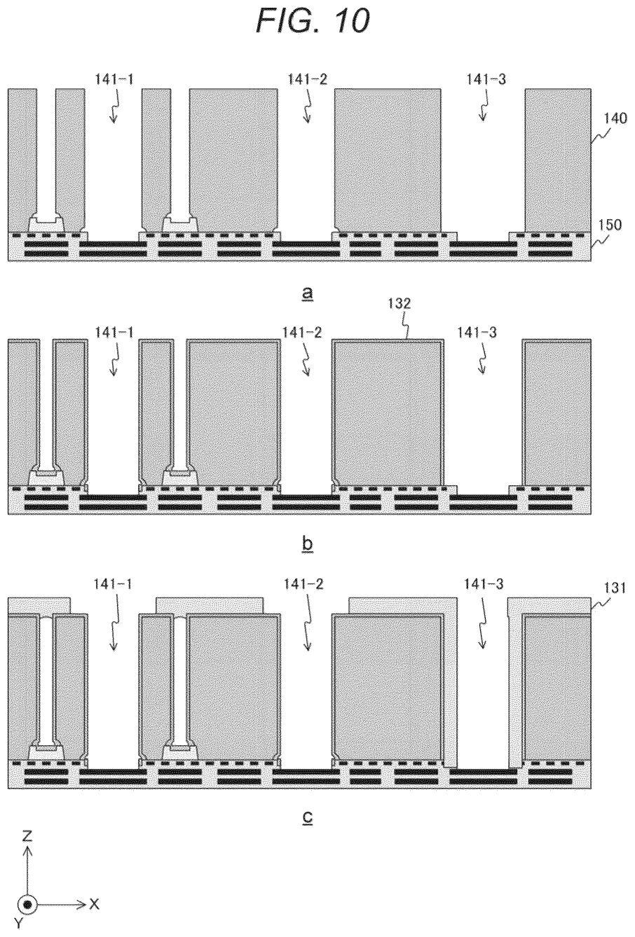

FIG. 10 illustrates a method for manufacturing the semiconductor device 100 of the third embodiment. a in the figure corresponds to c in FIG. 3 of the first embodiment. However, no annular trench is formed around the through holes 141-2 and 141-3.

Next, as exemplified in b of FIG. 10, an inorganic insulating film, for example, a SiO2 film is formed on the entire surface including the annular trench and the through hole as the back surface insulating film 132 by an atomic layer deposition (ALD) method or a plasma enhanced chemical vapor deposition (PE-CVD) method.

Next, as exemplified in c of the figure, a photosensitive insulating resin is formed on the entire surface as the back surface insulating film 131, and a part of the annular semiconductor substrate and the photosensitive resin in the through hole are removed by a lithography method. For the through hole 141-3, film formation conditions and a mask pattern for lithography are adjusted so that the back surface insulating film 131 is also formed on the side surface. Further, the entire surface is etched back, and each through hole is connected to the pad on the front surface side.

Thereafter, similarly to b and c of FIG. 4 of the first embodiment, the through wiring 122, the back surface rewiring 121, and the solder mask 110 are formed, and the structure of FIG. 9 is obtained.

By the manufacturing method as described above, it is possible to simultaneously form a plurality of types of through electrodes without adding a manufacturing process to the second embodiment.

As described above, according to the third embodiment of the present technology, since the through electrodes 149-1 in which the annular trenches 142 are formed and the through electrodes 149-2 and 149-3 without the annular trenches are provided, it is possible to achieve both signal transmission performance and integration.

### 4. Fourth Embodiment

In the first embodiment described above, the annular trench 142 is formed around the through hole 141 in the through electrode 149, but when a plurality of through electrodes is arranged, it may be required to reduce the pitch. A semiconductor device 100 according to a fourth embodiment is different from that of the first embodiment in that two adjacent through electrodes share a part of an annular trench.

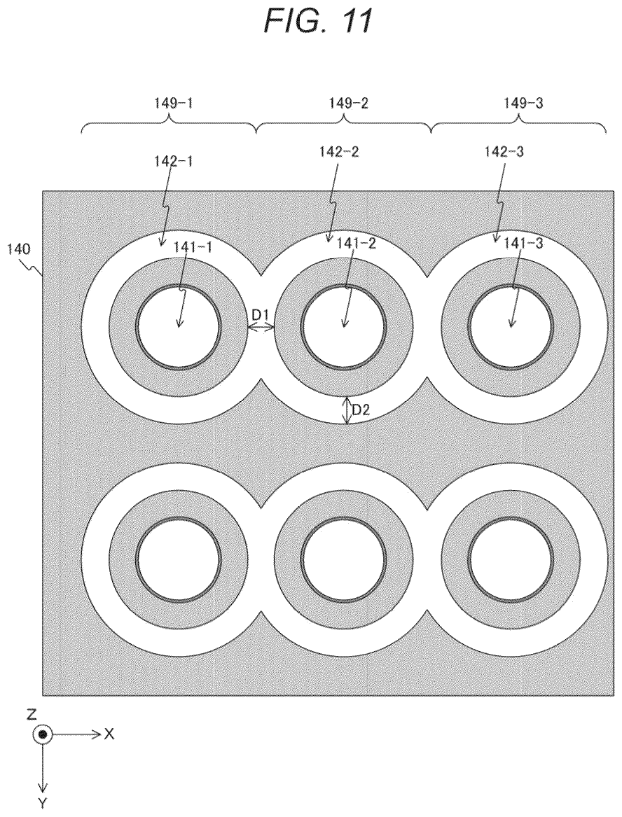

FIG. 11 is an example of a cross-sectional view of the semiconductor device 100 as viewed from the Z-axis direction according to the fourth embodiment of the present technology.

A plurality of through electrodes such as the through electrodes 149-1, 149-2, and 149-3 is arranged in the X-axis direction and the Y-axis direction. Annular trenches such as annular trenches 142-1, 142-2, and 142-3 are formed around respective through holes of the through electrodes. Two adjacent through electrodes arranged in the X-axis direction share a part of an annular trench. For example, in the through electrodes 149-1 and 149-2, the annular trench 142-1 and the annular trench 142-2 are partially shared. As a result, the pitch of the through electrodes can be reduced.

Note that, in the figure, the through electrodes arranged in the X-axis direction share a part thereof, but the through electrodes arranged in the Y-axis direction may share a part thereof.

In addition, the width D1 of the shared portion of the annular trenches 142-1 and 142-2 can be made substantially the same as the width D2 of the non-shared portion. In the case of sharing the annular trench, if the dimension of the shared portion is different from the others, a problem such as variation in the entry amount of the insulating film occurs at the time of forming the back surface insulating film 131 occurs, but the variation is reduced by making the width substantially the same as illustrated in the figure.

Note that the second and third embodiments can be applied to the fourth embodiment.

As described above, according to the fourth embodiment of the present technology, since a part of the annular trench is shared by two adjacent through electrodes, the pitch of the through electrodes can be reduced than that in a case where the through electrodes are not shared.

### 5. Fifth Embodiment

In the first embodiment described above, the back surface rewiring 121 covers the inside of the annular trench 142, but in this configuration, wiring reliability may be insufficient. A semiconductor device 100 according to a fifth embodiment is different from that of the first embodiment in that the back surface rewiring 121 covers the entire surface of the annular trench 142.

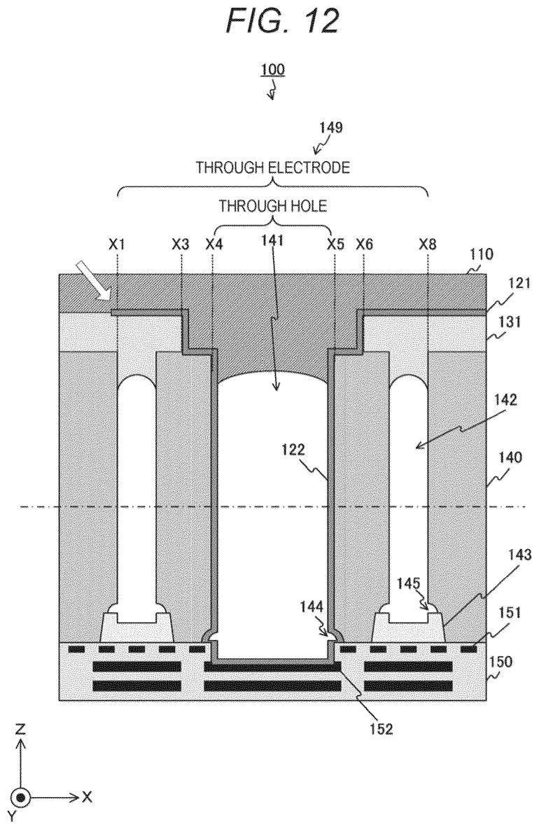

FIG. 12 is a cross-sectional view illustrating a configuration example of the semiconductor device 100 according to the fifth embodiment of the present technology.

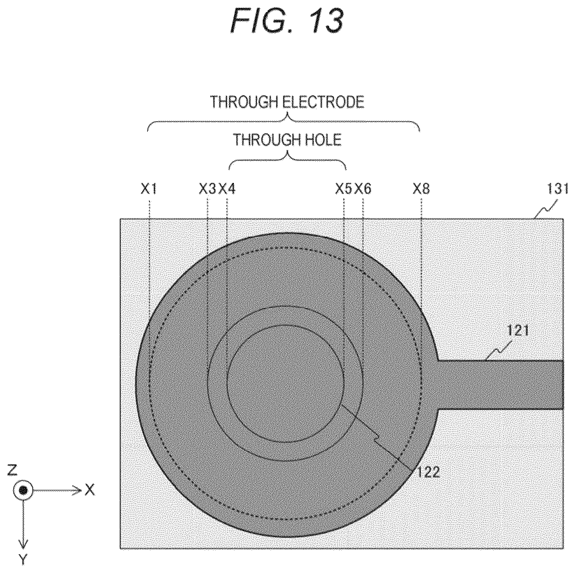

FIG. 13 is an example of a top view of the semiconductor device 100 according to the fifth embodiment of the present technology. The figure illustrates a top view before covering with the solder mask 110.

A feature of the fifth embodiment is that the back surface rewiring 121 facing the through wiring 122 is formed so as to cover the entire annular trench 142. In FIGS. 12 and 13, coordinates X1 to X8 correspond to the outer periphery of the through electrode 149, that is, the outer periphery of the annular trench 142. As exemplified in FIG. 13, the outer periphery of the back surface rewiring 121 is larger than the outer periphery of the annular trench 142.

Since the rigidity of the semiconductor substrate 140 is low in the upper portion of the annular trench 142, stress is likely to be applied to the back surface rewiring 121. Therefore, wiring reliability is likely to deteriorate, but in the fifth embodiment, a thin wiring does not traverse the annular trench 142, so that high wiring reliability can be obtained.

Note that each of the first, second, and third embodiments can be applied to the fifth embodiment.

As described above, according to the fifth embodiment of the present technology, since the back surface rewiring 121 covers the entire annular trench 142, wiring reliability is improved.

### 6. Sixth Embodiment

In the first embodiment described above, the back surface rewiring 121 is formed linearly from the periphery of the through hole 141, but the width of the back surface rewiring 121 may not be constant. A semiconductor device 100 according to a sixth embodiment is different from that of the first embodiment in that the width of the back surface rewiring 121 at a position traversing the upper portion of the annular trench 142 is increased.

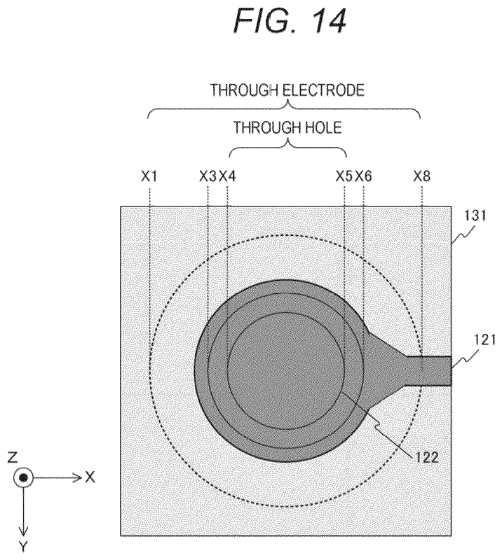

FIG. 14 is an example of a top view of the semiconductor device 100 according to the sixth embodiment of the present technology. The figure illustrates a top view before covering with the solder mask 110. Between the coordinates X6 and X8, the back surface rewiring 121 traverses the upper portion of the annular trench 142, but the width of the portion is thicker than the other portions.

Since the rigidity of the semiconductor substrate 140 is low in the upper portion of the annular trench 142, stress is likely to be applied to the back surface rewiring 121. Therefore, wiring reliability is likely to deteriorate, but in the sixth embodiment, high wiring reliability can be obtained by thickening the wiring traversing the annular trench 142. In addition, since the area of the back surface rewiring 121 is smaller than that of the fifth embodiment, it is advantageous for high integration.

Note that each of the first to fourth embodiments can be applied to the sixth embodiment.

As described above, according to the sixth embodiment of the present technology, since the width of the back surface rewiring 121 at the position traversing the upper portion of the annular trench 142 is increased, the wiring reliability can be improved.

### 7. Seventh Embodiment

In the first embodiment described above, the entire surface of the opening of the back surface insulating film 131 is covered, but in this structure, the yield may be insufficient. A semiconductor device 100 according to a seventh embodiment is different from that of the first embodiment in that the inside of the opening is covered.

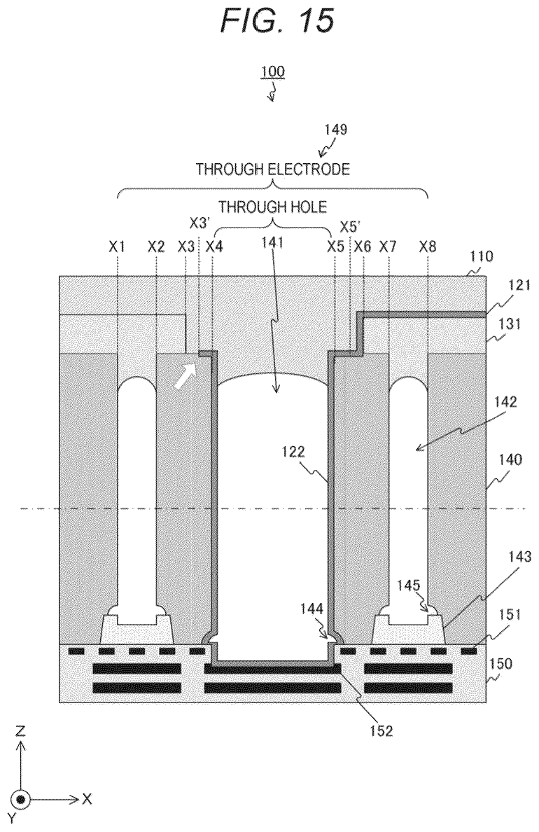

FIG. 15 is a cross-sectional view illustrating a configuration example of the semiconductor device 100 according to the seventh embodiment of the present technology.

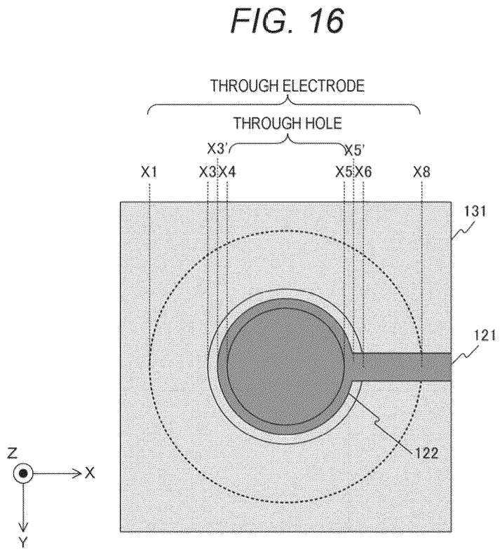

FIG. 16 is an example of a top view of the semiconductor device 100 according to the seventh embodiment of the present technology. The figure illustrates a top view before covering with the solder mask 110.

In the seventh embodiment, the back surface rewiring 121 around the through hole 141 covers the back surface inside the opening of the back surface insulating film 131. A range from coordinate X3 to coordinate X6 in FIGS. 15 and 16 corresponds to the diameter of the opening formed in the back surface insulating film 131. A coordinate between the coordinate X3 and the coordinate X4 of the end portion of the through hole 141 is defined as X3′. In addition, a coordinate between the coordinate X5 and the coordinate X6 of the end portion of the through hole 141 is defined as X5′. The inside of the opening from the coordinate X3′ to the coordinate X5′ is covered with the back surface rewiring 121.

Since a material having a large stress is generally used for the back surface rewiring 121, it is possible to improve the reliability of the through electrode 149 by reducing the area thereof as much as possible. On the other hand, since the exposure accuracy of lithography decreases in the vicinity of the step (coordinates X3 and X6) of the back surface insulating film 131, there is a concern of a decrease in yield. According to the structures illustrated in FIGS. 15 and 16, patterning is performed in advance so as not to ride on the back surface insulating film 131, so that both reduction of stress and a high yield can be achieved.

Note that each of the first to fourth embodiments can be applied to the seventh embodiment.

As described above, according to the seventh embodiment of the present technology, since the inside of the back surface insulating film 131 is covered with the back surface rewiring 121, it is possible to achieve both reduction of stress and high yield.

### 8. Eighth Embodiment

In the first embodiment described above, the annular trench 142 is formed around the through hole 141 in the through electrode 149, but an external connection terminal, a circuit, or the like can be connected to the through electrode 149. A semiconductor device 100 according to an eighth embodiment is different from that of the first embodiment in that an external connection terminal, a photoelectric conversion layer, or the like is added to function as a solid-state imaging device.

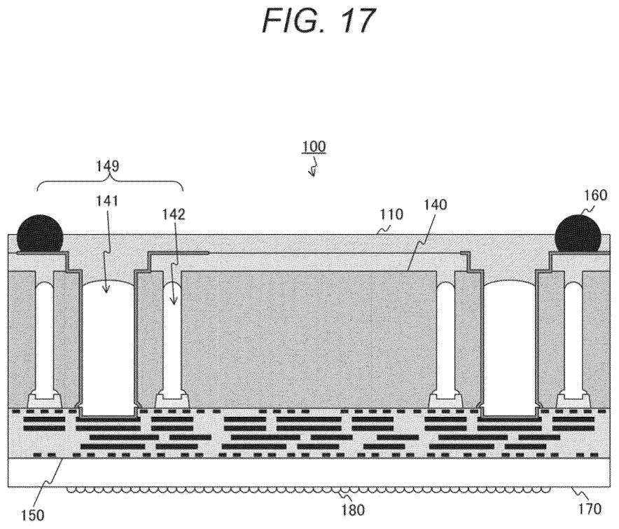

FIG. 17 is a cross-sectional view illustrating a configuration example of the semiconductor device 100 according to the eighth embodiment of the present technology. The eighth embodiment is an example in which the structure of the through electrode 149 of the first embodiment is adopted in a back-illuminated solid-state imaging device.

The external connection terminal 160 is connected to the through electrode 149 via the back surface rewiring 121. On the front surface side, a photoelectric conversion layer 170 including a semiconductor substrate such as silicon, for example, a group 3-5 substrate such as gallium nitride (GaAs), an organic material, or a laminate thereof is formed via the wiring layer 150.

Furthermore, a light condensing structure such as an on-chip lens 180 is disposed on the lower surface side of the photoelectric conversion layer 170 via an antireflection film (not illustrated) or the like. Also in a solid-state imaging element, for example, in an interface circuit, it is necessary to transmit a signal to the outside at a high speed, and by adopting the through electrode 149 of the present invention having a low capacitance and high reliability, higher performance than that of a conventional structure can be obtained.

Note that each of the second to seventh embodiments can be applied to the eighth embodiment.

As described above, according to the eighth embodiment of the present technology, since the external connection terminal 160 and the photoelectric conversion layer 170 are formed, the semiconductor device 100 can function as a solid-state imaging device.

### 9. Ninth Embodiment

In the first embodiment described above, the through electrode 149 is formed on the semiconductor substrate 140. However, if measures are taken to reduce parasitic capacitance, film stress of the conductive film (through wiring 122) may cause cracking or peeling on the bottom surface of the through hole 141. A semiconductor device 100 according to a ninth embodiment is different from that of the first embodiment in that a reinforcing film is formed around the through hole 141.

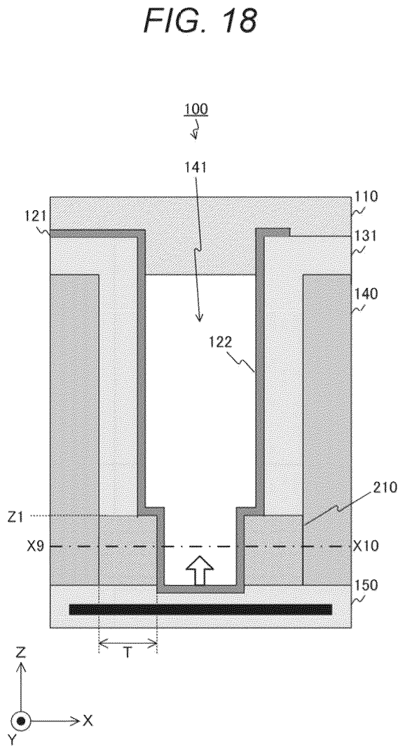

FIG. 18 is a cross-sectional view illustrating a configuration example of the semiconductor device 100 according to the ninth embodiment of the present technology. The semiconductor device 100 of the ninth embodiment is different from that of the first embodiment in further including a reinforcing film 210. In the figure, it is assumed that the annular trench 142 is not formed around the through hole 141.

In addition, in the ninth embodiment, the through hole 141 has a step at a predetermined depth position Z1 when viewed from the Y-axis direction or the X-axis direction. In addition, as the back surface insulating film 131, a material having a low dielectric constant such as a low-k film or a resin is used. In addition to the upper surface (that is, the back surface) of the semiconductor substrate 140, the back surface insulating film 131 covers the periphery of the through hole 141 in a range from the upper surface to the depth position Z1. The low dielectric constant back surface insulating film 131 can reduce the parasitic capacitance of the through electrode 149 and the back surface rewiring 121. However, in this configuration, in a case where the reinforcing film 210 is not provided, the film stress of the conductive film (through wiring 122) may cause cracking or peeling on the bottom surface of the through hole 141.

Furthermore, as the reinforcing film 210, an inorganic insulating film such as silicon oxide (SiO), silicon nitride (SiN), silicon oxynitride (SiON), or silicon carbide (SiC) is used.

The reinforcing film 210 covers the periphery of the through hole 141 in a range from the depth position Z1 to the wiring layer 150. The outer periphery of the reinforcing film 210 is in contact with a base material (silicon or the like) of the semiconductor substrate 140.

As exemplified in the figure, by forming the reinforcing film 210 at the lower end of the through hole 141, it is possible to suppress cracking and peeling of the bottom surface of the through hole 141 due to the film stress of the conductive film and the softness of the back surface insulating film 131. In the figure, a white arrow indicates the vector of deformation caused under Cu by film stress.

As the thickness T of the reinforcing film 210 in the X-axis direction or the Y-axis direction increases, the film stress can be dispersed to suppress cracking and peeling. For example, the thickness T is adjusted to 5 micrometers (μm) or more. In addition, as exemplified in the figure, in a case where the outer periphery of the reinforcing film 210 is in contact with the base material (silicon or the like) of the semiconductor substrate 140, the reinforcing effect can be increased as compared with a case where the outer periphery is not in contact with the base material.

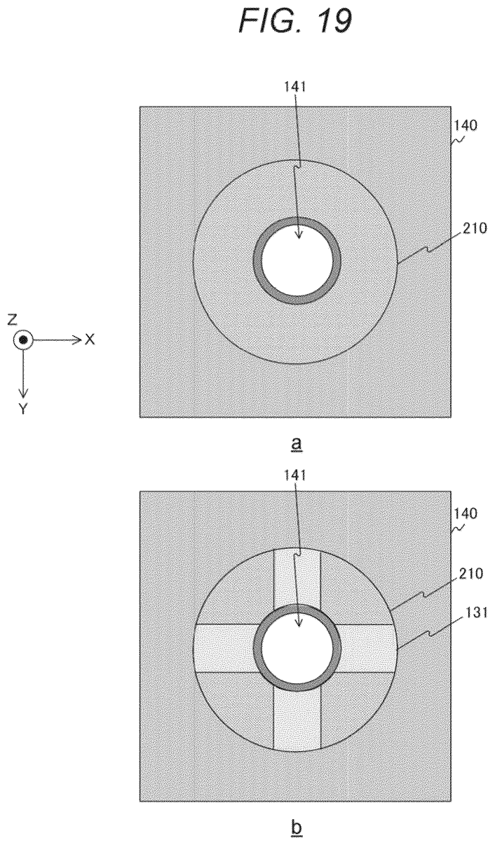

FIG. 19 is a cross-sectional view of the semiconductor device 100 according to the ninth embodiment of the present technology as viewed from the Z-axis direction. a and b in the figure are cross-sectional views taken along a line segment X9-X10 in FIG. 18 when viewed from the Z-axis direction.

As exemplified in a of the figure, the cross-sectional shape of the through hole 141 is circular when viewed from the Z-axis direction, and the reinforcing film 210 covers the entire circumference of the through hole 141.

Note that, as exemplified in b of the figure, the reinforcing film 210 may cover a part of the periphery of the through hole 141. As a result, the parasitic capacitance can be suppressed as compared with the case of covering the entire circumference.

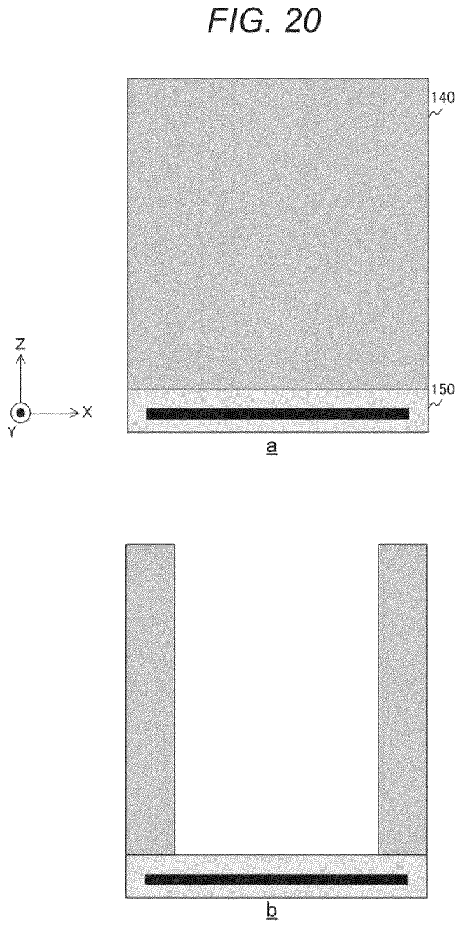

Next, a first manufacturing method of the semiconductor device 100 according to the ninth embodiment of the present technology is illustrated in FIGS. 20 to 23.

As exemplified in a of FIG. 20, the wiring layer 150 is formed on the front surface of the semiconductor substrate 140. Then, as exemplified in b of the figure, the semiconductor substrate 140 is opened.

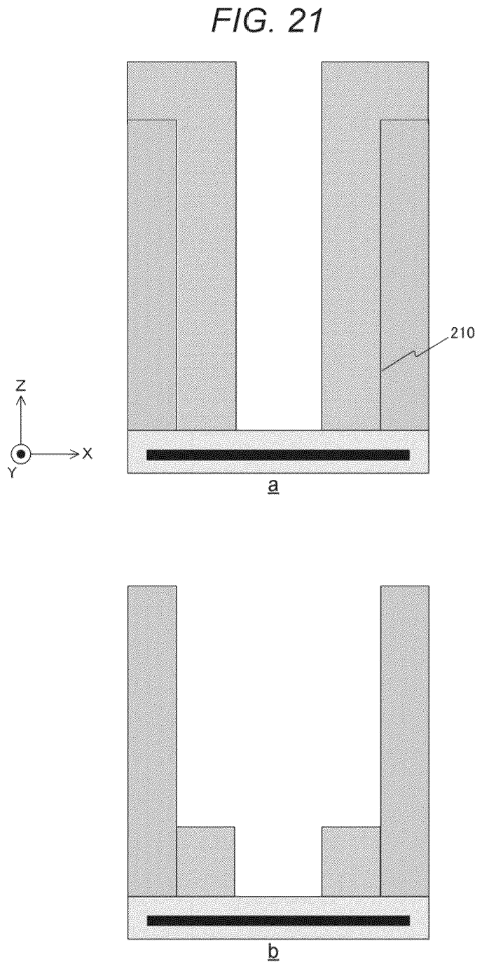

Next, as exemplified in a of FIG. 21, the reinforcing film 210 is formed. Then, as exemplified in b of the figure, the reinforcing film 210 is etched back while leaving the lower portion in the through hole.

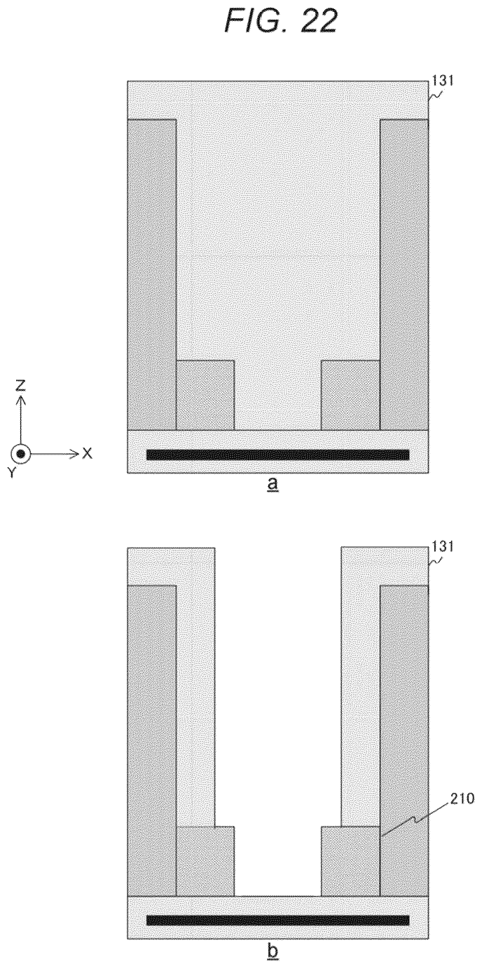

Next, as exemplified in a of FIG. 22, the back surface insulating film 131 having a low dielectric constant is formed. Then, as exemplified in b of the figure, the back surface insulating film 131 is opened so as to generate a step.

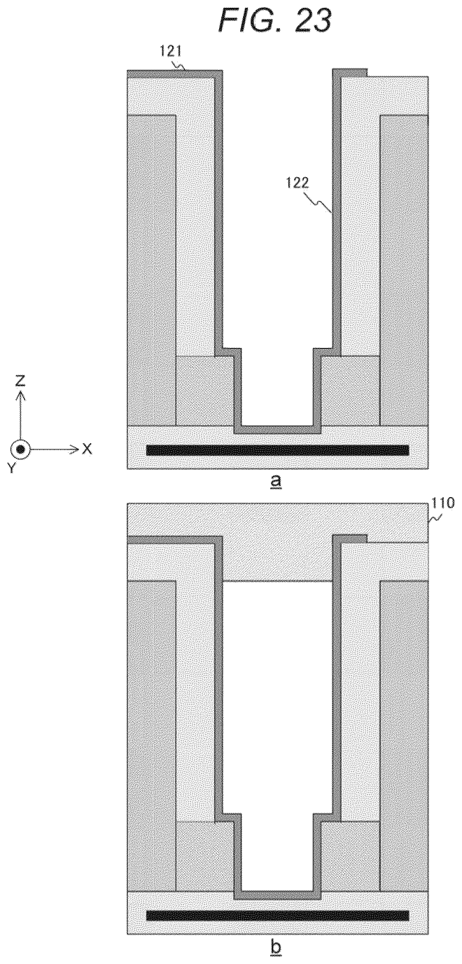

Next, as exemplified in a of FIG. 23, the conductive film (the back surface rewiring 121 and the through wiring 122) is formed. Then, as exemplified in b of the figure, the solder mask 110 is applied.

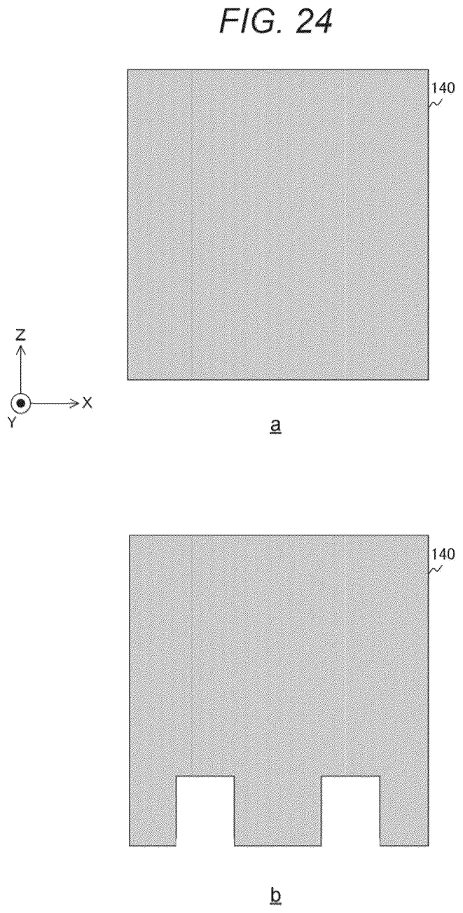

The manufacturing method of the ninth embodiment is not limited to the first manufacturing method described above. A second manufacturing method is illustrated in FIGS. 24 to 27.

As exemplified in a of FIG. 24, the semiconductor substrate 140 before formation of the wiring layer 150 is placed with the front surface side facing upward. Then, as exemplified in b of the figure, a trench is engraved on the front surface side.

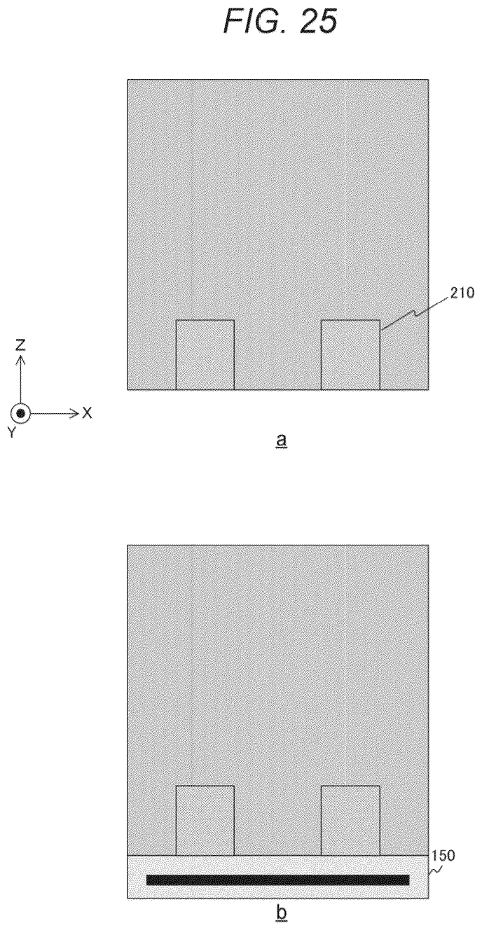

Next, as exemplified in a of FIG. 25, the reinforcing film 210 is formed in the trench, and the STI is obtained. Then, as exemplified in b of the figure, the wiring layer 150 is formed.

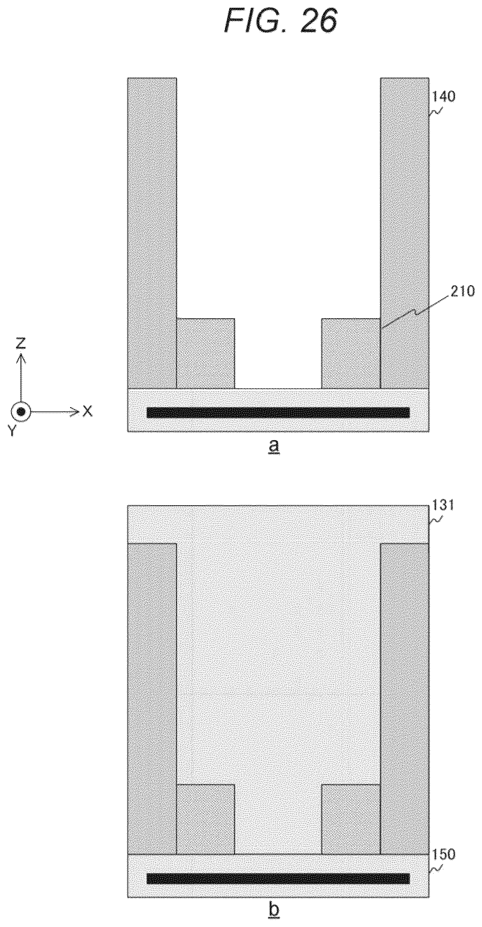

Next, as exemplified in a of FIG. 26, the semiconductor substrate 140 is opened, and as exemplified in b of the figure, the back surface insulating film 131 having a low dielectric constant is formed.

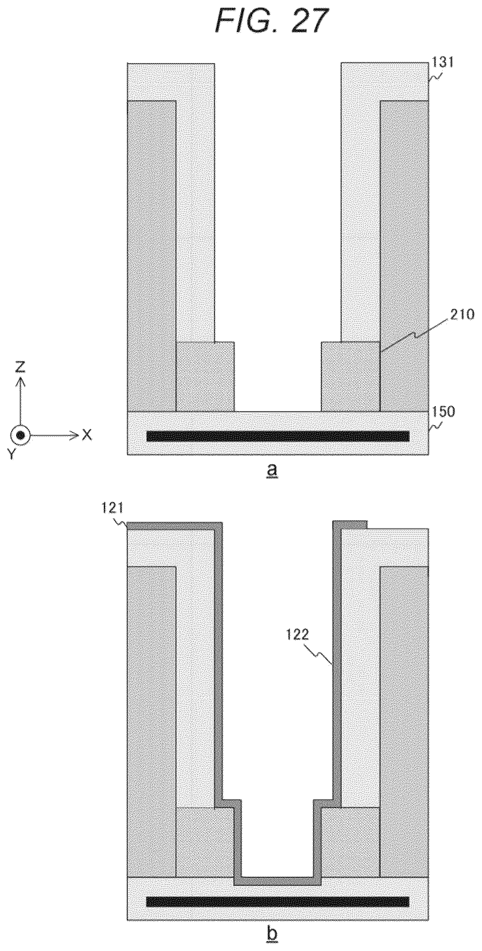

Next, as exemplified in a of FIG. 27, the back surface insulating film 131 is opened, and the conductive film is formed as exemplified in b of the figure. Then, the solder mask 110 (not illustrated) is applied.

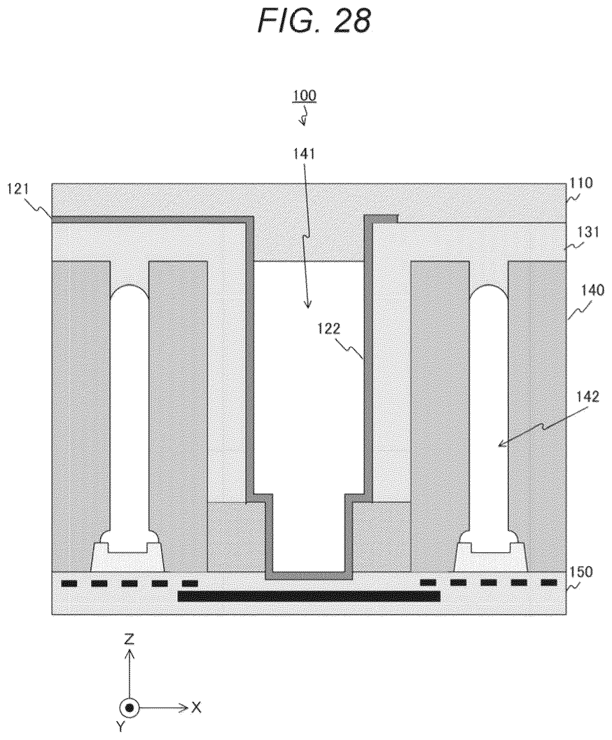

Note that, although the annular trench 142 is not disposed in FIG. 18, the annular trench 142 may be further disposed as exemplified in FIG. 28. In addition, each of the first to eighth embodiments can be applied to the ninth embodiment.

As described above, according to the ninth embodiment of the present technology, since the periphery of the through hole 141 is covered with the reinforcing film 210 in the range from the depth position Z1 to the wiring layer 150, cracking and peeling can be suppressed.

### First Modification

In the ninth embodiment described above, the through hole 141 has a step, but the corners of the step may be rounded when the reinforcing film 210 is etched back. A semiconductor device 100 according to a first modification of the ninth embodiment is different from that of the ninth embodiment in that the cross-sectional shape of the through hole 141 has a curved taper.

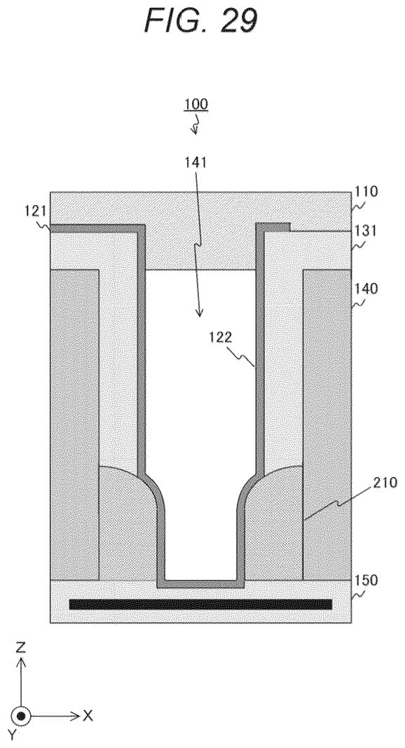

FIG. 29 is a cross-sectional view illustrating a configuration example of the semiconductor device 100 in the first modification of the ninth embodiment of the present technology. The semiconductor device 100 according to the first modification of the ninth embodiment is different from that of the ninth embodiment in that the cross-sectional shape of each of the through hole 141 and the reinforcing film 210 as viewed from the X-axis direction or the Y-axis direction has a curved taper. This facilitates adjustment of the cross-sectional shape at the time of etch-back.

Note that each of the first to eighth embodiments can be applied to the first modification of the ninth embodiment.

As described above, according to the first modification of the ninth embodiment of the present technology, since the cross-sectional shape of each of the through hole 141 and the reinforcing film 210 has the curved taper, the cross-sectional shape is easily adjusted at the time of etch-back.

### Second Modification

In the ninth embodiment described above, the reinforcing film 210 is formed such that the outer periphery of the reinforcing film 210 is in contact with the base material of the semiconductor substrate 140, but the parasitic capacitance may increase as the thickness thereof increases. A semiconductor device 100 according to a second modification of the ninth embodiment is different from that of the ninth embodiment in that the back surface insulating film 131 covers the periphery of the through hole 141 and the reinforcing film 210.

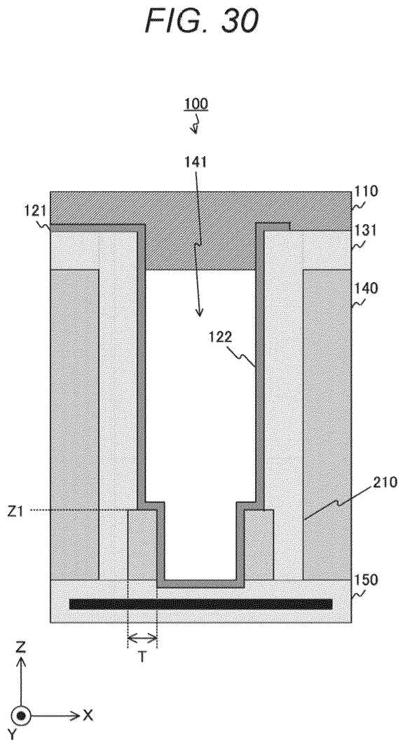

FIG. 30 is a cross-sectional view illustrating a configuration example of the semiconductor device 100 according to the second modification of the ninth embodiment of the present technology. The semiconductor device 100 according to the second modification of the ninth embodiment is different from that of the ninth embodiment in that the back surface insulating film 131 covers not only the periphery of the through hole 141 but also the periphery of the reinforcing film 210.

As exemplified in the figure, in a case where the reinforcing film 210 is not in contact with the base material of the semiconductor substrate 140, the optimum value of the thickness T of the reinforcing film 210 is within a certain range. If the thickness T is too small, the effect of reinforcement is insufficient. On the other hand, when the thickness T is too large, there is a possibility that the entire reinforcing film 210 is lifted and peeled off, and only a position where the reinforcing film is peeled off is changed. In addition, the parasitic capacitance may increase. For example, the thickness T is preferably adjusted within a range of 5 to 10 micrometers (μm).

Note that each of the first to eighth embodiments can be applied to the second modification of the ninth embodiment.

As described above, according to the second modification of the ninth embodiment of the present technology, since the back surface insulating film 131 covers the periphery of the through hole 141 and the reinforcing film 210, the thickness of the reinforcing film 210 can be reduced to reduce the parasitic capacitance.

### Third Modification

In the ninth embodiment described above, the through hole 141 has a step, but instead of the through hole 141, a base material of the semiconductor substrate 140 may have a step. A semiconductor device 100 in a third modification of the ninth embodiment is different from that of the ninth embodiment in that a base material of a semiconductor substrate 140 has a step.

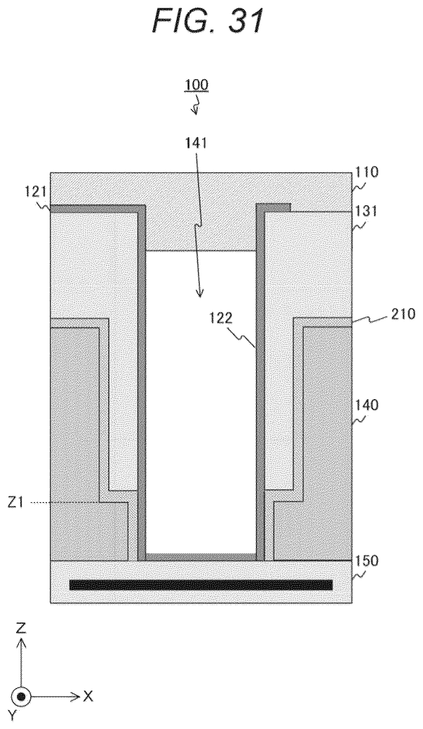

FIG. 31 is a cross-sectional view illustrating a configuration example of the semiconductor device 100 in the third modification of the ninth embodiment of the present technology. The semiconductor device 100 according to the third modification of the ninth embodiment is different from that of the ninth embodiment in that the through hole 141 does not have a step, and instead, the base material of the semiconductor substrate 140 has a step at the depth position Z1.

The back surface insulating film 131 covers the through hole 141 in a range from the back surface to the depth position Z1. In addition, the reinforcing film 210 covers the through hole 141 in a range from the depth position Z1 to the wiring layer 150. Further, the reinforcing film 210 is formed along the base material of the semiconductor substrate 140, and is located between the base material and the back surface insulating film 131 above the depth position Z1.

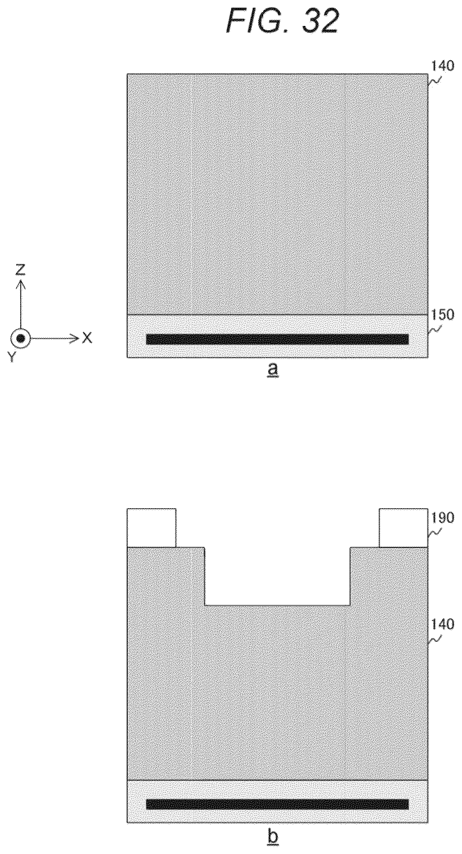

Next, FIGS. 32 to 35 illustrate a method for manufacturing the semiconductor device 100 according to the third modification of the ninth embodiment of the present technology.

As exemplified in a of FIG. 32, the wiring layer 150 is formed on the front surface of the semiconductor substrate 140. Then, as exemplified in b of the figure, the semiconductor substrate 140 is opened, and the resist mask 190 is applied to a portion other than a portion to be provided with a step.

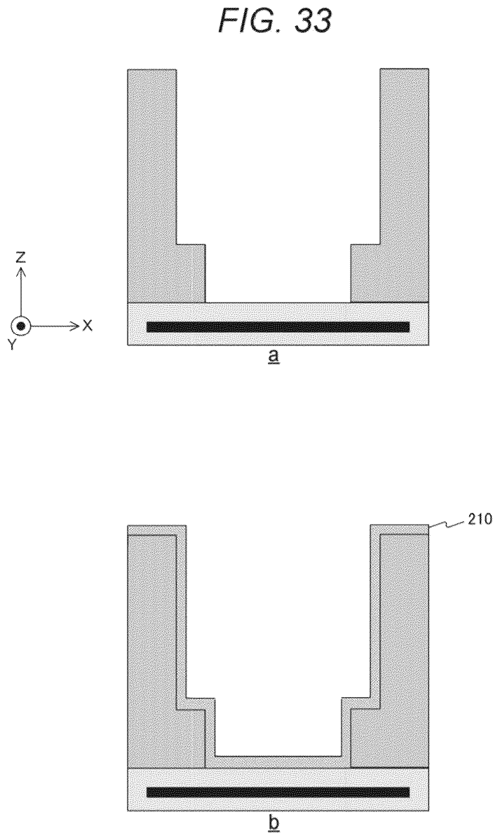

Next, as exemplified in a of FIG. 33, a step is formed in the opening of the base material, and the resist mask 190 is removed. Then, as exemplified in b of the figure, the reinforcing film 210 is formed.

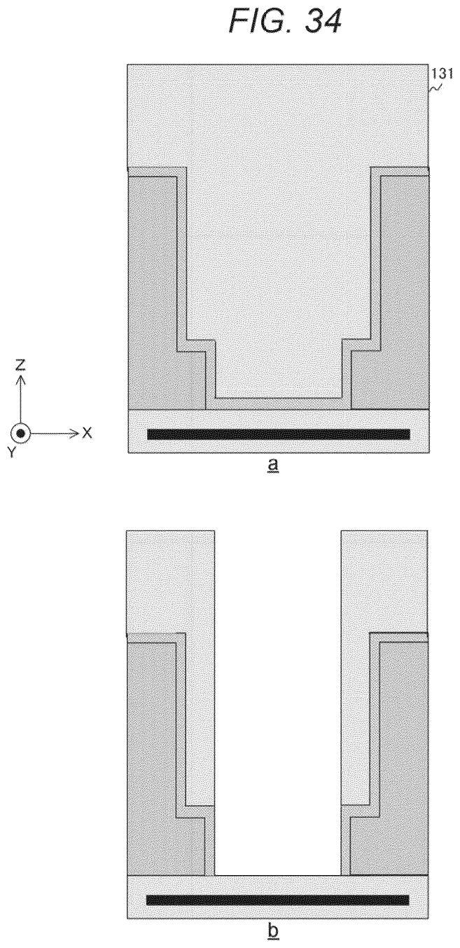

Next, as exemplified in a of FIG. 34, the back surface insulating film 131 is formed, and as exemplified in b of the figure, the back surface insulating film 131 is opened.

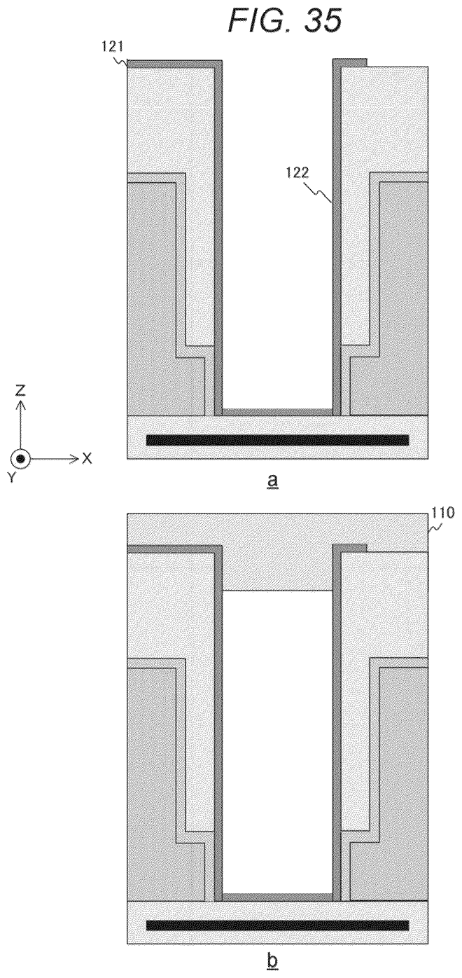

Next, as exemplified in a of FIG. 35, the conductive film (the back surface rewiring 121 and the through wiring 122) is formed. Then, as exemplified in b of the figure, the solder mask 110 is applied.

Note that each of the first to eighth embodiments can be applied to the third modification of the ninth embodiment.

As described above, according to the third modification of the ninth embodiment of the present technology, since the base material of the semiconductor substrate 140 has a step, it is not necessary to provide a step in the through hole 141.

### Fourth Modification

In the ninth embodiment described above, the cross-sectional shape of the through hole 141 when viewed from the Z-axis direction is circular, but may be rectangular. A semiconductor device 100 according to a fourth modification of the ninth embodiment is different from that of the ninth embodiment in that the cross-sectional shape of the through hole 141 is rectangular.

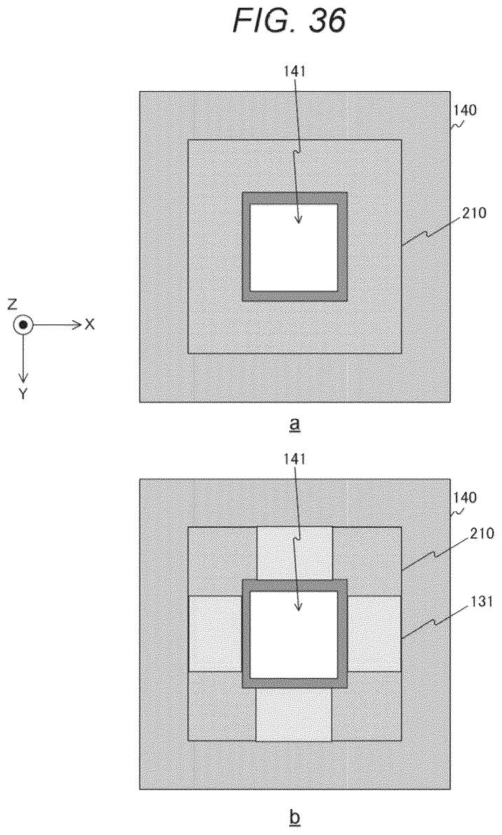

FIG. 36 is a cross-sectional view of the semiconductor device 100 according to the fourth modification of the ninth embodiment of the present technology as viewed from the Z-axis direction. a and b in the figure are cross-sectional views taken along a line segment X9-X10 in FIG. 18 when viewed from the Z-axis direction.

As exemplified in a of FIG. 36, the cross-sectional shape of the through hole 141 is rectangular when viewed from the Z-axis direction, and the reinforcing film 210 covers the entire circumference of the through hole 141.

Note that, as exemplified in b of the figure, the reinforcing film 210 may cover a part of the periphery of the through hole 141. As a result, the parasitic capacitance can be suppressed as compared with the case of covering the entire circumference.

Note that each of the first to eighth embodiments can be applied to the fourth modification of the ninth embodiment.

As described above, according to the fourth modification of the ninth embodiment of the present technology, it is possible to suppress cracking and peeling in the semiconductor device 100 in which the cross-sectional shape of the through hole 141 is rectangular.

### Fifth Modification

In the ninth embodiment described above, the cross-sectional shape of the through hole 141 when viewed from the Z-axis direction is circular, but may be a polygon (hexagon) other than a rectangle. A semiconductor device 100 according to a fifth modification of the ninth embodiment is different from that of the ninth embodiment in that the cross-sectional shape of the through hole 141 is a hexagon.

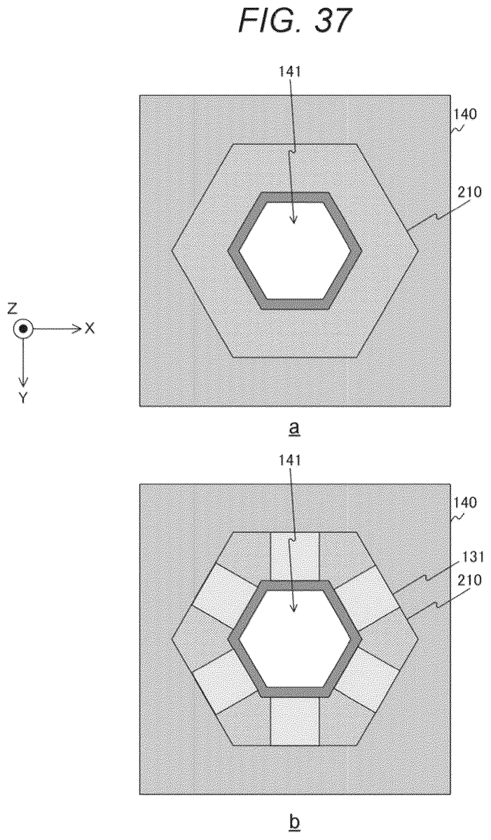

FIG. 37 is a cross-sectional view of the semiconductor device 100 according to the fifth modification of the ninth embodiment of the present technology as viewed from the Z-axis direction. a and b in the figure are cross-sectional views taken along a line segment X9-X10 in FIG. 18 when viewed from the Z-axis direction.

As exemplified in a of FIG. 37, the cross-sectional shape of the through hole 141 is a polygon (such as a hexagon) other than a rectangle when viewed from the Z-axis direction, and the reinforcing film 210 covers the entire circumference of the through hole 141. Note that, although the cross-sectional shape is a hexagon in the figure, the cross-sectional shape may be a polygon other than a hexagon.

Further, as exemplified in b of the figure, the reinforcing film 210 may cover a part of the periphery of the through hole 141. As a result, the parasitic capacitance can be suppressed as compared with the case of covering the entire circumference.

In addition, each of the first to eighth embodiments can be applied to the fifth modification of the ninth embodiment.

As described above, according to the fifth modification of the ninth embodiment of the present technology, it is possible to suppress cracking and peeling in the semiconductor device 100 in which the cross-sectional shape of the through hole 141 is hexagonal.

### 10. 10th Embodiment

In the first embodiment described above, the annular trench 142 is formed around the through hole 141, but the semiconductor substrate 140 may be peeled off due to contraction of the upper back surface insulating film 131 during annealing. A semiconductor device 100 according to a 10th embodiment is different from that of the first embodiment in that the protection member is provided at the lower portion of the annular trench 142 to suppress peeling.

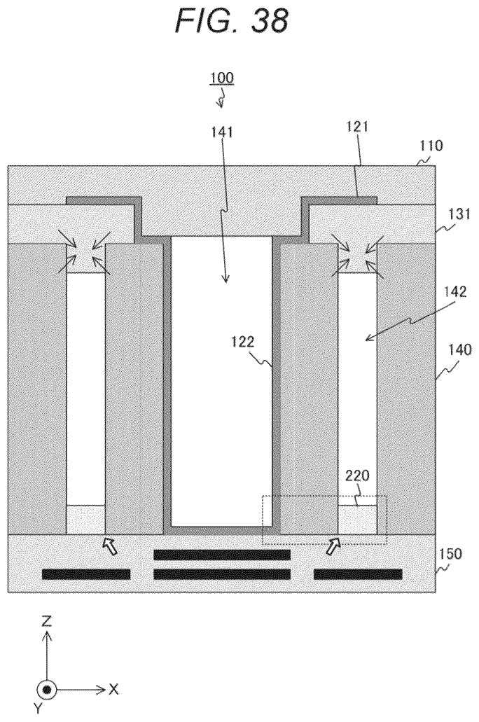

FIG. 38 is a cross-sectional view illustrating a configuration example of the semiconductor device 100 according to the 10th embodiment of the present technology. The semiconductor device 100 according to the 10th embodiment is different from that of the first embodiment in that a protection member 220 is disposed adjacent to the wiring layer 150 in the annular trench 142. As the protection member 220, for example, an insulating resin is used. The material of the resin may be the same as or different from that of the back surface insulating film 131.

In the manufacturing process, when annealing is performed, the back surface insulating film 131 entering the upper portion of the annular trench 142 contracts. A black arrow in the figure indicates the direction of contraction. Due to this contraction, a stress that causes the semiconductor substrate 140 to peel off occurs, and in particular, the stress concentrates on the corner on the inner peripheral side of the bottom portion of the annular trench 142. A white arrow in the figure indicates the direction of stress.

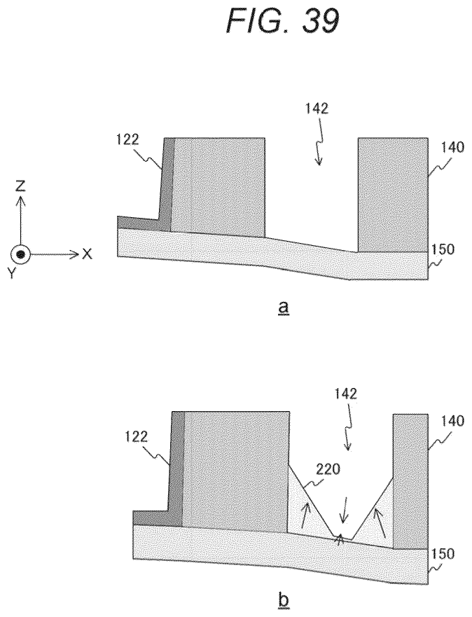

FIG. 39 is a diagram for explaining an effect of the semiconductor device according to the 10th embodiment of the present technology. a in the figure is an enlarged view of a portion surrounded by a dotted line in FIG. 38 in a case where the protection member 220 is not provided. b in the figure illustrates an enlarged view in a case where the protection member 220 is provided.

By making the annular trench 142 hollow, the dielectric constant can be reduced, and high-speed transmission can be realized. However, as exemplified in a of the figure, in a case where the protection member 220 is not provided, the semiconductor substrate 140 and the wiring layer 150 are deformed, and the semiconductor substrate 140 may be locally peeled off. Note that, in a and b of the figure, the degree of deformation is emphasized 100 times or more.

On the other hand, as exemplified in b of the figure, in a case where the protection member 220 is provided, the protection member 220 contracts, and deformation of the semiconductor substrate 140 and the wiring layer 150 is suppressed by the contraction. An arrow in b in the figure indicates the direction of contraction. As a result, local peeling is suppressed. For example, by setting the film thickness of the protection member 220 to 5 micrometers (μm) or more, peeling can be sufficiently suppressed. Therefore, it is possible to achieve both high-speed transmission by the hollow annular trench 142 and suppression of peeling.

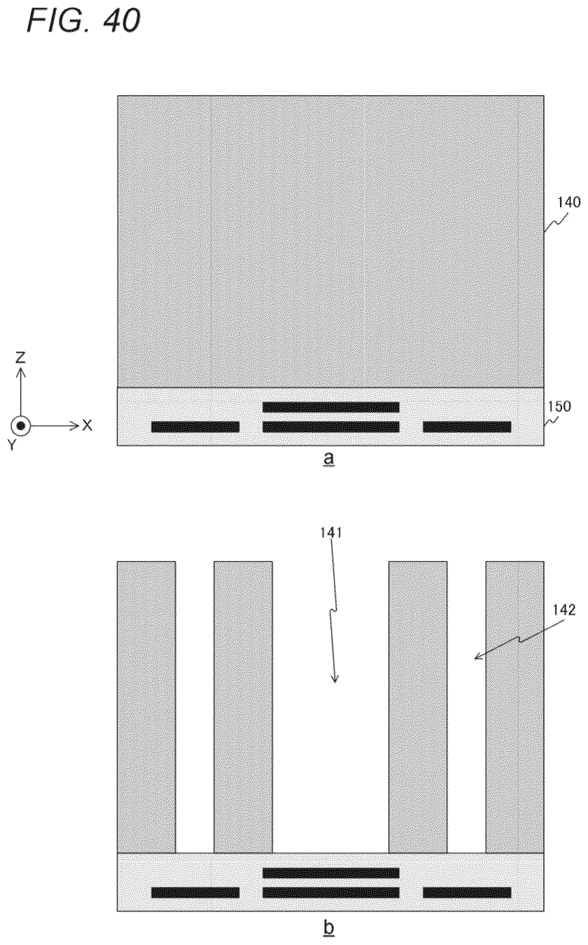

Next, a method for manufacturing the semiconductor device 100 according to the first embodiment of the present technology is illustrated in FIGS. 40 to 42.

As exemplified in a of FIG. 40, the wiring layer 150 is formed on the front surface of the semiconductor substrate 140. Then, as exemplified in b of the figure, the through hole 141 and the annular trench 142 are formed by dry etching. Note that the through hole 141 and the annular trench 142 may be simultaneously formed once or may be formed twice.

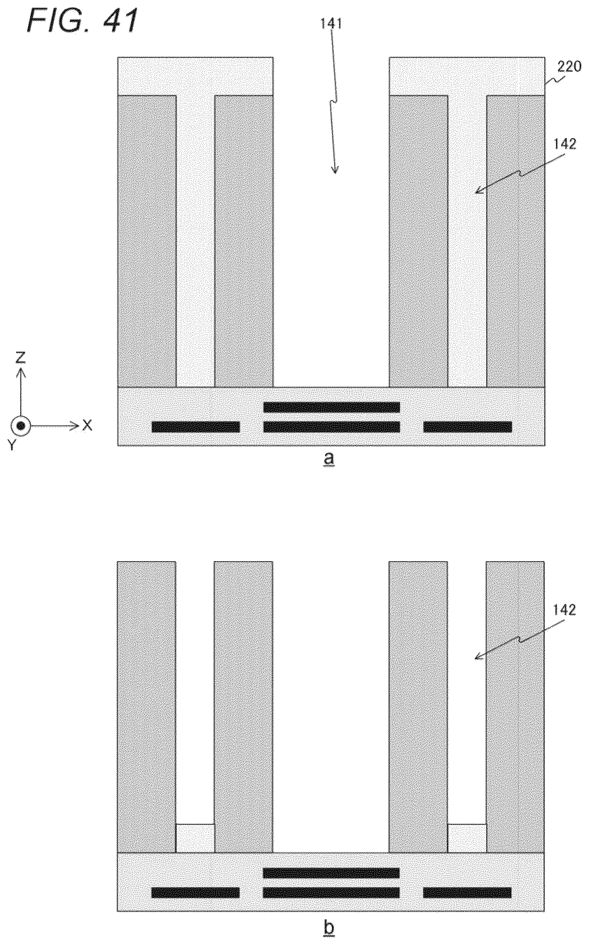

Next, as exemplified in a of FIG. 41, a photosensitive protection member 220 is applied, and a portion of the through hole 141 is removed by a lithography method. Then, as exemplified in b of the figure, etch-back is performed so that the protection member 220 remains only at the bottom portion of the annular trench 142.

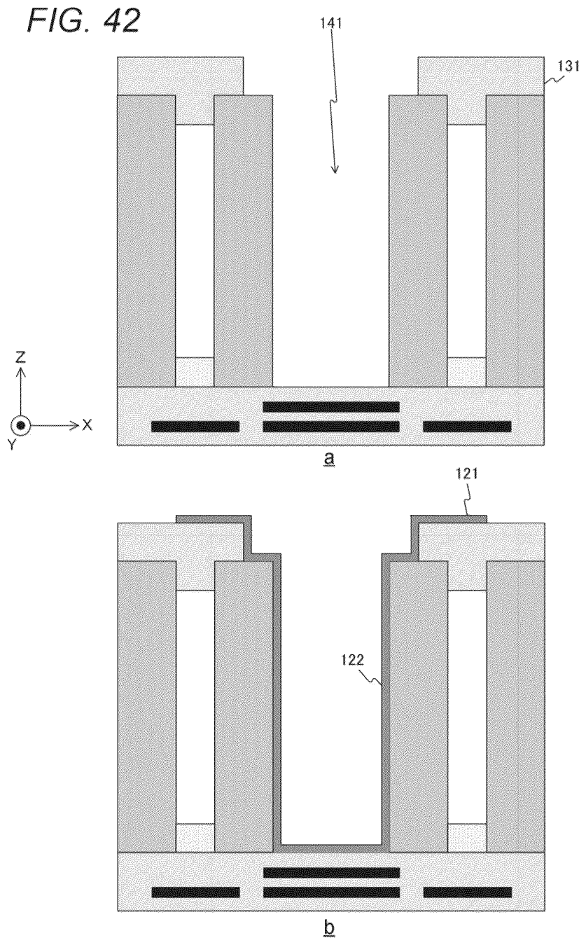

Next, as exemplified in a of FIG. 42, the photosensitive back surface insulating film 131 is formed, and the inside of the through hole 141 and a part of the periphery thereof are removed by a lithography method. Then, as exemplified in b of the figure, the back surface rewiring 121 and the through wiring 122 are simultaneously formed. Then, the solder mask 110 (not illustrated) is formed, and the semiconductor device 100 in FIG. 38 is obtained.

Note that, in FIG. 38, the protection member 220 is formed so as to cover the entire bottom surface of the annular trench 142, but the present invention is not limited to this configuration.

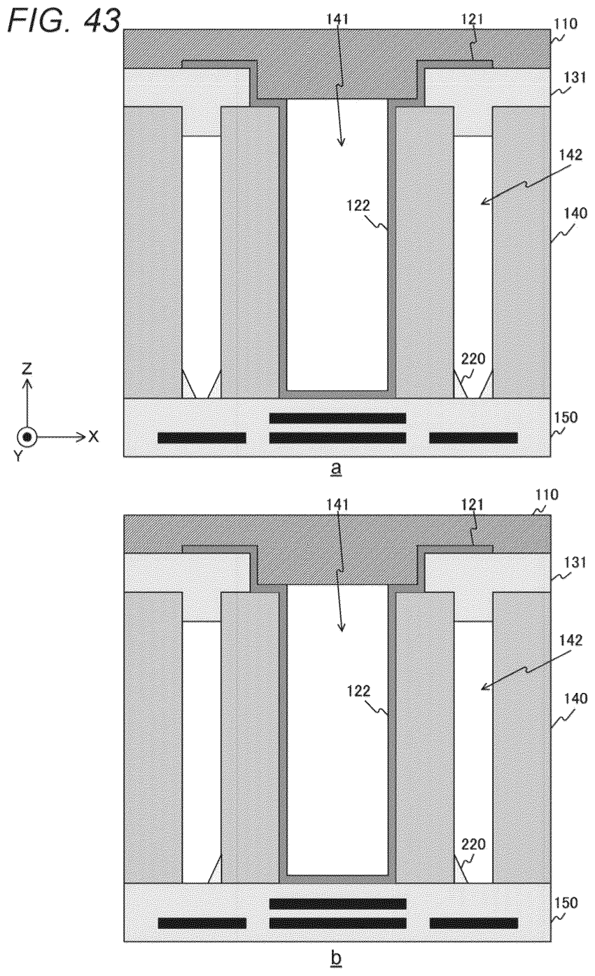

As exemplified in a of FIG. 43, it is also possible to arrange the protection member 220 so as to cover each of the corner on the inner peripheral side and the corner on the outer peripheral side of the annular trench 142 with a part of the bottom surface of the annular trench 142 left. Since the etch-back amount is particularly large at the central portion of the annular trench 142, the protection member 220 can be left only at the corner by adjusting the total amount of etch-back at the time of etch-back.

Further, as exemplified in b of the figure, the protection member 220 may be disposed so as to cover only the corner on the inner peripheral side. The dielectric constant of the resin used as the protection member 220 is generally higher than the dielectric constant of air. Therefore, as exemplified in a and b of the figure, by leaving the resin only in the corners, the volume of the entire resin is reduced, and the dielectric constant can be reduced by that amount, which is advantageous for high-speed transmission.

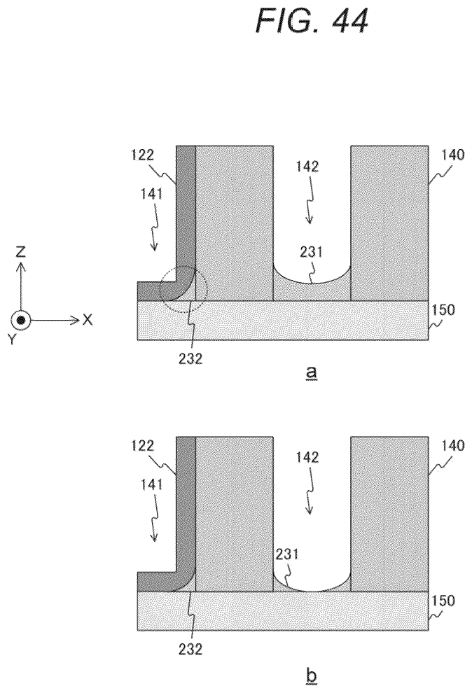

In addition, in FIG. 38, a resin is used as the protection member 220, but as exemplified in FIG. 44, an insulating inorganic film may be used instead of the resin. In particular, when the film is a tensile film, the effect of stress reduction equivalent to that of the resin is produced. In a compressive film, stress reduction equivalent to that of the resin cannot be obtained, but since the inorganic film is hard, there is an effect of suppressing deformation, and it is considered to be effective for measures against peeling.

For example, an inorganic film is formed by an atomic layer deposition (ALD) method, and then the inorganic film in the through hole 141 and the annular trench 142 is removed by etch-back. The inorganic film remaining at the corner in the through hole 141 is defined as a protection member 232, and the inorganic film remaining in the annular trench 142 is defined as a protection member 231. Note that the protection member 231 is an example of a first protection member described in the claims, and the protection member 232 is an example of a second protection member described in the claims.

As exemplified in a of FIG. 44, the inorganic film (protection member 232) remains also at the corner of the through hole 141, but since the corner of the through wiring 122 constituted by Cu or the like is rounded, an effect of alleviating the stress immediately below the through hole 141 is produced. In addition, also in the annular trench 142, since the etch-back proceeds from the central portion, the remaining protection member 231 has a shape recessed downward (in other words, the wiring layer 150 side). Even with such a shape, since the corner is covered, the effect of suppressing peeling is not affected. In addition, the volume of the protection member 231 is reduced by the recess, and the dielectric constant can be reduced by that amount, which is advantageous for high-speed transmission.

Depending on the degree of etch-back, there is a possibility that a part of the bottom surface of the annular trench 142 is exposed and the protection member 231 remains only at the corner as exemplified in b of the figure. Even in this case, since the corners are rounded, the effect of suppressing peeling is produced.

Note that each of the first to ninth embodiments can be applied to the 10th embodiment.

As described above, according to the 10th embodiment of the present technology, since the protection member 220 is disposed adjacent to the wiring layer 150 in the annular trench 142, peeling can be suppressed.

### First Modification

In the above-described 10th embodiment, the protection member 220 is disposed in the annular trench 142 to suppress peeling, but in this configuration, it is necessary to add a step of forming the protection member 220. A semiconductor device 100 according to a first modification of the 10th embodiment is different from that of the 10th embodiment in that the protection member 220 is unnecessary.

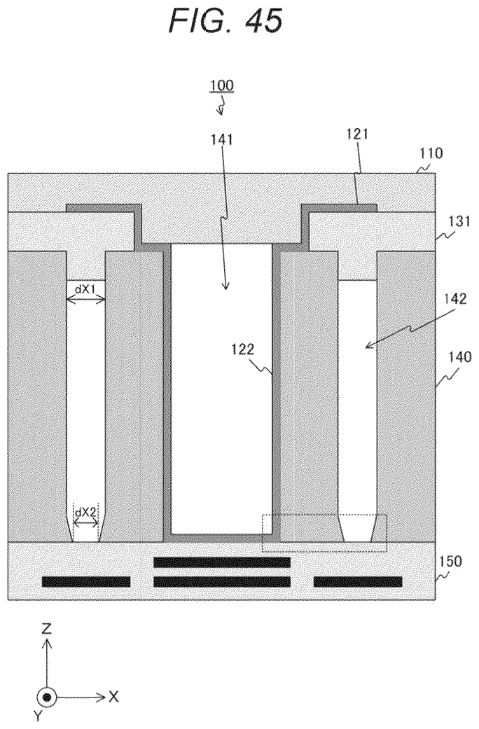

FIG. 45 is a cross-sectional view illustrating a configuration example of the semiconductor device 100 in the first modification of the 10th embodiment of the present technology. In the semiconductor device 100 according to the first modification of the 10th embodiment, the protection member 220 is not formed. Instead, the width dX2 of the annular trench 142 on the wiring layer 150 side is adjusted to be narrower than the width dX1 of the annular trench 142 on the back surface insulating film 131 side. For example, the cross-sectional shape of the annular trench 142 has a taper that becomes thinner toward the wiring layer 150 at the lower portion thereof.

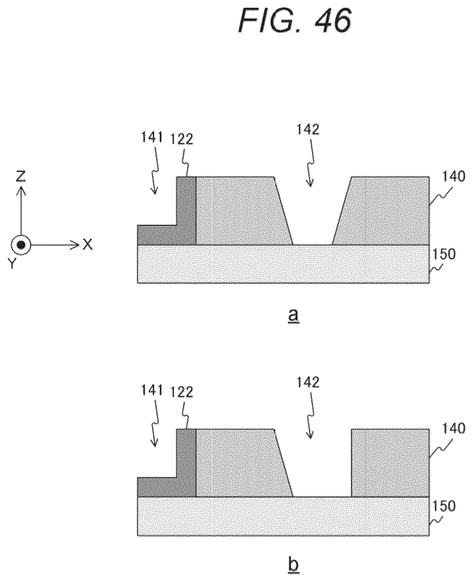

FIG. 46 is an example of an enlarged view of the semiconductor device in the first modification of the 10th embodiment of the present technology. a in the figure illustrates an enlarged view of a portion surrounded by a dotted line in FIG. 45.

As exemplified in a of FIG. 46, the annular trench 142 has a taper on both the inner peripheral side and the outer peripheral side. Note that, as exemplified in b of the figure, a configuration having a taper only on the inner peripheral side may be adopted. By providing a taper as exemplified in a and b of the figure, deformation can be suppressed and peeling can be prevented.

Note that each of the first to ninth embodiments can be applied to the first modification of the 10th embodiment.

As described above, according to the first modification of the 10th embodiment of the present technology, since the cross-sectional shape of the annular trench 142 is tapered, the protection member 220 is unnecessary.

### Second Modification

In the above-described 10th embodiment, the protection member 220 is disposed in the annular trench 142 to suppress peeling, but in this configuration, it is necessary to add a step of forming the protection member 220. A semiconductor device 100 according to a second modification of the 10th embodiment is different from that of the 10th embodiment in that the protection member 220 is unnecessary.

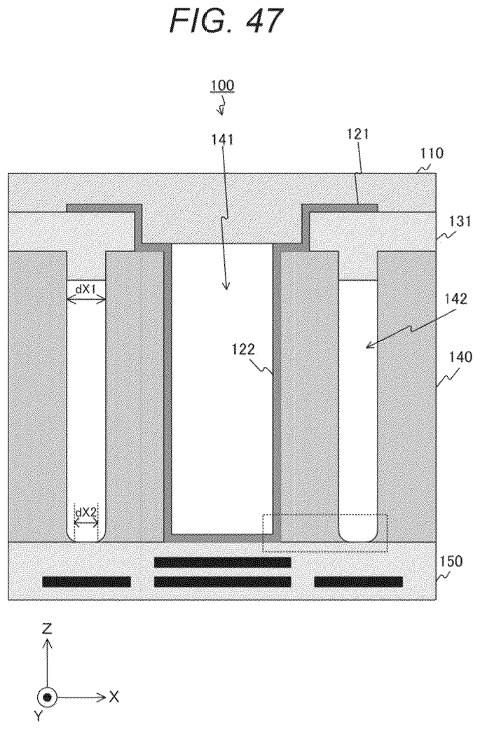

FIG. 47 is a cross-sectional view illustrating a configuration example of the semiconductor device 100 according to the second modification of the 10th embodiment of the present technology. In the semiconductor device 100 according to the second modification of the 10th embodiment, the protection member 220 is not formed. Instead, the width dX2 of the annular trench 142 on the wiring layer 150 side is adjusted to be narrower than the width dX1 of the annular trench 142 on the back surface insulating film 131 side. For example, the corner of the bottom portion of the annular trench 142 is adjusted to have a rounded shape.

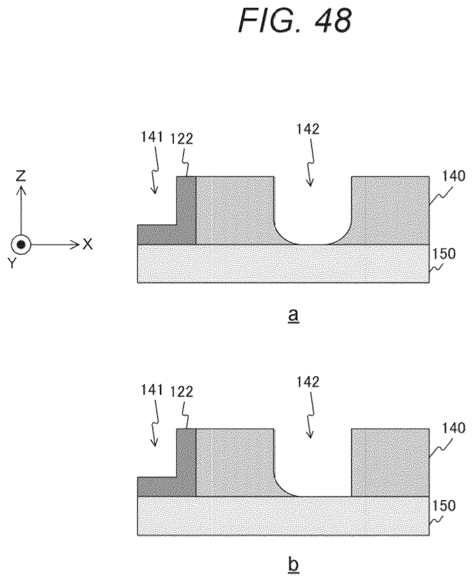

FIG. 48 is an example of an enlarged view of the semiconductor device in the second modification of the 10th embodiment of the present technology. a in the figure illustrates an enlarged view of a portion surrounded by a dotted line in FIG. 47.

As exemplified in a of FIG. 48, in the first modification of the 10th embodiment, it is assumed that both corners on the inner peripheral side and the outer peripheral side of the annular trench 142 are rounded. Note that, as exemplified in b of the figure, only the corner on the inner peripheral side may be rounded. As exemplified in a and b of the figure, the so-called round corner shape can suppress deformation and prevent peeling.

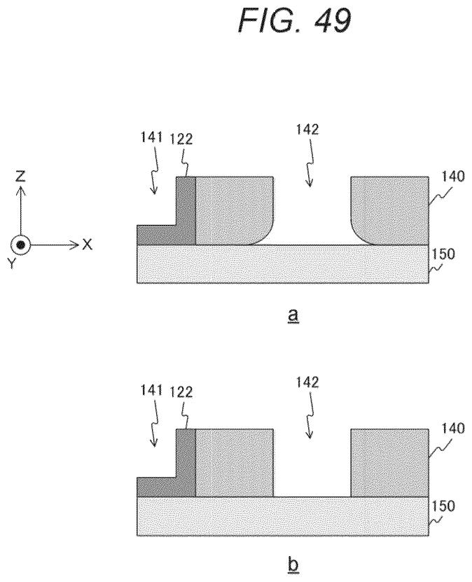

On the other hand, as exemplified in a of FIG. 49, in a case where a notch is formed in a corner, the wiring layer 150 is easily peeled off due to stress concentrated in the corner. In addition, as exemplified in b of the figure, even in a case where there is no notch in the corner, the effect of suppressing peeling cannot be obtained unless the corner is rounded.

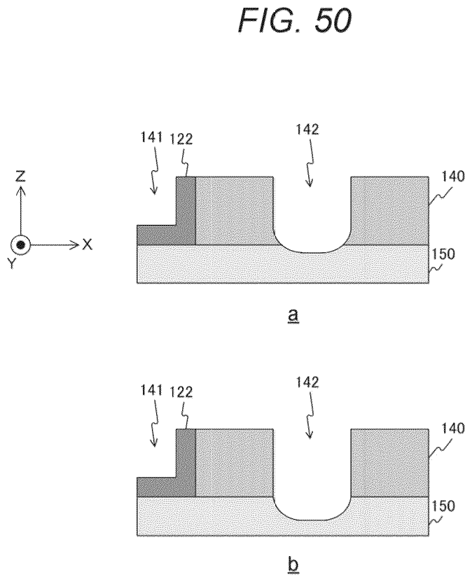

Note that although the corner does not reach the wiring layer 150 in FIG. 47, etching can be performed such that the corner straddles the boundary between the semiconductor substrate 140 and the wiring layer 150 as exemplified in a of FIG. 50. Further, as exemplified in b of the figure, etching can be performed such that the corner is located in the wiring layer 150.

Note that each of the first to ninth embodiments can be applied to the second modification of the 10th embodiment.

As described above, according to the second modification of the 10th embodiment of the present technology, since the corners of the annular trench 142 are rounded, the protection member 220 is unnecessary.

### 11. 11th Embodiment

In the first embodiment described above, the annular trench 142 is formed around the through hole 141, but in this case, the base material (silicon or the like) of the semiconductor substrate 140 remains in a ring shape between the through hole 141 and the annular trench 142. In this configuration, a pattern layout such as securing a sufficient width of the cavity in the annular trench 142 in order to increase the withstand voltage of the back surface rewiring 121 or securing a sufficient ring width in order to suppress peeling of the ring-shaped silicon is required. Therefore, there is a problem that high integration of patterns becomes difficult. A semiconductor device 100 according to a 11th embodiment is different from that of the first embodiment in that a space between the through hole 141 and the annular trench 142 is depleted.

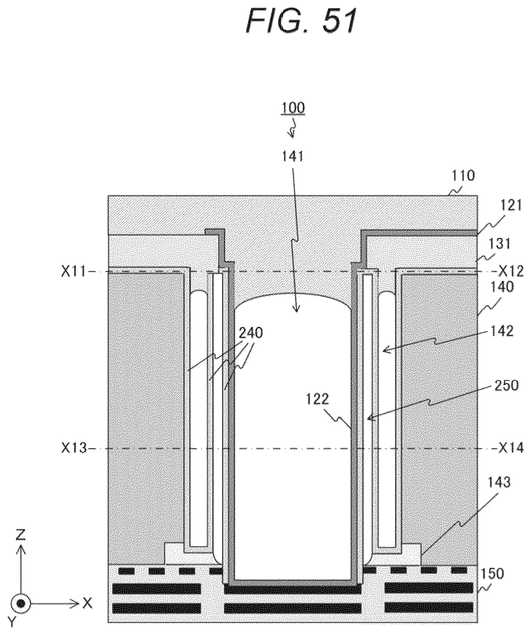

FIG. 51 is a cross-sectional view illustrating a configuration example of the semiconductor device 100 according to the 11th embodiment of the present technology. The semiconductor device 100 according to the 11th embodiment is different from that of the first embodiment in that an insulating film 240 is formed between the outer periphery of the annular trench 142 and the through hole 141 and the annular trench 142. Further, the third embodiment is different from the first embodiment in that a depletion layer 250 is formed in the insulating film 240 between the through hole 141 and the annular trench 142. For example, SiO₂ is used as the insulating film 240.

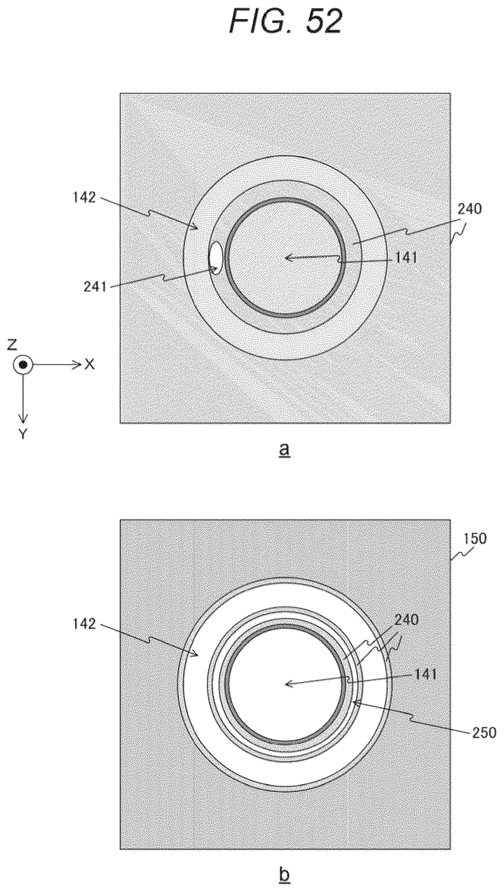

FIG. 52 is an example of a cross-sectional view of the semiconductor device 100 according to the 11th embodiment of the present technology when viewed from another direction. a in the figure is a cross-sectional view taken along a line segment X11-X12 in FIG. 51 and viewed from the Z-axis direction. b of FIG. 52 is a cross-sectional view taken along a line segment X13-X14 of FIG. 51 and viewed from the Z-axis direction.

As exemplified in a of FIG. 52, the insulating film 240 is opened at the upper end of the annular trench 142, and a circular or elliptical hole 241 is formed. Note that the hole 241 is an example of an opening described in the claims.

Further, as exemplified in b of FIG. 52, the insulating film 240 between the annular trench 142 and the through hole 141 is completely depleted to form the depletion layer 250. With the structure in which the portion that is ring-shaped silicon in the first embodiment is completely depleted, the outer diameter of the annular trench 142 can be reduced while ensuring the insulation width between the through wiring 122 and the semiconductor substrate 140. In addition, since the metal wiring in the wiring layer 150 is not exposed at the bottom portion of the ring-shaped depletion layer 250, pattern collapse such as film peeling and corrosion of the metal wiring are suppressed. As a result, the through electrode 149 having a high withstand voltage and a low capacitance can be highly integrated, and improvement in device reliability can be expected.

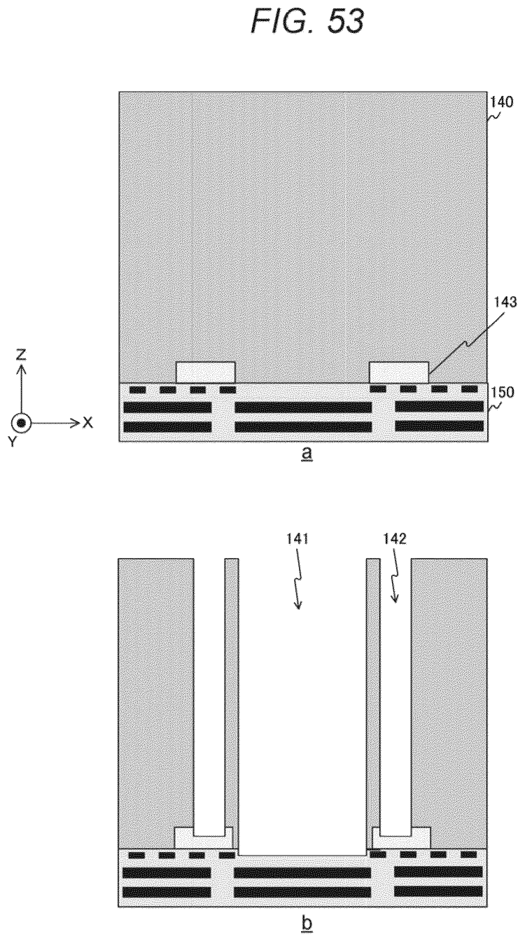

Next, a method for manufacturing the semiconductor device 100 according to the 11th embodiment of the present technology is illustrated in FIGS. 53 to 56.

As exemplified in a of FIG. 53, the semiconductor substrate 140 on which the circuit is created is bonded to a support substrate including the wiring layer 150. In the grinder device, the semiconductor substrate 140 is thinned by polishing until the thickness becomes about 80 micrometers (μm). The support substrate may be a silicon substrate or a glass substrate.

Next, as exemplified in b of the figure, the through hole 141 and the annular trench 142 are formed. First, a resist pattern of the through hole 141 and the annular trench 142 is created by lithography. For example, the diameter of the through hole 141 is 40 micrometers (μm), and the width of the ring-shaped silicon between the through hole 141 and the annular trench 142 is 2 micrometers (μm). In addition, the width of the annular trench 142 is 5 micrometers (μm). At this time, the element isolation region 143 (STI) is preferably provided at the bottom portion of the annular trench 142, and it is desirable that there is no STI at the bottom portion of the through hole 141. Then, dry etching of silicon is performed using the resist as a mask. For example, a vertical shape is obtained by SF₆ (silicon hexafluoride) or C₄F₈ (octafluorocyclobutane) gas.

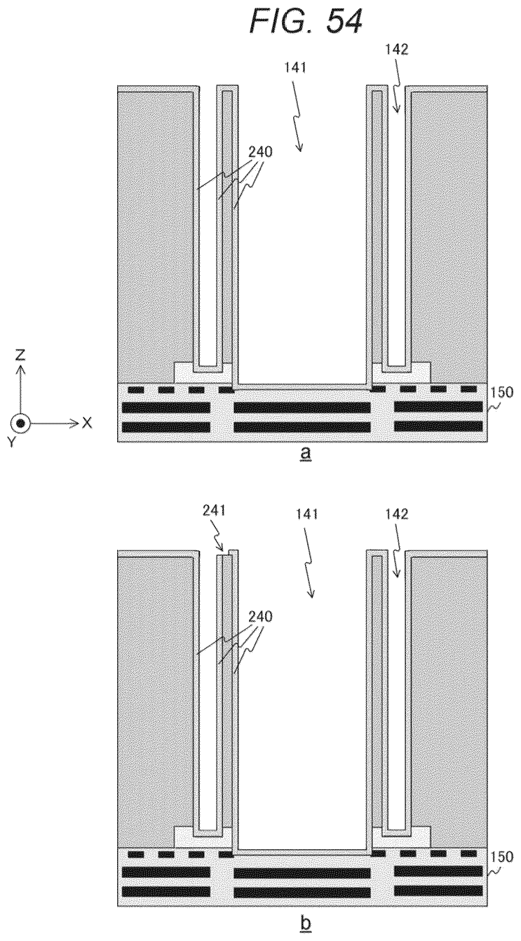

Next, as exemplified in a of FIG. 54, the insulating film 240 is formed by a CVD method. For example, by forming a film of tetra eth oxy silane (TEOS) with a thickness of 1 micrometer (μm) on the flat portion, a film with a thickness of 0.5 to 0.7 micrometers (μm) is formed on the side wall or the bottom portion of the through hole 141 or the annular trench 142. Note that, in addition to SiO₂, the insulating film 240 may be silicon nitride (SiN) or silicon oxynitride (SiON). In addition, the film formation can also be performed by an ALD method.

Next, as exemplified in b of the figure, a part of the insulating film 240 at the upper end of the annular trench 142 is opened by lithography and dry etching, and one hole 241 is formed.

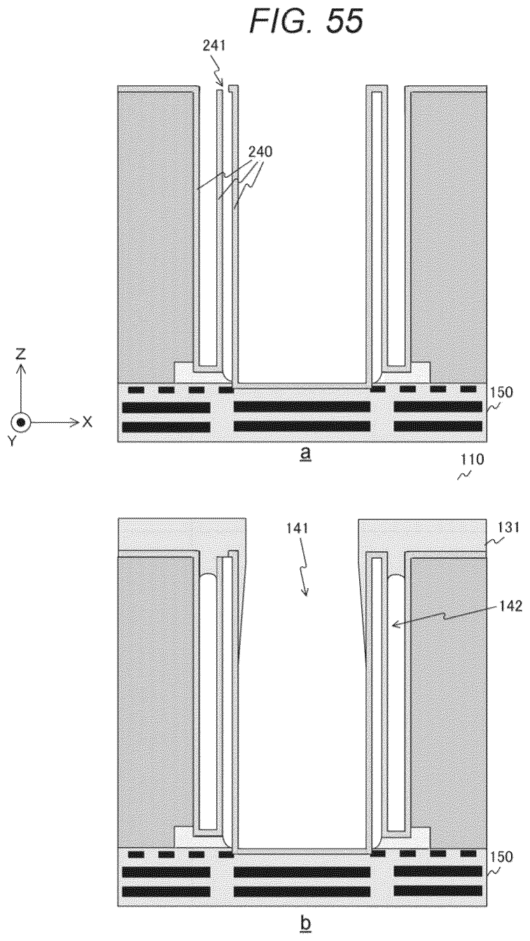

Next, as exemplified in a of FIG. 55, ring-shaped silicon between the through hole 141 and the annular trench 142 is removed via the hole 241 by chemical dry etching using SF₆ gas. At this time, the etching selectivity ratio to the insulating film 240 is 500 or more, and the scraping of the insulating film 240 when etching about 160 micrometers (μm) of the half circumferential length of ring-shaped silicon is 0.3 micrometers (μm) or less. Note that, in the removal of silicon, for example, wet etching using a tetramethyl ammonium hydroxide (TMAH) aqueous solution can also be used. In this case, a pattern of the plurality of holes 241 considering anisotropic etching of the silicon plane orientation is preferable.

Next, as exemplified in b of the figure, the back surface insulating film 131 is formed. For example, a photosensitive resin material is applied, and the resin material is patterned in accordance with the through hole 141 by lithography. At this time, the annular trench 142 is closed without being completely filled with the resin material, and becomes hollow.

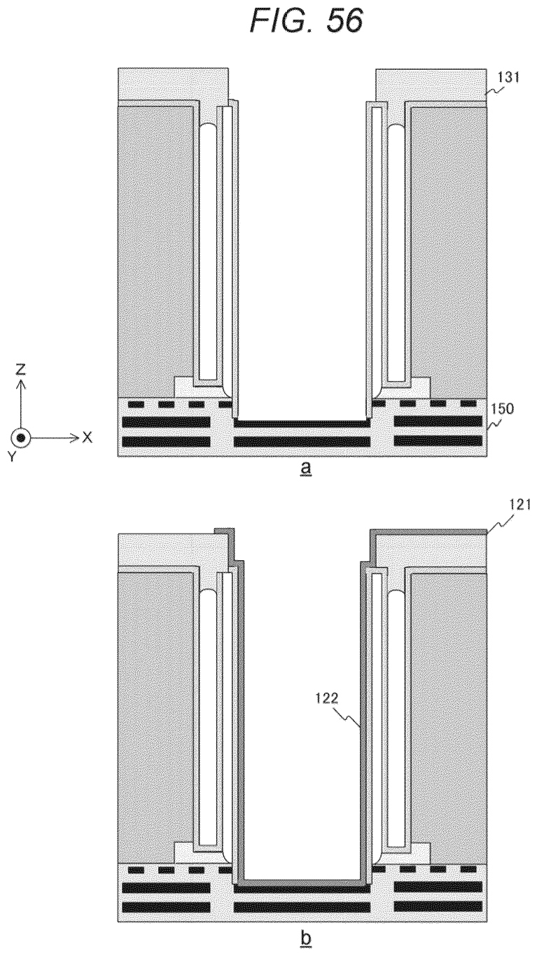

Next, as exemplified in a of FIG. 56, the insulating film 240 at the bottom portion of the through hole 141 and the interlayer film of the wiring layer 150 are removed by dry etching using the patterned resin material as a mask, and the metal wiring of the wiring layer 150 is exposed.

Next, as exemplified in b of the figure, the back surface rewiring 121 and the through wiring 122 are formed. For example, Cu wiring (the back surface rewiring 121 and the through wiring 122) is formed by a semi-additive method using a resist mask and Cu plating. Then, the solder mask 110 (not illustrated) is formed.

Note that each of the first to 10th embodiments can be applied to the 11th embodiment.

As described above, according to the 11th embodiment of the present technology, since the depletion layer 250 is formed in the insulating film 240 between the through hole 141 and the annular trench 142, the reliability of the device can be improved.

### First Modification

In the above-described 11th embodiment, one hole 241 is formed at the upper end of the annular trench 142, but it may be difficult to remove ring-shaped silicon with one hole. A semiconductor device 100 according to a first modification of the 11th embodiment is different from that of the 11th embodiment in that two or more holes 241 are provided.

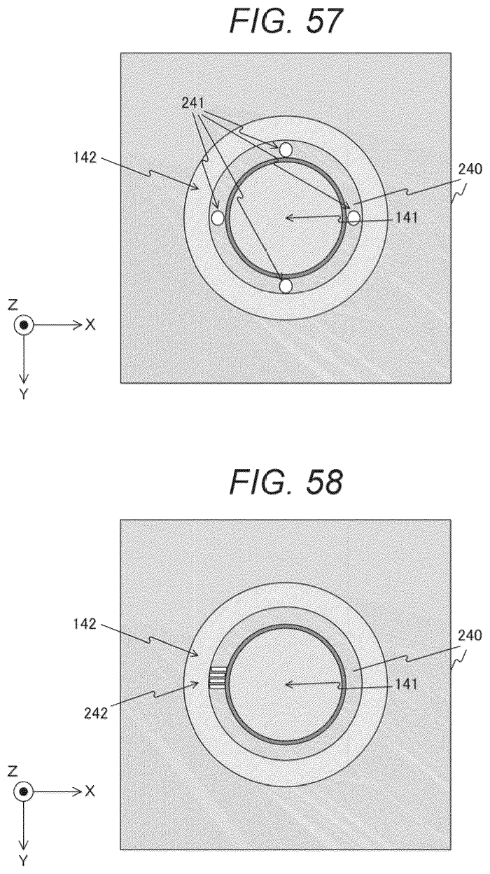

FIG. 57 is an example of a cross-sectional view of the semiconductor device 100 in the first modification of the 11th embodiment of the present technology. The figure is a cross-sectional view taken along a line segment X11-X12 in FIG. 51 and viewed from the Z-axis direction.

As exemplified in FIG. 57, in the first modification of the 11th embodiment, two or more holes 241 are formed. This facilitates removal of ring-shaped silicon.

Note that each of the first to ninth embodiments can be applied to the first modification of the 11th embodiment.

As described above, according to the first modification of the 11th embodiment of the present technology, since two or more holes 241 are provided, ring-shaped silicon can be easily removed.

### Second Modification

In the above-described 11th embodiment, the circular or elliptical hole 241 is opened at the upper end of the annular trench 142, but the shape of the opening is not limited to a circle or an ellipse. A semiconductor device 100 according to a second modification of the 11th embodiment is different from that of the 11th embodiment in that a slit is formed.

FIG. 58 is an example of a cross-sectional view of the semiconductor device 100 in the second modification of the 11th embodiment of the present technology. The figure is a cross-sectional view taken along a line segment X11-X12 in FIG. 51 and viewed from the Z-axis direction.

As exemplified in FIG. 58, in the second modification of the 11th embodiment, one or more cuts are formed as slits 242 along a predetermined direction instead of the holes 241.

Note that each of the first to ninth embodiments can be applied to the second modification of the 11th embodiment.

As described above, according to the second modification of the 11th embodiment of the present technology, since the slit 242 is formed at the upper end of the annular trench 142, the ring-shaped trench can be removed via the slit 242.

### 12. 12th Embodiment

In the second embodiment described above, the back surface insulating film 132 (SiO₂ or the like) is formed on the inner wall of the through hole 141, but in this configuration, the shape of the bottom portion may be a notch or a trailing shape when the through hole 141 is formed. In this case, the back surface insulating film 132 becomes thin at a portion having a notch or a trailing shape, and a problem of a withstand voltage failure or a decrease in reliability occurs. A semiconductor device 100 according to a 12th embodiment is different from that of the second embodiment in that notches and a trailing shape are suppressed.

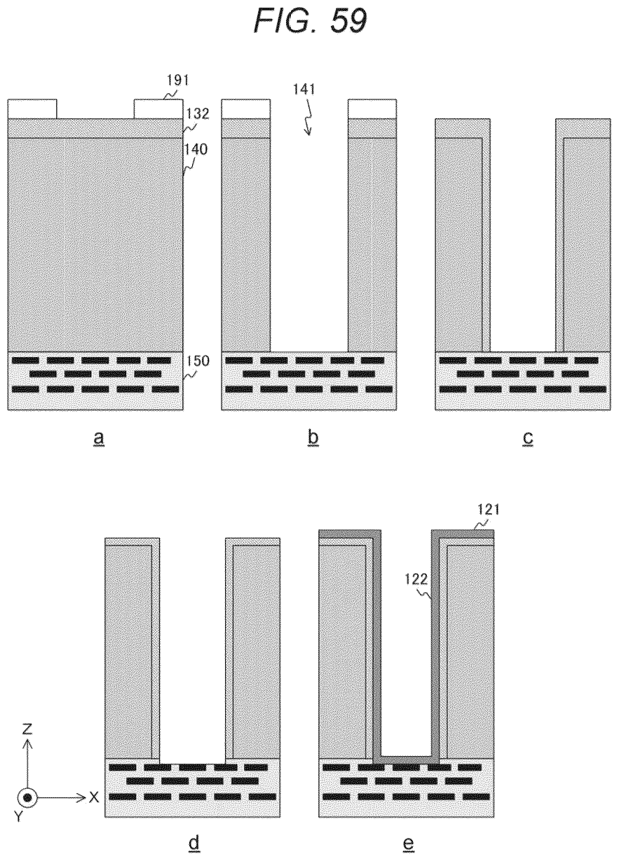

FIG. 59 is a diagram illustrating an example in which an ideal through hole is formed according to the second embodiment of the present technology. In the figure, the annular trench 142 is omitted. It similarly applies to the subsequent drawings.

As exemplified in a of the figure, a photoresist 191 is formed on the upper surface of the back surface insulating film 132 except for the processed position. Then, as exemplified in b of the figure, the through hole 141 penetrating the semiconductor substrate 140 is formed. Then, the photoresist 191 is removed, and the back surface insulating film 132 is also formed on the inner wall of the through hole 141 as exemplified in c of the figure. Subsequently, the back surface insulating film 132 is etched back as exemplified in d of the figure. Then, as exemplified in e of the figure, metal wiring (the back surface rewiring 121 and the through wiring 122) is formed. In a case where the through hole 141 has an ideal shape as illustrated in the figure, problems such as a withstand voltage failure and a decrease in reliability do not occur.

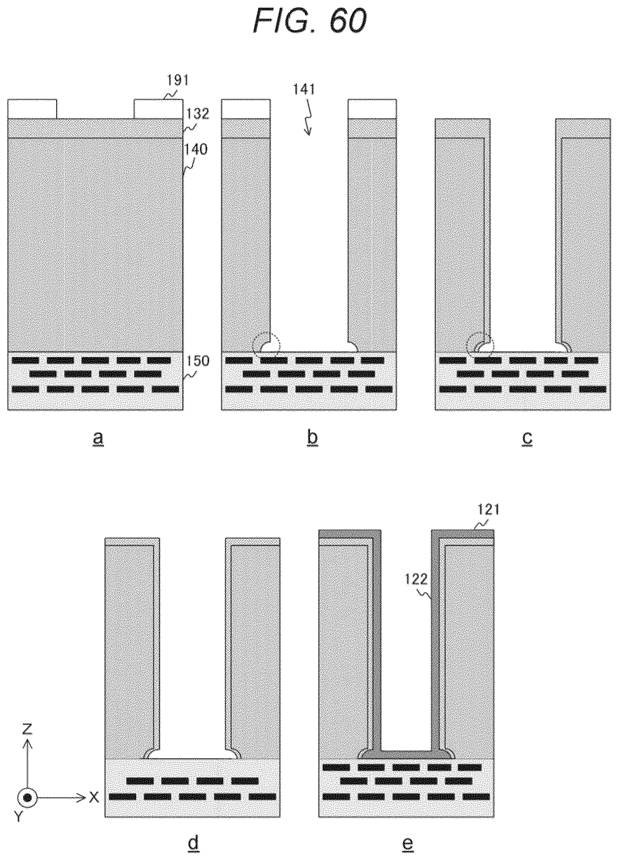

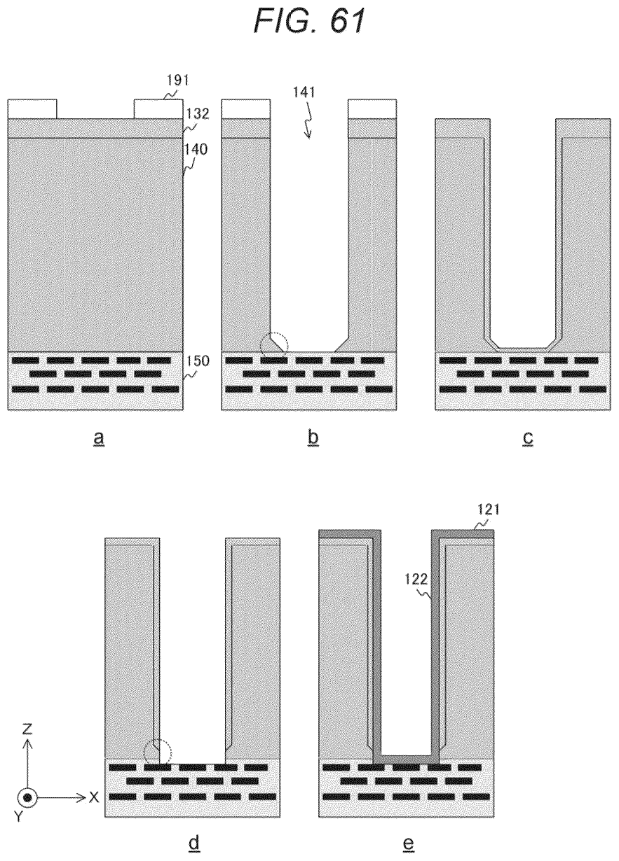

However, as exemplified in FIG. 60, a notch may be generated at the bottom portion of the through hole 141. The silicon processing of the semiconductor substrate 140 is performed so as to reach the wiring layer 150, but when the processing reaches the wiring layer 150, there is no silicon to be processed. For this reason, as exemplified in a portion surrounded by a dotted line in b of the figure, silicon is processed in the lateral direction to form a shape called a notch. In the portion of the notch, the back surface insulating film 132 formed in c of the figure becomes thin. For this reason, problems such as a withstand voltage failure and a decrease in reliability occur.

Furthermore, as exemplified in FIG. 61, the bottom portion of the through hole 141 may have a trailing shape. In a case where the silicon processing is insufficient, as exemplified in a portion surrounded by a dotted line in b of the figure, the silicon has a trailing shape. In this case, the back surface insulating film 132 on the silicon side wall becomes thin by the etch-back processing in d of the figure, and problems such as a withstand voltage failure and a decrease in reliability occur.

In particular, in a case where silicon processing is simultaneously performed on the respective portions of the through hole 141 and the annular trench 142, the etching rate is different, so that the etching amount of a pattern having an early etching rate increases, and a notch is likely to occur.

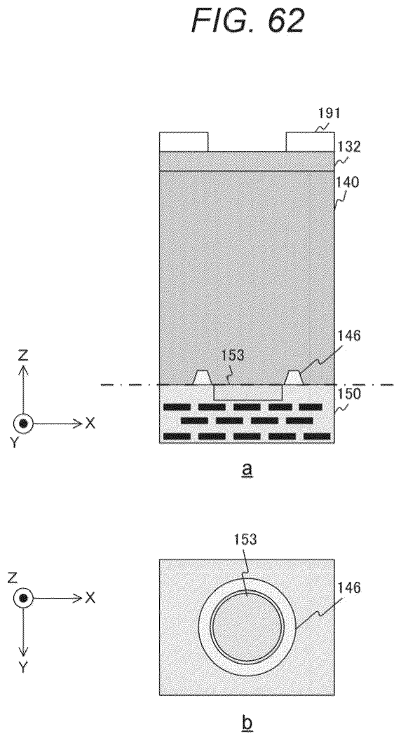

FIG. 62 is an example of a cross-sectional view of the semiconductor device 100 before formation of the through hole 141 according to the 12th embodiment of the present technology. In the 12th embodiment, an element isolation region (STI) 146 and a dummy polysilicon 153 are further disposed in order to prevent the notch and the trailing shape described above. a in the figure is an example of a cross-sectional view of the semiconductor device 100 as viewed from the Y-axis direction. b in the figure is an example of a cross-sectional view taken along an alternate long and short dash line in a of the figure and viewed from the Z-axis direction. Note that the element isolation region 146 is an example of a first element isolation region described in the claims.

As exemplified in a and b of the figure, in the semiconductor substrate 140, the element isolation regions 146 are disposed in a ring shape around the region to be the bottom portion of the through hole 141. Furthermore, in the wiring layer 150, the dummy polysilicon 153 is disposed in a region where silicon processing reaches the wiring layer 150 and becomes the bottom portion of the through hole 141. As exemplified in b of the figure, the dummy polysilicon 153 is circular when viewed from the Z-axis direction, and its diameter is smaller than the inner diameter of the element isolation region 146.

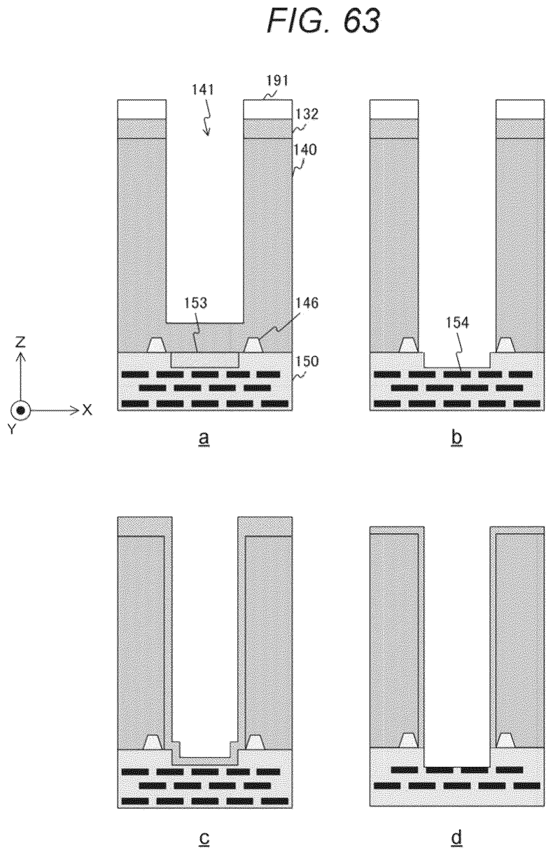

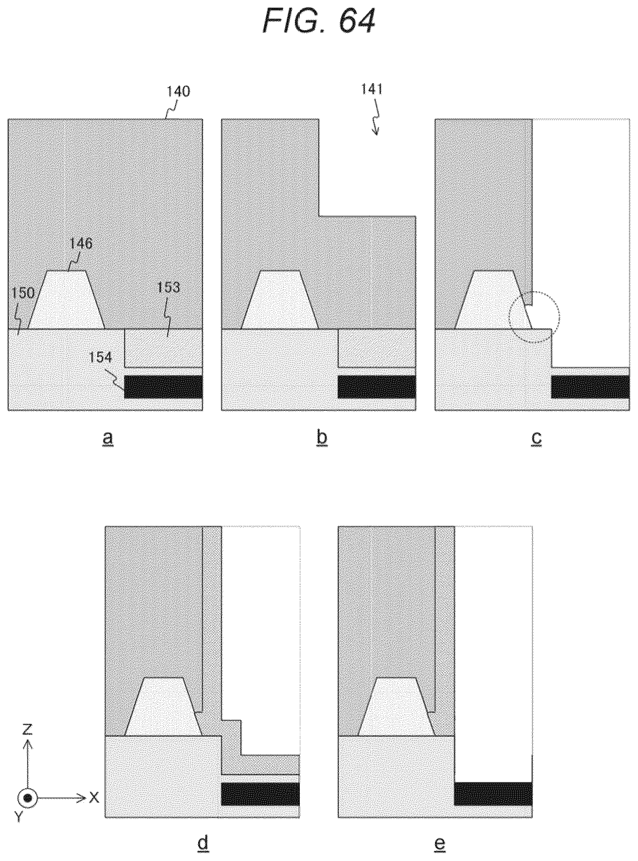

FIG. 63 is a diagram for explaining the method for manufacturing the semiconductor device 100 up to etch-back according to the 12th embodiment of the present technology. For the semiconductor device 100 in the state of FIG. 62, silicon processing is started as exemplified in a of FIG. 63. a of FIG. 63 illustrates a state in the middle of processing.

Then, as exemplified in b of FIG. 63, the silicon processing proceeds until the dummy polysilicon 153 is removed, and the insulating film in the wiring layer 150 remaining on the upper portion of the Cu wiring 154 in the wiring layer 150 becomes thin. After the silicon processing, as exemplified in c of the figure, the back surface insulating film 132 is formed so as to cover the side wall and the bottom surface of the through hole 141. Subsequently, as exemplified in d of the figure, the insulating film is processed by etch-back until the Cu wiring 154 is exposed. In d of the figure, processing for adding the respective film thicknesses of the insulating film on the upper portion of the Cu wiring 154 remaining in b of the figure and the back surface insulating film 132 formed in c of the figure is required. Note that, in the figure, the procedure after the wiring of the through wiring 122 is omitted.

With the arrangement of the element isolation regions 146, it is possible to suppress the occurrence of notches and trailing shapes and to improve the withstand voltage and the reliability. In addition, since the insulating film on the upper portion of the Cu wiring 154 is thinned by the dummy polysilicon 153, the processing amount of the insulating film for exposing the Cu wiring 154 can be reduced. As a result, the processing amount of the back surface insulating film 132 on the side wall of the through hole 141 is also reduced, and the withstand voltage and the reliability can be improved.

Note that, although both the element isolation region 146 and the dummy polysilicon 153 are disposed, only the element isolation region 146 may be disposed. In addition, although the annular trench 142 (not illustrated) is formed around the through hole 141, the annular trench 142 may not be formed.

FIG. 64 is an enlarged view of the vicinity of the element isolation region 146 according to the 12th embodiment of the present technology. a in the figure is an enlarged view of FIG. 62, and b, c, d, and e in FIG. 64 are enlarged views of a, b, c, and d in FIG. 63. As exemplified in a portion surrounded by a dotted line in c of FIG. 64, a minute notch may be generated, but enlargement of the notch is suppressed by the element isolation region 146. In addition, the arrangement position of the dummy polysilicon 153 is processed deeper than its periphery, and becomes a contact position with the metal (through wiring 122) by self-alignment.

As described above, according to the 12th embodiment of the present technology, since the ring-shaped element isolation region 146 and the dummy polysilicon 153 are disposed, it is possible to suppress the occurrence of notches and trailing shapes and to improve the withstand voltage and the reliability.

### First Modification

In the above-described 12th embodiment, the circular dummy polysilicon 153 is disposed when viewed from the Z-axis direction, but the shape of the dummy polysilicon 153 is not limited to this shape. A semiconductor device 100 according to a first modification of the 12th embodiment is different from that of the 12th embodiment in that the shape of the dummy polysilicon 153 is changed.

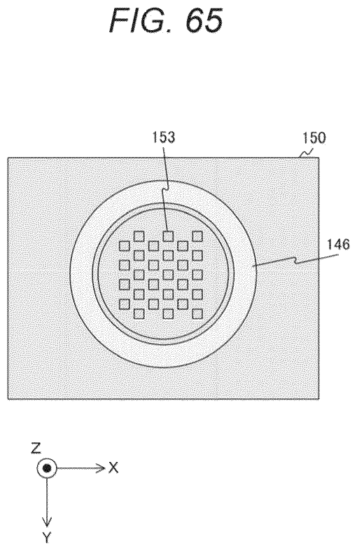

FIG. 65 is an example of a cross-sectional view of the semiconductor device 100 in the first modification of the 12th embodiment of the present technology. The figure is an example of a cross-sectional view viewed from the Z-axis direction. The shape of the dummy polysilicon 153 is not limited to a circle, and can be formed in various patterns. For example, the dummy polysilicon 153 is formed in a dot pattern.

As described above, according to the first modification of the 12th embodiment of the present technology, the dummy polysilicon 153 can be formed in various patterns other than a circle.

### Second Modification

In the above-described 12th embodiment, the circular dummy polysilicon 153 is disposed when viewed from the Z-axis direction, but the shape of the dummy polysilicon 153 is not limited to this shape. A semiconductor device 100 according to a second modification of the 12th embodiment is different from that of the 12th embodiment in that the shape of the dummy polysilicon 153 is changed.

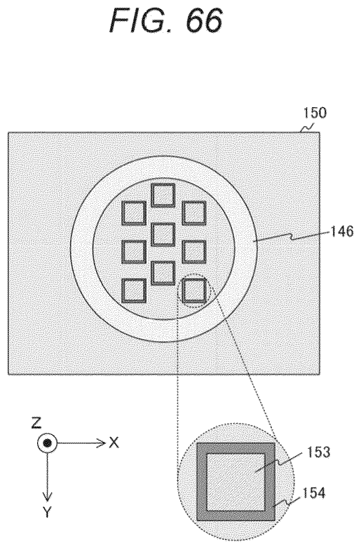

FIG. 66 is an example of a cross-sectional view of the semiconductor device 100 in the second modification of the 12th embodiment of the present technology. The figure is an example of a cross-sectional view viewed from the Z-axis direction. The pattern of the dummy polysilicon 153 is, for example, a dot pattern, and each of the dot-shaped dummy polysilicon 153 is disposed in a region corresponding to the Cu wiring 154. The area of each dummy polysilicon 153 is smaller than the corresponding Cu wiring 154. As a result, the portion of the Cu wiring 154 can be opened by self-alignment at the time of etch-back.

As described above, according to the second modification of the 12th embodiment of the present technology, since the dot-shaped dummy polysilicon 153 is disposed in the region corresponding to the Cu wiring 154, the portion of the Cu wiring 154 can be opened by self-alignment at the time of etch-back.

### 13. 13th Embodiment

In the first embodiment described above, the annular trench 142 is formed around the through hole 141, but in this case, the base material (silicon or the like) of the semiconductor substrate 140 remains in a ring shape between the through hole 141 and the annular trench 142. In this configuration, a pattern layout such as securing a sufficient width of the cavity in the annular trench 142 in order to increase the withstand voltage of the back surface rewiring 121 or securing a sufficient ring width in order to suppress peeling of the ring-shaped silicon is required. Therefore, there is a problem that high integration of patterns becomes difficult. A semiconductor device 100 according to a 13th embodiment is different from that of the first embodiment in that a low-k material is disposed between the through hole 141 and the annular trench 142.

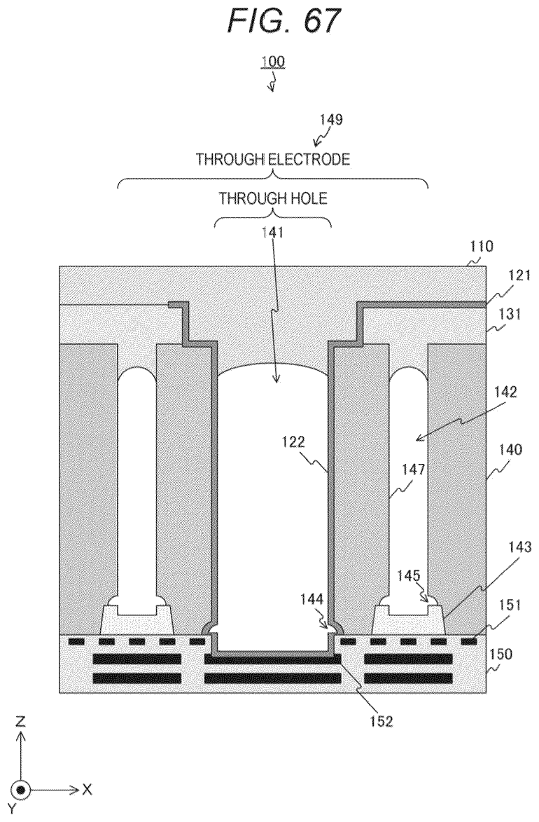

FIG. 67 is a cross-sectional view illustrating a configuration example of the semiconductor device 100 according to the 13th embodiment of the present technology. The semiconductor device 100 according to the 13th embodiment is different from that of the first embodiment in that a ring-shaped low-k material 147 is disposed between the through hole 141 and the annular trench 142.

The low-k material 147 is a material having a dielectric constant lower than that of a base material (silicon or the like) of the semiconductor substrate 140. As the low-k material 147, silicon dioxide (SiO₂), carbon-containing silicon nitride (SiOC), or the like is used. By disposing the low-k material 147 between the through hole 141 and the annular trench 142, the dielectric constant can be reduced as compared with the first embodiment in which silicon is disposed, and a measure for peeling off of ring-shaped silicon around the through hole 141 becomes unnecessary. This facilitates high integration.

Note that, in the figure, the back surface of the semiconductor substrate 140 and the annular trench 142 are covered with the back surface insulating film 131, and the back surface insulating film 131 is covered with the solder mask 110. However, as described later, the back surface insulating film 131 may not be used.

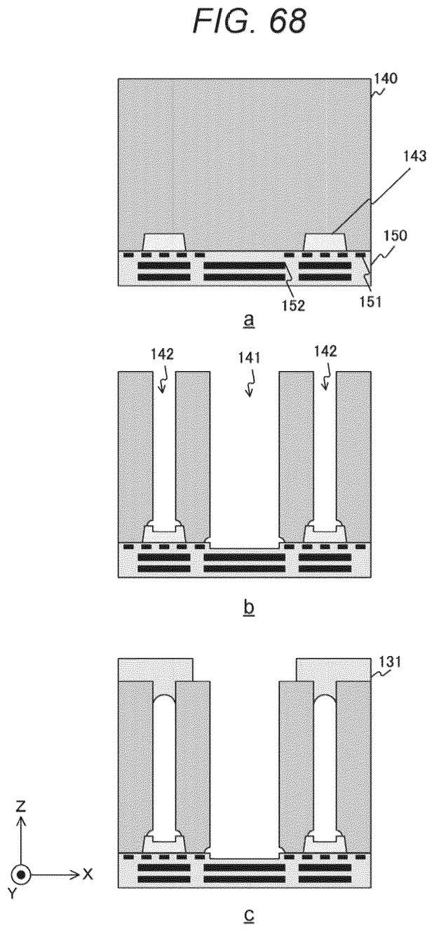

Next, a method for manufacturing the semiconductor device 100 according to the 13th embodiment of the present technology is illustrated in FIGS. 68 to 70.

First, as exemplified in a of FIG. 68, on the front surface side of the semiconductor substrate 140, the pad 152 is formed at the position of the subsequent through wiring 122, and the element isolation region 143 is formed at the position of the annular trench 142. In addition, the dummy gate 151 is formed up to the position of the annular trench 142.

Next, as exemplified in b of the figure, the through hole 141 and the annular trench 142 are formed by dry etching. Since the condition of the etching rate and the occurrence of the notch tend to be in a trade-off relationship, it is necessary to properly use the conditions as necessary. Note that the annular trench 142 can also be processed after the through hole 141 is processed and the side surface is hardened.

Next, as exemplified in c of the figure, after a photosensitive insulating resin is formed on the entire surface as the back surface insulating film 131, the photosensitive resin around the through hole 141 and the inside of the through hole 141 is removed by a lithography method, and is made into a permanent resin by annealing.

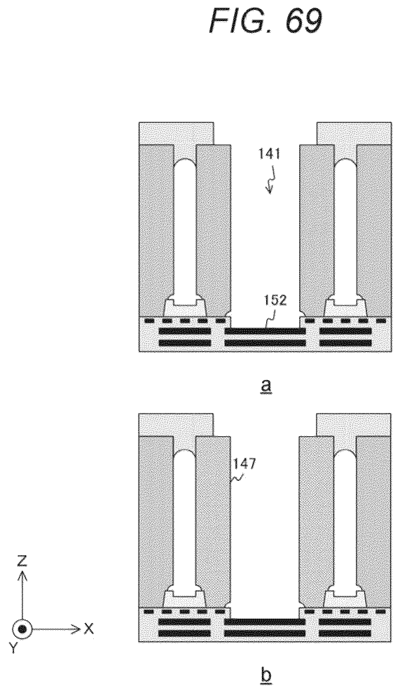

Then, as exemplified in a of FIG. 69, the entire surface is etched back, and the through hole 141 is connected to the pad 152 on the front surface side. Next, as exemplified in b of the figure, the low-k material 147 is formed by implantation of oxygen ions.

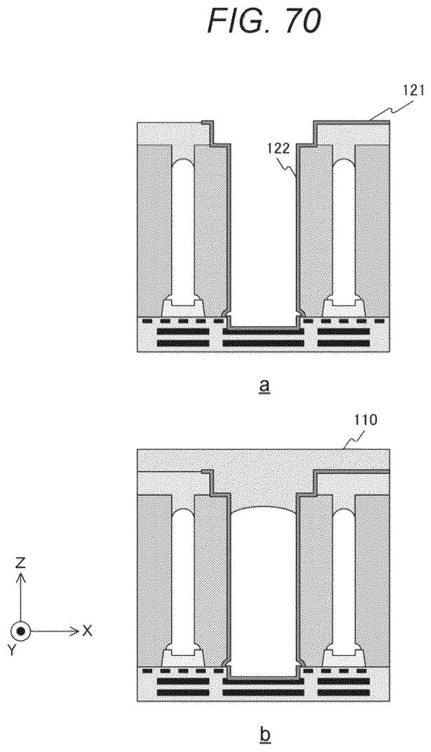

Then, as exemplified in a of FIG. 70, the back surface rewiring 121 and the through wiring 122 are simultaneously formed by a semi-additive method. Next, as exemplified in b of the figure, the solder mask 110 is formed.

As described above, according to the 13th embodiment of the present technology, since the ring-shaped low-k material 147 is disposed between the through hole 141 and the annular trench 142, the dielectric constant decreases, a measure for peeling of silicon becomes unnecessary, and high integration becomes easy.

### Modification

In the above-described 13th embodiment, the back surface of the semiconductor substrate 140 and the annular trench 142 are covered with the back surface insulating film 131. However, instead of the back surface insulating film 131, the back surface may be covered with the low-k material 147. A semiconductor device 100 according to a modification of the 13th embodiment is different from that of the 13th embodiment in that the back surface of the semiconductor substrate 140 is covered with the low-k material 147.

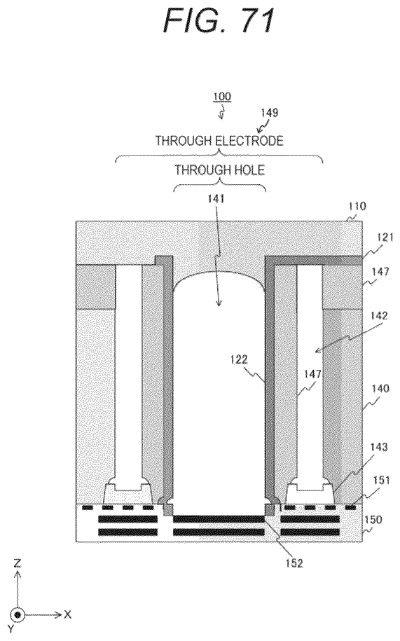

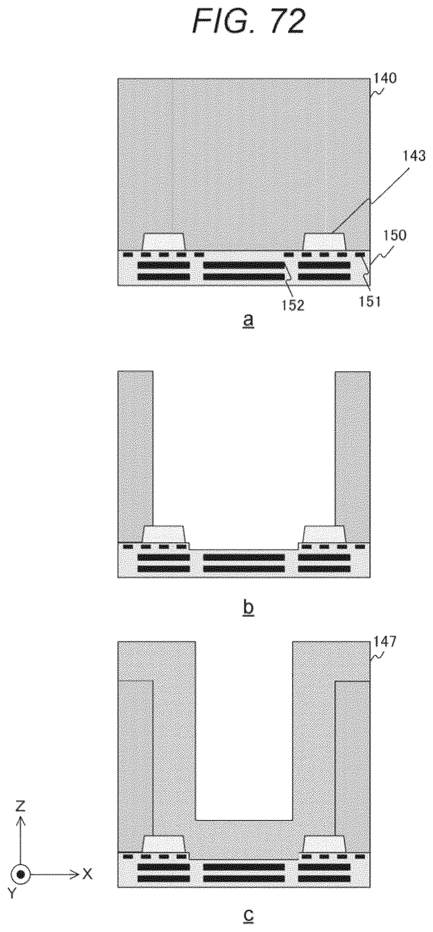

FIG. 71 is a cross-sectional view illustrating a configuration example of the semiconductor device 100 according to the modification of the 13th embodiment of the present technology. In the modification of the 13th embodiment, the back surface insulating film 131 is not provided, and instead, the back surface of the semiconductor substrate 140 is covered with the low-k material 147. In addition, the low-k material 147 covering the back surface and the upper end of the annular trench 142 are covered with the solder mask 110.

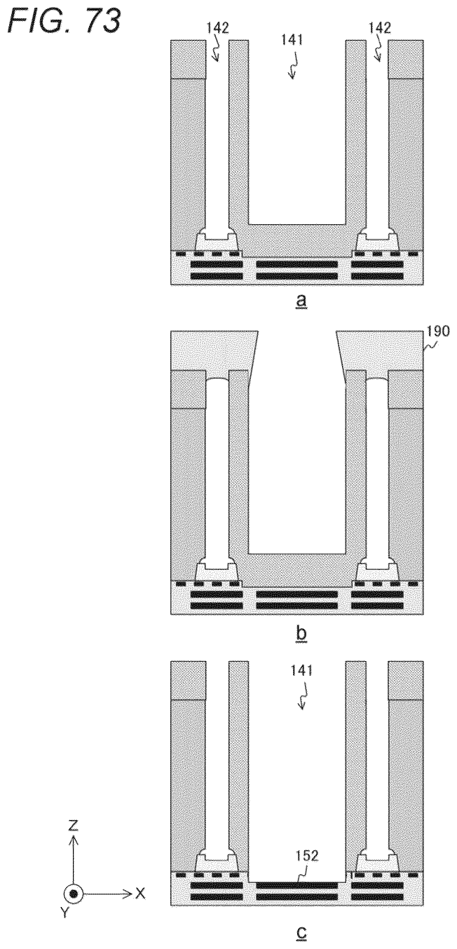

Next, FIGS. 72 to 74 illustrate a method for manufacturing the semiconductor device 100 according to the modification of the 13th embodiment of the present technology.

First, as exemplified in a of FIG. 72, on the front surface side of the semiconductor substrate 140, the pad 152 is formed at the position of the subsequent through wiring 122, and the element isolation region 143 is formed at the position of the annular trench 142. In addition, the dummy gate 151 is formed up to the position of the annular trench 142.

Next, as exemplified in b of the figure, a through hole having substantially the same diameter as the annular trench 142 is formed by dry etching. Then, as exemplified in c of the figure, a film of the low-k material 147 is formed.

Then, as exemplified in a of FIG. 73, the through hole 141 and the annular trench 142 are formed by dry etching on the low-k material 147 in the through hole. Next, as exemplified in b of the figure, the resist mask 190 is applied except for the through hole 141, and as exemplified in c of the figure, the through hole 141 is connected to the pad 152 on the front surface side by etch-back.

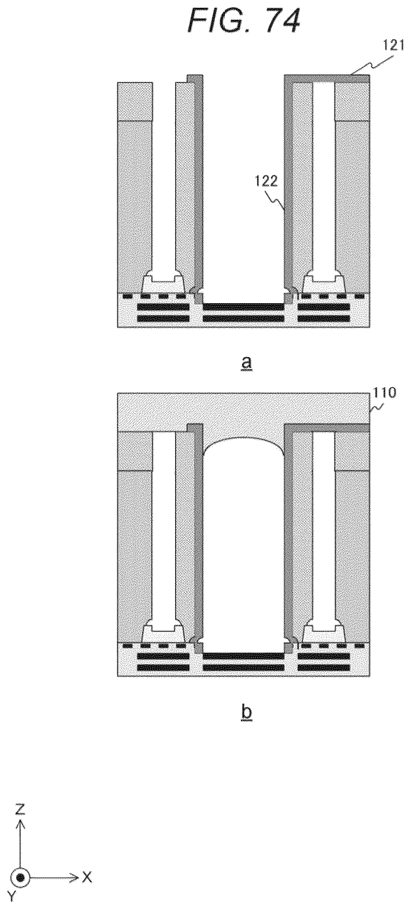

Then, as exemplified in a of FIG. 74, the back surface rewiring 121 and the through wiring 122 are simultaneously formed by a semi-additive method. Next, as exemplified in b of the figure, the solder mask 110 is formed.

As described above, according to the modification of the 13th embodiment of the present technology, since the back surface of the semiconductor substrate 140 is covered with the low-k material 147, the step of forming the back surface insulating film 131 becomes unnecessary.

### 14. 14th Embodiment

In the first embodiment described above, the parasitic capacitance is reduced by forming the hollow annular trench 142 around the through hole 141. However, when a high-frequency signal is transmitted, the signal may be affected by an electromagnetic wave from the outside. In addition, since the annular trench 142 is a cavity, the strength of the semiconductor substrate 140 may be weakened. A semiconductor device 100 according to a 14th embodiment is different from that of the first embodiment in that the annular trench 142 is filled with a conductive metal.

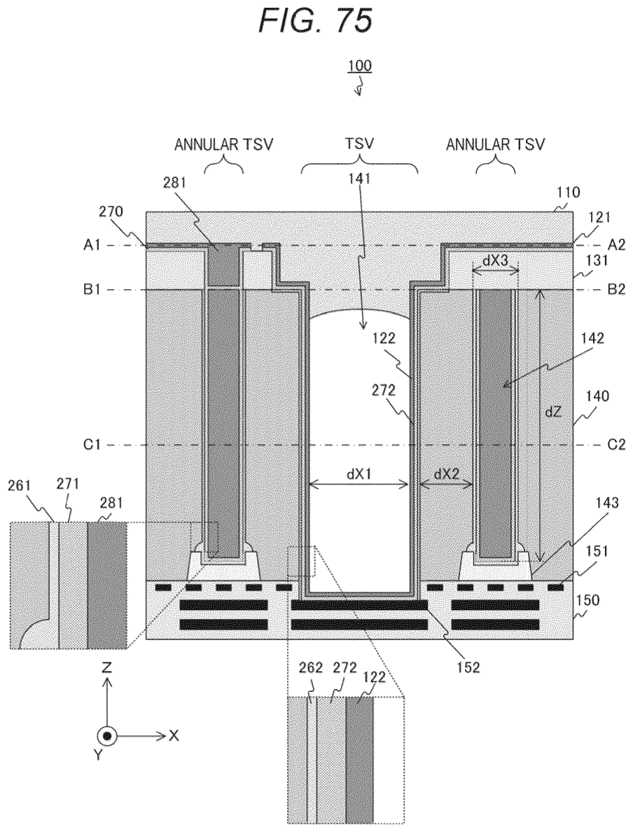

FIG. 75 is a cross-sectional view illustrating a configuration example of the semiconductor device 100 according to the 14th embodiment of the present technology. The semiconductor device 100 according to the 14th embodiment is different from that of the first embodiment in further including insulating films 261 and 262, barrier metals 271 and 272, and a conductive metal 281.

The side surface of the through hole 141 is covered with the barrier metal 272 via the insulating film 262. The back surface of the semiconductor substrate 140 is also covered with the barrier metal 272, and the back surface rewiring 121 on the back surface and the through wiring 122 on the side surface of the through hole 141 are formed on the barrier metal 272. The through hole 141 and the through wiring 122 are used as through silicon vias (TSVs).

In addition, the side surface of the annular trench 142 is covered with the barrier metal 271 via the insulating film 261. In addition, the conductive metal 281 is embedded in the annular trench 142. The conductive metal 281 is separated from the back surface rewiring 121 and the through wiring 122. The annular trench 142 in which the conductive metal 281 is embedded is used as a TSV different from the central TSV. The annular trench 142 filled with the conductive metal 281 is hereinafter referred to as “annular TSV”.

The size dX3 of the annular TSV in the X-axis direction (in other words, the width) is, for example, 3 micrometers (μm). In addition, dZ, which is the size (in other words, height) of the annular TSV in the Z-axis direction, is, for example, 30 micrometers (μm). When the aspect ratio (AR) exceeds 10, etching processing becomes difficult. Therefore, the size of the width and the height can be freely set within a range in which an aspect ratio (AR) is 10 or less.

In addition, the through wiring 122 of the central TSV is connected to a signal potential, and exchanges an electrical signal (such as a high-frequency signal) with the external electrode. On the other hand, the conductive metal 281 of the annular TSV is connected to the same potential (ground potential or the like) as the potential of the semiconductor substrate 140, and does not exchange signals. As described above, the potential of the through wiring 122 is different from the potential of the conductive metal 281. With this structure, the annular TSV exerts a shielding effect for reducing the electromagnetic wave from the outside. In addition, an effect of increasing the strength of the semiconductor substrate 140 is generated.

In addition, dX1, which is the diameter of the inner periphery of the central TSV, is, for example, 15 micrometers (μm). The distance dX2 between the central TSV and the annular TSV in the X-axis direction is, for example, 5 micrometers (μm).

Note that insulating films 261 and 262 are examples of first and second insulating films described in the claims. The barrier metals 271 and 272 are examples of first and second barrier metals described in the claims.

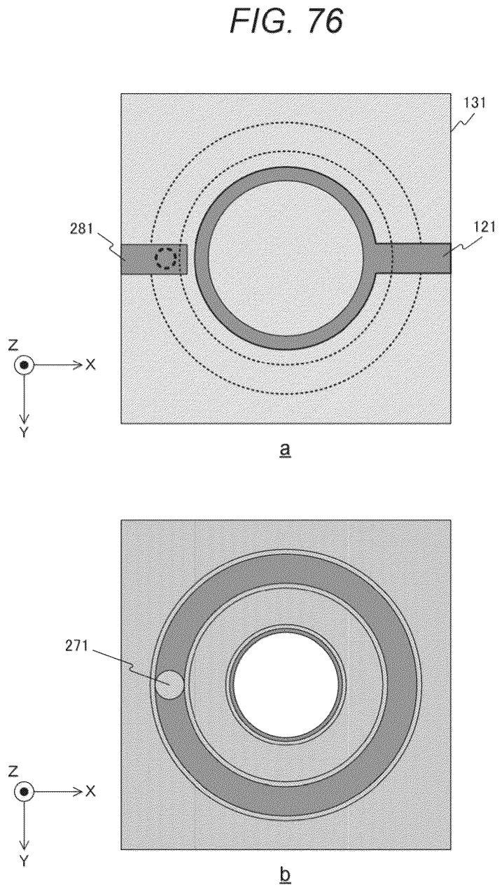

FIG. 76 is an example of a cross-sectional view of the semiconductor device taken along line segments A1-A2 and B1-B2 according to the 14th embodiment of the present technology. a of FIG. 76 is an example of a cross-sectional view taken along a line segment A1-A2 of FIG. 75, and b of FIG. 76 is an example of a cross-sectional view taken along line B1-B2 of FIG. 75.

As exemplified in a of FIG. 76, the back surface rewiring 121 is formed in a ring shape along the inner periphery of the through hole 141 when viewed from the Z-axis direction, and a part thereof extends in the X-axis direction and is connected to an external electrode (not illustrated). In addition, the conductive metal 281 extends in the X-axis direction and is connected to the ground potential.

As exemplified in b of the figure, the circular barrier metal 271 is formed on a part of the upper surface of the annular TSV when viewed from the Z-axis direction. A thick dotted line in a of the figure indicates an outline of a circular portion in b of the figure.

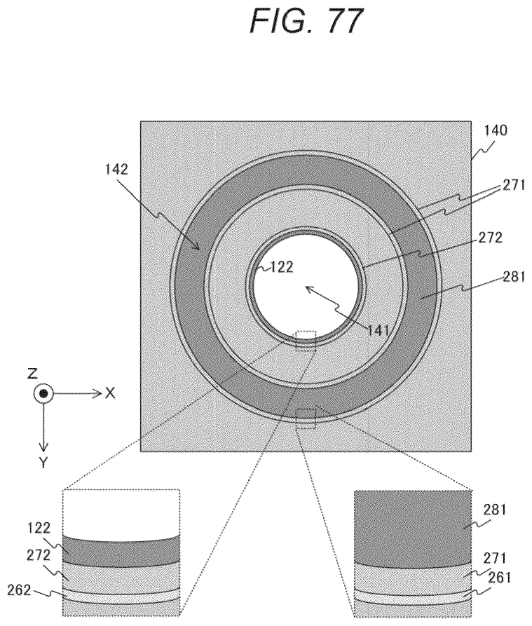

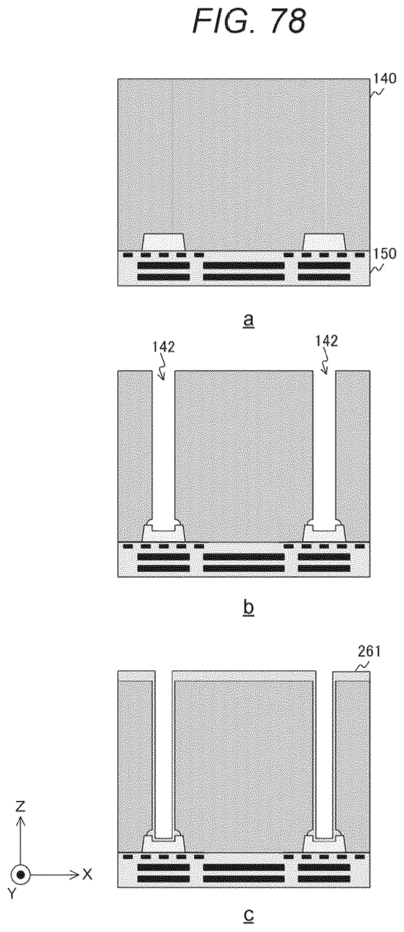

FIG. 77 is an example of a cross-sectional view of the semiconductor device taken along a line segment C1-C2 according to the 14th embodiment of the present technology. As exemplified in the figure, the side surface of the through hole 141 is covered with the barrier metal 272, and the through wiring 122 is formed on the barrier metal 272. The barrier metal 272 is separated from the semiconductor substrate 140 by the insulating film 262. In addition, the side surface of the annular trench 142 is covered with the barrier metal 271, and the conductive metal 281 is embedded in the annular trench 142. The barrier metal 271 is separated from the semiconductor substrate 140 by the insulating film 261.

Next, a method for manufacturing the semiconductor device 100 according to the 14th embodiment of the present technology is illustrated in FIGS. 78 to 80.

As exemplified in a of the figure, the semiconductor substrate 140 is placed such that the back surface, which is one of both surfaces of the semiconductor substrate 140 on which the wiring layer 150 is not formed, is on the upper side.

Then, as exemplified in b of the figure, the annular trench 142 is formed in the semiconductor substrate 140 by lithography and dry etching. Thereafter, as exemplified in c of the figure, the insulating film 261 is formed by a CVD method in order to ensure insulation property between the conductive metal 281 and the semiconductor substrate 140. As the insulating film 261, silicon oxynitride (SiON) or the like is used.

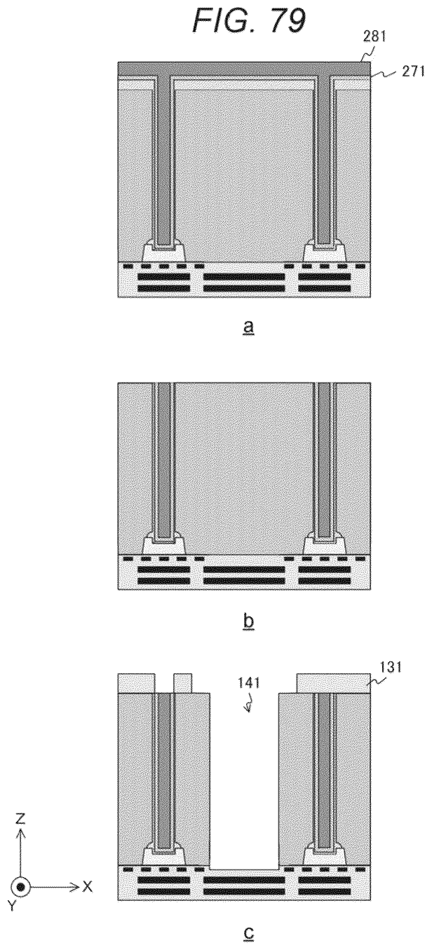

Next, as exemplified in a of FIG. 79, the barrier metal 271 and a seed metal are deposited by sputtering. As the barrier metal 271, for example, any one of titanium (Ti), titanium nitride (TiN), tantalum (Ta), tantalum nitride (TaN), and ruthenium (Ru) is used. Then, the annular trench 142 is filled with the conductive metal 281 by plating. As the conductive metal 281, for example, any of copper (Cu), aluminum (Al), tungsten (W), cobalt (Co), silver (Ag), gold (Au), iron (Fe), and lead (Pb) is used. Here, it is assumed that Cu is filled as the conductive metal 281.

Then, as exemplified in b of the figure, extra Cu on the back surface of the semiconductor substrate 140 and SiON are removed by chemical mechanical polishing (CMP). Then, as exemplified in c of the figure, the back surface insulating film 131 such as SiON is formed on the back surface. In addition, the through hole 141 is formed through the back surface insulating film 131.

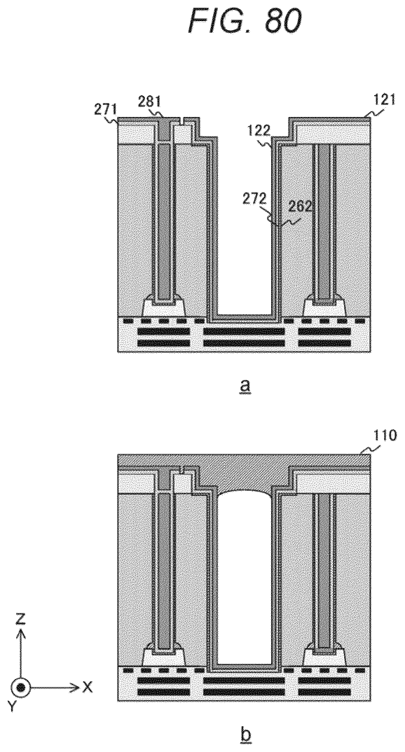

Next, as exemplified in a of FIG. 80, the conductive metal 281 is further formed by second Cu plating in order to ground the annular TSV. In addition, the insulating film 262 and the barrier metal 272 are formed, and the back surface rewiring 121 and the through wiring 122 are formed on the barrier metal 272. As a result, the central TSV is connected to the external electrode, and can be electrically exchanged.

Finally, as exemplified in b of the figure, the back surface is covered with the solder mask 110, and oxidation of the annular TSV, the central TSV, and the back surface rewiring 121 is prevented.

As described above, according to the 14th embodiment of the present technology, since the conductive metal 281 is embedded in the annular trench 142, electromagnetic waves from the outside can be blocked, and the strength of the semiconductor substrate 140 can be improved.

### First Modification

In the above-described 14th embodiment, the conductive metal 281 is embedded in the annular trench 142, but in this configuration, it is preferable to further reduce the parasitic capacitance. A semiconductor device 100 according to a first modification of the 14th embodiment is different from that of the 14th embodiment in that an annular trench is doubled.

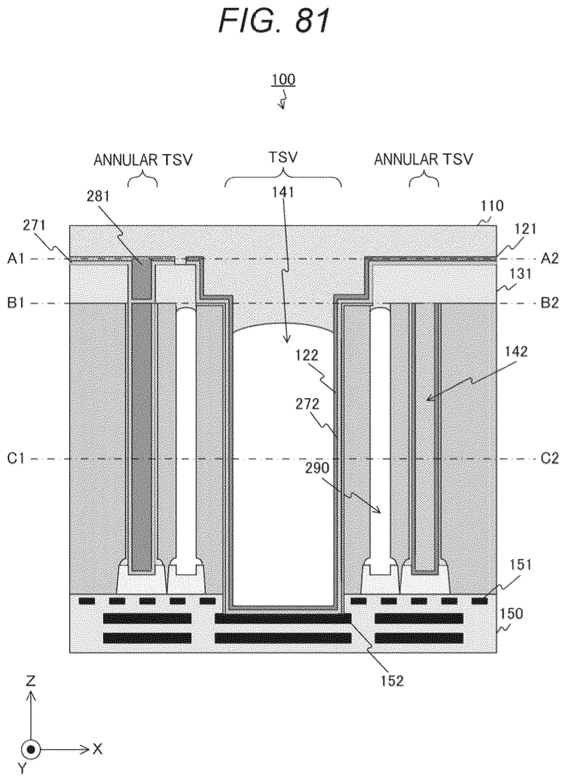

FIG. 81 is a cross-sectional view illustrating a configuration example of the semiconductor device 100 in the first modification of the 14th embodiment of the present technology. The semiconductor device 100 according to the first modification of the 14th embodiment is different from that of the first embodiment in that a hollow annular trench 290 is further formed between the annular trench 142 and the through hole 141. Note that the annular trench 142 is an example of a first annular trench described in the claims, and the annular trench 290 is an example of a second annular trench described in the claims.

As exemplified in the figure, by adding the hollow annular trench 290, the parasitic capacitance can be reduced as compared with the 14th embodiment.

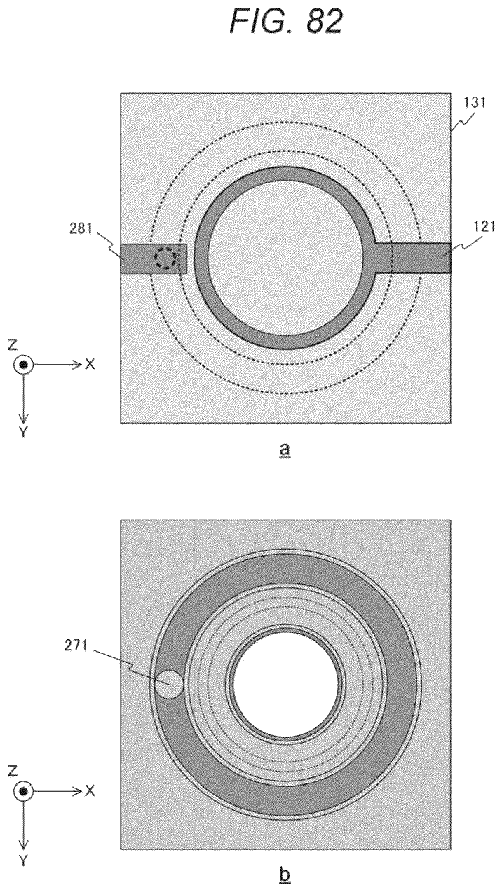

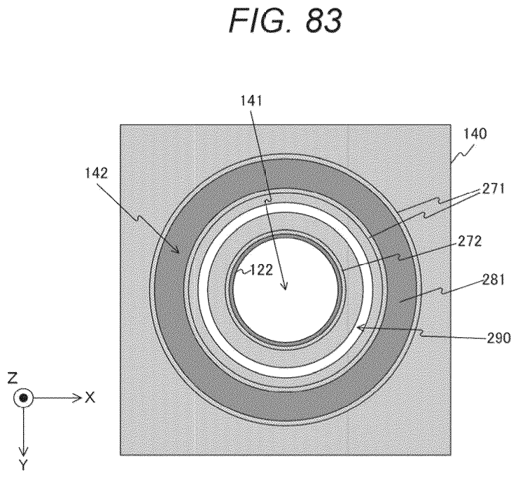

FIG. 82 is an example of a cross-sectional view of the semiconductor device taken along line segments A1-A2 and B1-B2 in the first modification of the 14th embodiment of the present technology. a of FIG. 82 is an example of a cross-sectional view taken along a line segment A1-A2 of FIG. 81, and b of FIG. 82 is an example of a cross-sectional view taken along line B1-B2 of FIG. 81.

As exemplified in a of FIG. 82, a cross-sectional view taken along a line segment A1-A2 in the first modification of the 14th embodiment is similar to that of the 14th embodiment. As exemplified in b of the figure, also in the first modification of the 14th embodiment, the circular barrier metal 271 is formed on a part of the upper surface of the annular TSV.

FIG. 83 is an example of a cross-sectional view of the semiconductor device taken along a line segment C1-C2 in the first modification of the 14th embodiment of the present technology. As exemplified in the figure, the hollow annular trench 290 is formed between the annular trench 142 and the through hole 141.

As described above, according to the first modification of the 14th embodiment of the present technology, since the hollow annular trench 290 is further formed between the annular trench 142 and the through hole 141, the parasitic capacitance can be reduced.

### Second Modification

In the above-described 14th embodiment, the conductive metal 281 is embedded in the annular trench 142, but with this configuration, it is difficult to block a plurality of types of electromagnetic waves. A semiconductor device 100 according to a second modification of the 14th embodiment is different from that of the first embodiment in that an annular trench 290 in which a conductive metal 282 is embedded is further formed between the annular trench 142 and the through hole 141.

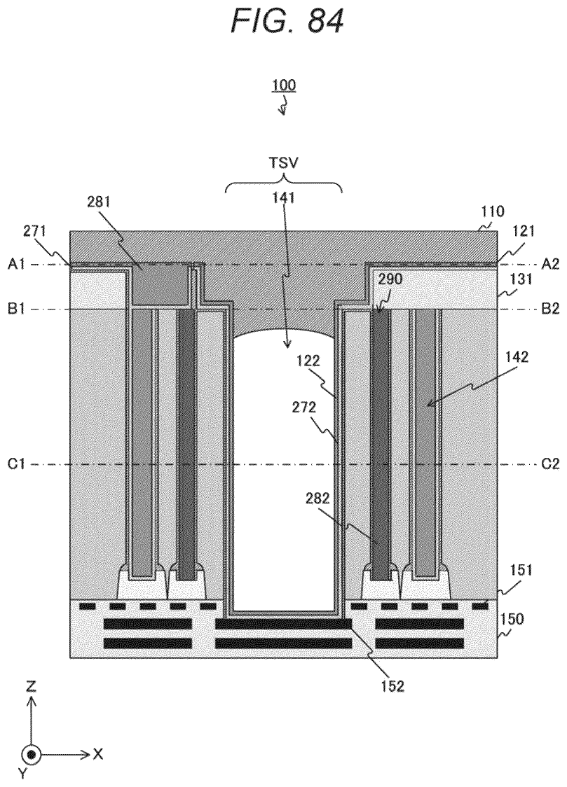

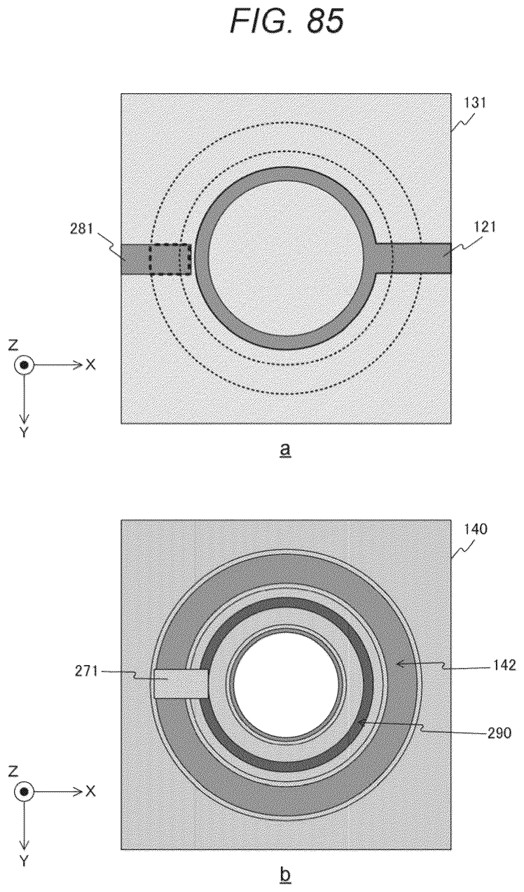

FIG. 84 is a cross-sectional view illustrating a configuration example of the semiconductor device 100 according to the second modification of the 14th embodiment of the present technology. The semiconductor device 100 according to the second modification of the 14th embodiment is different from that of the first embodiment in that the annular trench 290 in which the conductive metal 282 is embedded is further formed between the annular trench 142 and the through hole 141.

The type of the conductive metal 282 is different from that of the conductive metal 281. For example, Cu is used as the conductive metal 281, and Fe is used as the conductive metal 282. Cu blocks beta rays, and Fe blocks alpha rays and gamma rays. As described above, by filling the double annular trenches with the conductive metals 281 and 282 of different types, it is possible to block a plurality of types of electromagnetic waves from the outside. As a result, the semiconductor device 100 can be applied to a device mounted on an aircraft or medical equipment.

Note that the annular trench 142 is an example of a first annular trench described in the claims, and the annular trench 290 is an example of a second annular trench described in the claims. Conductive metals 281 and 282 are examples of first and second conductive metals described in the claims.

FIG. 85 is an example of a cross-sectional view of the semiconductor device taken along line segments A1-A2 and B1-B2 in the second modification of the 14th embodiment of the present technology. a of FIG. 85 is an example of a cross-sectional view taken along a line segment A1-A2 of FIG. 84, and b of FIG. 85 is an example of a cross-sectional view taken along line B1-B2 of FIG. 84.

As exemplified in a of FIG. 85, a cross-sectional view taken along a line segment A1-A2 in the second modification of the 14th embodiment is similar to that of the 14th embodiment. As exemplified in b of the figure, in the second modification of the 14th embodiment, the barrier metal 271 is formed in a region straddling the annular trenches 142 and 290. The shape of this portion when viewed from the Z-axis direction is a rectangle in b of the figure, but is not limited to a rectangle, and may be an ellipse or the like.

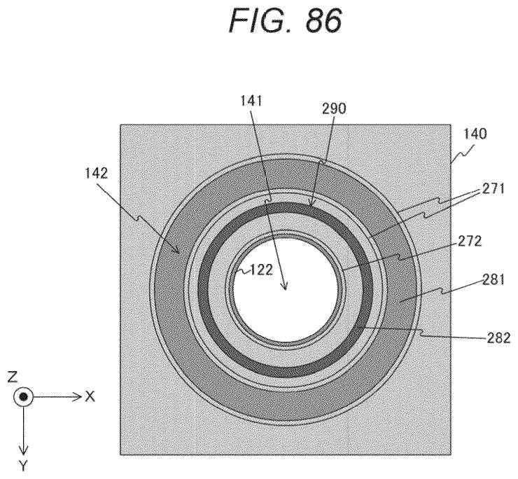

FIG. 86 is an example of a cross-sectional view of the semiconductor device taken along a line segment C1-C2 in the second modification of the 14th embodiment of the present technology. As exemplified in the figure, the annular trench 290 in which the conductive metal 282 is embedded is formed between the annular trench 142 and the through hole 141.

As described above, according to the first modification of the 14th embodiment of the present technology, since the annular trench 290 in which the conductive metal 282 is embedded is further formed between the annular trench 142 and the through hole 141, it is possible to block a plurality of types of electromagnetic waves from the outside.

### 15. Application Example to Mobile Body

The technology according to the present disclosure (present technology) can be applied to various products. For example, the technology according to the present disclosure may be realized as a device mounted on any type of mobile body such as an automobile, an electric vehicle, a hybrid electric vehicle, a motorcycle, a bicycle, a personal mobility, an airplane, a drone, a ship, and a robot.

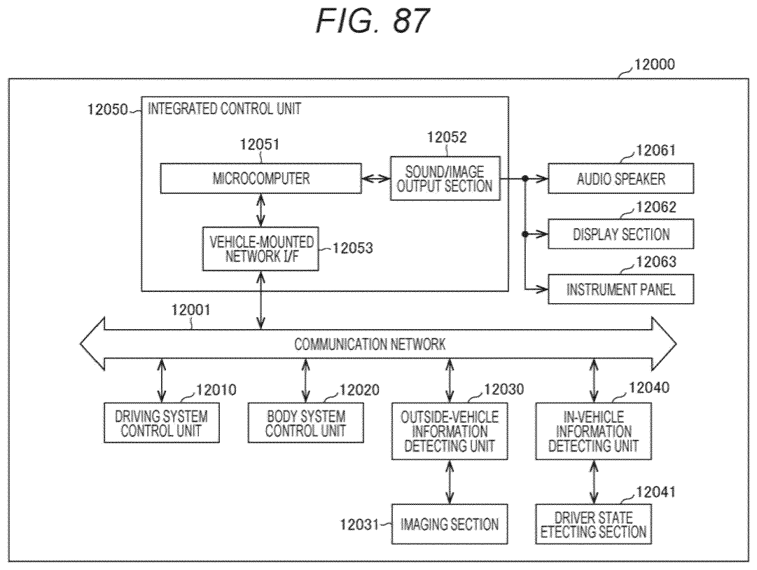

FIG. 87 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 87, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 87, an audio speaker 12061, a display section 12062, and an instrument panel 12063 are illustrated as the output device. The display section 12062 may, for example, include at least one of an on-board display and a head-up display.

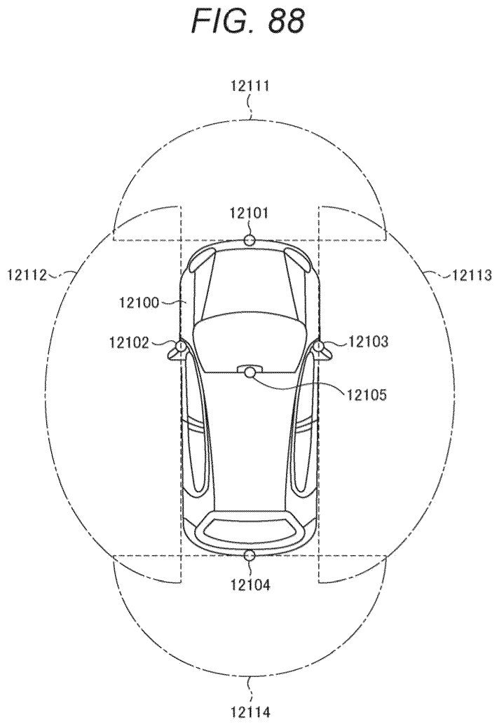

FIG. 88 is a diagram depicting an example of the installation position of the imaging section 12031.

In FIG. 88, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 88 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to, for example, the imaging section 12031 among the configurations described above. Specifically, the semiconductor device 100 in FIG. 1 can be applied to the imaging section 12031. By applying the technology according to the present disclosure to the imaging section 12031, it is possible to increase the yield of the semiconductor device 100 and improve the reliability of the vehicle control system.

Note that the embodiments described above illustrate examples for embodying the present technology, and the matters in the embodiments and the matters specifying the invention in the claims have correspondence relationships. Similarly, the matters specifying the invention in the claims and matters with the same names in the embodiments of the present technology have correspondence relationships. However, the present technology is not limited to the embodiments, and can be embodied by applying various modifications to the embodiments without departing from the gist of the present technology.

Note that advantageous effects described in the present specification are merely examples and are not limited, and other advantageous effects may be provided.

Note that the present technology may also have the following configurations.
(1) A semiconductor device including:
a semiconductor substrate having a wiring layer formed on a front surface of the semiconductor substrate;
a through hole penetrating the semiconductor substrate;
a through wiring formed along a side surface of the through hole; and
an annular trench surrounding a periphery of the through hole when viewed from a direction perpendicular to a back surface of the semiconductor substrate with respect to the front surface.
(2) The semiconductor device according to (1),
in which a cavity is formed inside the annular trench when viewed from a direction parallel to the back surface.
(3) The semiconductor device according to (2), further including
a back surface insulating film that covers the back surface of the semiconductor substrate with respect to the front surface,
in which the back surface insulating film includes first and second back surface insulating films laminated, and
the second back surface insulating film covers the back surface and a side wall of at least one of the through hole or the annular trench.
(4) The semiconductor device according to (3), further including
a first element isolation region formed around a bottom portion of the through hole.
(5) The semiconductor device according to (3),
in which the second back surface insulating film includes a fixed charge film.
(6) The semiconductor device according to any one of (2) to (5),
in which the through hole includes a first through hole and a second through hole,
the annular trench is formed around the first through hole, and
the annular trench is not formed around the second through hole.
(7) The semiconductor device according to (2),
in which the through holes include first and second through holes arranged adjacent to each other in the direction parallel to the back surface,
the annular trench includes a first annular trench formed around the first through hole and a second annular trench formed around the second through hole, and
the first annular trench shares a part with the second annular trench.
(8) The semiconductor device according to (7),
in which a width of a portion shared by the first and second annular trenches is substantially same as a width of a portion not shared.
(9) The semiconductor device according to any one of (2) to (8), further including
a back surface insulating film that covers the back surface of the semiconductor substrate with respect to the front surface; and
a back surface rewiring formed along the periphery of the through hole and the back surface insulating film in the back surface.
(10) The semiconductor device according to (9),
in which an outer periphery of the back surface rewiring formed around the through hole is larger than an outer periphery of the annular trench.
(11) The semiconductor device according to (9),
in which a width of a portion traversing the annular trench in the back surface rewiring is thicker than other portions.
(12) The semiconductor device according to (9),
in which an opening having an outer periphery larger than an outer periphery of the through hole is formed in the back surface insulating film, and
the back surface rewiring around the through hole covers the back surface inside the opening.
(13) The semiconductor device according to any one of (2) to (12), further including:
an on-chip lens;
a photoelectric conversion section; and
an external terminal.
(14) The semiconductor device according to any one of (2) to (13), further including
a back surface insulating film that covers the back surface of the semiconductor substrate with respect to the front surface,
in which an end portion of the back surface insulating film includes a tapered shape.
(15) The semiconductor device according to any one of (2) to (14),
in which a diameter of the through hole is 1.5 to 4.0 times a width of the annular trench.
(16) The semiconductor device according to (15),
in which the diameter of the through hole is 2.0 to 3.0 times the width of the annular trench.
(17) The semiconductor device according to any one of (2) to (16), further including
a solder mask that covers the insulating film and the through hole,
in which a cavity closed by the solder mask is formed inside the through hole when viewed from the direction parallel to the back surface.
(18) The semiconductor device according to (17), further including
a low-k material formed between the through hole and the annular trench and having a dielectric constant lower than that of the semiconductor substrate.
(19) The semiconductor device according to (18), further including
a back surface insulating film that covers the back surface of the semiconductor substrate with respect to the front surface and the annular trench,
in which the solder mask further covers the back surface insulating film.
(20) The semiconductor device according to (18),
in which the low-k material covers the back surface of the semiconductor substrate with respect to the front surface, and
the solder mask further covers the low-k material and the annular trench.
(21) The semiconductor device according to any one of (2) to (20), further including
a first element isolation region formed between the wiring layer and the annular trench.
(22) The semiconductor device according to any one of (2) to (21),
in which the wiring layer includes a dummy gate formed between the through hole and the annular trench.
(23) The semiconductor device according to any one of (2) to (22), further including:
a back surface insulating film that covers the back surface of the semiconductor substrate with respect to the front surface; and
an insulating reinforcing film adjacent to the wiring layer and covering the periphery of the through hole.
(24) The semiconductor device according to (23),
in which the through hole has a step at a predetermined depth position when viewed from the direction parallel to the back surface,
the back surface insulating film covers the periphery of the through hole in a range from the back surface to the depth position, and
the reinforcing film covers the periphery of the through hole in a range from the depth position to the wiring layer, and is formed between a base material of the semiconductor substrate and the through hole when viewed from the direction perpendicular.
(25) The semiconductor device according to (23),
in which a cross-sectional shape of each of the through hole and the reinforcing film as viewed from the direction parallel has a curved taper.
(26) The semiconductor device according to (23),
in which the through hole has a step at a predetermined depth position when viewed from the direction parallel to the back surface,
the reinforcing film covers the periphery of the through hole in a range from the depth position to the wiring layer, and
the back surface insulating film covers the through hole and a periphery of the reinforcing film.
(27) The semiconductor device according to any one of (23) to (26),
in which a shape of the through hole includes a circle or a polygon when viewed from the direction perpendicular.
(28) The semiconductor device according to any one of (23) to (27),
in which the through hole covers an entire circumference of the through hole when viewed from the direction perpendicular.
(29) The semiconductor device according to any one of (23) to (27),
in which the reinforcing film covers a part of the periphery of the through hole when viewed from the direction perpendicular.
(30) The semiconductor device according to (23), in which a base material of the semiconductor substrate has a step at a predetermined depth position when viewed from the direction parallel to the back surface,
the back surface insulating film covers the periphery of the through hole in a range from the back surface to the depth position, and
the reinforcing film covers the periphery of the through hole in a range from the depth position to the wiring layer.
(31) The semiconductor device according to any one of (2) to (30), further including
a first protection member disposed adjacent to the wiring layer in the annular trench.
(32) The semiconductor device according to (31),
in which the first protection member includes an insulating resin or an inorganic film.
(33) The semiconductor device according to (31) or (32),
in which a shape of the first protection member is recessed toward a side of the wiring layer when viewed from the direction parallel to the back surface.
(34) The semiconductor device according to any one of (31) to (33),
in which the first protection member covers both corners on an inner peripheral side and an outer peripheral side of the annular trench.
(35) The semiconductor device according to any one of (31) to (33),
in which the first protection member covers only a corner on an inner peripheral side of the annular trench.
(36) The semiconductor device according to any one of (31) to (35), further including a second protection member disposed adjacent to the wiring layer in the through hole.
(37) The semiconductor device according to (2), further including
a back surface insulating film that covers the back surface of the semiconductor substrate with respect to the front surface,
in which a width of the annular trench on a side of the wiring layer is narrower than a width of the annular trench on a side of the back surface insulating film.
(38) The semiconductor device according to (37),
in which a cross-sectional shape of the annular trench has a taper when viewed from the direction parallel to the back surface.
(39) The semiconductor device according to (37),
in which a corner of the annular trench is rounded when viewed from the direction parallel to the back surface.
(40) The semiconductor device according to (39),
in which the corner is located in the wiring layer.
(41) The semiconductor device according to (39),
in which the corner straddles a boundary between the semiconductor substrate and the wiring layer.
(42) The semiconductor device according to any one of (39) to (41),
in which only the corner on an inner peripheral side of an inner periphery and an outer periphery of the annular trench is rounded.
(43) The semiconductor device according to any one of (2) to (42),
further including:
an insulating film formed between the annular trench and the through hole; and
an annular depletion layer formed in the insulating film.
(44) The semiconductor device according to (43),
in which the insulating film has a predetermined number of openings formed at an end portion of the depletion layer.
(45) The semiconductor device according to (44),
in which holes are formed as the openings at the end portion.
(46) The semiconductor device according to (44),
in which slits are formed as the openings at the end portion.
(47) The semiconductor device according to (1), further including a conductive metal embedded in the annular trench.
(48) The semiconductor device according to (47),
in which a potential of the through wiring is different from a potential of the conductive metal.
(49) The semiconductor device according to (47) or (48), further including a first insulating film that covers a side surface of the annular trench.
(50) The semiconductor device according to (49), further including a second insulating film that covers the side surface of the through hole.
(51) The semiconductor device according to any one of (47) to (50),
further including:
a first barrier metal that covers a side surface of the annular trench; and
a second barrier metal that covers the side surface of the through hole,
in which each of the first and second barrier metals includes any one of titanium, titanium nitride, tantalum, tantalum nitride, and ruthenium.
(52) The semiconductor device according to any one of (47) to (51),
in which the conductive metal includes any of copper, aluminum, tungsten, cobalt, silver, gold, iron, and lead.
(53) The semiconductor device according to any one of (47) to (52),
in which the annular trench includes a first annular trench and a second annular trench formed between the first annular trench and the through hole.
(54) The semiconductor device according to (53),
in which the conductive metal includes a first conductive metal embedded in the first annular trench and a second conductive metal embedded in the second annular trench, and
the second conductive metal is different in type from the first conductive metal.
(55) A method for manufacturing a semiconductor device including:
an etching procedure of forming, by etching, an annular trench surrounding a periphery of a through hole when viewed from a direction perpendicular to a back surface with respect to a front surface together with the through hole penetrating a semiconductor substrate in which a wiring layer is formed on the front surface; and
a wiring procedure of forming a through wiring along a side surface of the through hole.
(56) The method for manufacturing the semiconductor device according to (55),
in which the semiconductor substrate includes a second element isolation region disposed around a region to be a bottom portion of the through hole.
(57) The method for manufacturing the semiconductor device according to (56),
in which the wiring layer includes dummy polysilicon disposed in a region to be a bottom portion of the through hole, and
the dummy polysilicon is removed in the etching procedure.
(58) The method for manufacturing the semiconductor device according to (57),
in which a pattern of the dummy polysilicon includes a dot pattern.
(59) The method for manufacturing the semiconductor device according to (58), in which the wiring layer includes a predetermined number of wirings, and
the dummy polysilicon is disposed in a dot shape at a position corresponding to each of the wirings.

### REFERENCE SIGNS LIST

100 Semiconductor device
110 Solder mask
121 Back surface rewiring
122 Through wiring
131, 132 Back surface insulating film
140 Semiconductor substrate
141, 141-1, 141-2, 141-3 Through hole
142, 142-1, 142-2, 142-3, 290 Annular trench
143, 146 Element isolation region
144, 145 Notch
147 low-k material
149, 149-1, 149-2, 149-3 Through electrode
150 Wiring layer
151 Dummy gate
152 Pad
153 Dummy polysilicon
154 Cu wiring
160 External connection terminal
170 Photoelectric conversion layer
180 On-chip lens
190 Resist mask
191 Photoresist
210 Reinforcing film
220, 231, 232 Protection member
240, 261, 262 Insulating film
241 Hole
242 Slit
250 Depletion layer
271, 272 Barrier metal
281, 282 Conductive metal
12031 Imaging section

What is claimed is:

1. A semiconductor device, comprising:
a semiconductor substrate having a wiring layer formed on a front surface of the semiconductor substrate;
a through hole penetrating the semiconductor substrate;
a through wiring formed along a side surface of the through hole; and
an annular trench surrounding a periphery of the through hole when viewed from a direction perpendicular to a back surface of the semiconductor substrate with respect to the front surface.

2. The semiconductor device according to claim 1,
wherein a cavity is formed inside the annular trench when viewed from a direction parallel to the back surface.

3. The semiconductor device according to claim 2, further comprising
a back surface insulating film that covers the back surface of the semiconductor substrate with respect to the front surface,
wherein the back surface insulating film includes first and second back surface insulating films laminated, and
the second back surface insulating film covers the back surface and a side wall of at least one of the through hole or the annular trench.

4. The semiconductor device according to claim 3, further comprising
a first element isolation region formed around a bottom portion of the through hole.

5. The semiconductor device according to claim 3,
wherein the second back surface insulating film includes a fixed charge film.

6. The semiconductor device according to claim 2,
wherein the through hole includes a first through hole and a second through hole,
the annular trench is formed around the first through hole, and
the annular trench is not formed around the second through hole.

7. The semiconductor device according to claim 2,
wherein the through holes include first and second through holes arranged adjacent to each other in the direction parallel to the back surface,
the annular trench includes a first annular trench formed around the first through hole and a second annular trench formed around the second through hole, and
the first annular trench shares a part with the second annular trench.

8. The semiconductor device according to claim 7,
wherein a width of a portion shared by the first and second annular trenches is substantially same as a width of a portion not shared.

9. The semiconductor device according to claim 2, further comprising
a back surface insulating film that covers the back surface of the semiconductor substrate with respect to the front surface; and
a back surface rewiring formed along the periphery of the through hole and the back surface insulating film in the back surface.

10. The semiconductor device according to claim 9,
wherein an outer periphery of the back surface rewiring formed around the through hole is larger than an outer periphery of the annular trench.

11. The semiconductor device according to claim 9,
wherein a width of a portion traversing the annular trench in the back surface rewiring is thicker than other portions.

12. The semiconductor device according to claim 9,
wherein an opening having an outer periphery larger than an outer periphery of the through hole is formed in the back surface insulating film, and
the back surface rewiring around the through hole covers the back surface inside the opening.

13. The semiconductor device according to claim 2, further comprising:
an on-chip lens;
a photoelectric conversion section; and
an external terminal.

14. The semiconductor device according to claim 2, further comprising
a back surface insulating film that covers the back surface of the semiconductor substrate with respect to the front surface,
wherein an end portion of the back surface insulating film includes a tapered shape.

15. The semiconductor device according to claim 2,
wherein a diameter of the through hole is 1.5 to 4.0 times a width of the annular trench.

16. The semiconductor device according to claim 15,
wherein the diameter of the through hole is 2.0 to 3.0 times the width of the annular trench.

17. The semiconductor device according to claim 2, further comprising
a solder mask that covers the through hole,
wherein a cavity closed by the solder mask is formed inside the through hole when viewed from the direction parallel to the back surface.

18. The semiconductor device according to claim 17, further comprising
a low-k material formed between the through hole and the annular trench and having a dielectric constant lower than that of the semiconductor substrate.

19. The semiconductor device according to claim 18, further comprising
a back surface insulating film that covers the back surface of the semiconductor substrate with respect to the front surface and the annular trench,
wherein the solder mask further covers the back surface insulating film.

20. The semiconductor device according to claim 18,
wherein the low-k material covers the back surface of the semiconductor substrate with respect to the front surface, and
the solder mask further covers the low-k material and the annular trench.

21. The semiconductor device according to claim 2, further comprising
a second element isolation region formed between the wiring layer and the annular trench.

22. The semiconductor device according to claim 2,
wherein the wiring layer includes a dummy gate formed between the through hole and the annular trench.

23. The semiconductor device according to claim 2, further comprising:
a back surface insulating film that covers the back surface of the semiconductor substrate with respect to the front surface; and
an insulating reinforcing film adjacent to the wiring layer and covering the periphery of the through hole.

24. The semiconductor device according to claim 23,
wherein the through hole has a step at a predetermined depth position when viewed from the direction parallel to the back surface,
the back surface insulating film covers the periphery of the through hole in a range from the back surface to the depth position, and
the reinforcing film covers the periphery of the through hole in a range from the depth position to the wiring layer, and is formed between a base material of the semiconductor substrate and the through hole when viewed from the direction perpendicular.

25. The semiconductor device according to claim 23,
wherein a cross-sectional shape of each of the through hole and the reinforcing film as viewed from the direction parallel has a curved taper.

26. The semiconductor device according to claim 23,
wherein the through hole has a step at a predetermined depth position when viewed from the direction parallel to the back surface,
the reinforcing film covers the periphery of the through hole in a range from the depth position to the wiring layer, and
the back surface insulating film covers the through hole and a periphery of the reinforcing film.

27. The semiconductor device according to claim 23,
wherein a shape of the through hole includes a circle or a polygon when viewed from the direction perpendicular.

28. The semiconductor device according to claim 23,
wherein the through hole covers an entire circumference of the through hole when viewed from the direction perpendicular.

29. The semiconductor device according to claim 23,
wherein the reinforcing film covers a part of the periphery of the through hole when viewed from the direction perpendicular.

30. The semiconductor device according to claim 23, wherein a base material of the semiconductor substrate has a step at a predetermined depth position when viewed from the direction parallel to the back surface,
the back surface insulating film covers the periphery of the through hole in a range from the back surface to the depth position, and
the reinforcing film covers the periphery of the through hole in a range from the depth position to the wiring layer.

31. The semiconductor device according to claim 2, further comprising
a first protection member disposed adjacent to the wiring layer in the annular trench.

32. The semiconductor device according to claim 31,
wherein the first protection member includes an insulating resin or an inorganic film.

33. The semiconductor device according to claim 31,
wherein a shape of the first protection member is recessed toward a side of the wiring layer when viewed from the direction parallel to the back surface.

34. The semiconductor device according to claim 31,
wherein the first protection member covers both corners on an inner peripheral side and an outer peripheral side of the annular trench.

35. The semiconductor device according to claim 31,
wherein the first protection member covers only a corner on an inner peripheral side of the annular trench.

36. The semiconductor device according to claim 31, further comprising
a second protection member disposed adjacent to the wiring layer in the through hole.

37. The semiconductor device according to claim 2, further comprising
a back surface insulating film that covers the back surface of the semiconductor substrate with respect to the front surface,
wherein a width of the annular trench on a side of the wiring layer is narrower than a width of the annular trench on a side of the back surface insulating film.

38. The semiconductor device according to claim 37,
wherein a cross-sectional shape of the annular trench has a taper when viewed from the direction parallel to the back surface.

39. The semiconductor device according to claim 37,
wherein a corner of the annular trench is rounded when viewed from the direction parallel to the back surface.

40. The semiconductor device according to claim 39,
wherein the corner is located in the wiring layer.

41. The semiconductor device according to claim 39,
wherein the corner straddles a boundary between the semiconductor substrate and the wiring layer.

42. The semiconductor device according to claim 39,
wherein only the corner on an inner peripheral side of an inner periphery and an outer periphery of the annular trench is rounded.

43. The semiconductor device according to claim 2, further comprising:
an insulating film formed between the annular trench and the through hole; and
an annular depletion layer formed in the insulating film.

44. The semiconductor device according to claim 43,
wherein the insulating film has a predetermined number of openings formed at an end portion of the depletion layer.

45. The semiconductor device according to claim 44,
wherein holes are formed as the openings at the end portion.

46. The semiconductor device according to claim 44,
wherein slits are formed as the openings at the end portion.

47. The semiconductor device according to claim 1, further comprising a conductive metal embedded in the annular trench.

48. The semiconductor device according to claim 47,
wherein a potential of the through wiring is different from a potential of the conductive metal.

49. The semiconductor device according to claim 47, further comprising a first insulating film that covers a side surface of the annular trench.

50. The semiconductor device according to claim 49, further comprising a second insulating film that covers the side surface of the through hole.

51. The semiconductor device according to claim 47,
further comprising:
a first barrier metal that covers a side surface of the annular trench; and
a second barrier metal that covers the side surface of the through hole,
wherein each of the first and second barrier metals includes any one of titanium, titanium nitride, tantalum, tantalum nitride, and ruthenium.

52. The semiconductor device according to claim 47,
wherein the conductive metal includes any of copper, aluminum, tungsten, cobalt, silver, gold, iron, and lead.

53. The semiconductor device according to claim 47,
wherein the annular trench includes a first annular trench and a second annular trench formed between the first annular trench and the through hole.

54. The semiconductor device according to claim 53,
wherein the conductive metal includes a first conductive metal embedded in the first annular trench and a second conductive metal embedded in the second annular trench, and
the second conductive metal is different in type from the first conductive metal.

55. A method for manufacturing a semiconductor device, comprising:
an etching procedure of forming, by etching, an annular trench surrounding a periphery of a through hole when viewed from a direction perpendicular to a back surface with respect to a front surface together with the through hole penetrating a semiconductor substrate in which a wiring layer is formed on the front surface; and
a wiring procedure of forming a through wiring along a side surface of the through hole.

56. The method for manufacturing the semiconductor device according to claim 55,
wherein the semiconductor substrate includes a second element isolation region disposed around a region to be a bottom portion of the through hole.

57. The method for manufacturing the semiconductor device according to claim 56,
wherein the wiring layer includes dummy polysilicon disposed in a region to be a bottom portion of the through hole, and
the dummy polysilicon is removed in the etching procedure.

58. The method for manufacturing the semiconductor device according to claim 57,
wherein a pattern of the dummy polysilicon includes a dot pattern.

59. The method for manufacturing the semiconductor device according to claim 58, wherein the wiring layer includes a predetermined number of wirings, and
the dummy polysilicon is disposed in a dot shape at a position corresponding to each of the wirings.
